(19) United States
(12) Patent Application Publication
(10) Pub. No.: US 2015/0091231 A1
(43) Pub. Date: Apr. 2, 2015

(54) STAGE DEVICE AND SEMICONDUCTOR FABRICATION APPARATUS INCLUDING THE SAME

(71) Applicant: SAMSUNG ELECTRONICS CO., LTD., SUWON-SI (KR)

(72) Inventors: SANG-WOOK PARK, SUWON-SI (KR); OUI-SERG KIM, SEONGNAM-SI (KR); SANG-DON JANG, SUWON-SI (KR)

(73) Assignee: SAMSUNG ELECTRONICS CO., LTD., SUWON-SI (KR)

(21) Appl. No.: 14/255,186

(22) Filed: Apr. 17, 2014

(30) Foreign Application Priority Data
Sep. 27, 2013 (KR) 10-2013-0115471

(51) Int. Cl. H01L 21/687; G03F 7/20

(52) U.S. Cl. CPC H01L 21/68764; G03F 7/70716; H01L 2221/683
USPC 269/55

(57) ABSTRACT

A stage device includes an interference mirror extending in an X-axis direction and first through third flexure structures configured to restrict the interference mirror. The first flexure structure restricts the interference mirror in a Y-axis direction and a Z-axis direction. The second flexure structure restricts the interference mirror in the Y-axis direction and the Z-axis direction. The third flexure structure restricts the interference mirror in the X-axis direction and the Z-axis direction.

### CROSS-REFERENCE TO RELATED APPLICATION

This application claims priority under 35 U.S.C. §119 to Korean Patent Application No. 10-2013-0115471 filed on Sep. 27, 2013, the disclosure of which is incorporated by reference herein in its entirety.

### TECHNICAL FIELD

Exemplary embodiments of the inventive concept relate to fabricating semiconductor devices, and more specifically, to a stage device including an interferometer and a semiconductor fabrication apparatus including the same.

### DISCUSSION OF RELATED ART

A semiconductor fabrication apparatus includes a stage device for supporting a wafer. The wafer may be moved in an X-axis direction and a Y-axis direction by the stage device during a fabrication process. Research has been conducted to precisely measure and control the position of a wafer during a fabrication process.

### SUMMARY

In accordance with an exemplary embodiment of the inventive concept, a stage device includes an interference mirror extending in an X-axis direction. A datum flexure structure restricts the interference mirror in a Y-axis direction and a Z-axis direction. The datum flexure structure includes a datum upper plate combined with the interference mirror. A datum hinge part is disposed under the datum upper plate. A distant flexure structure restricts the interference mirror in the Y-axis direction and the Z-axis direction. The distant flexure structure includes a distant upper plate spaced apart from the datum upper plate in the X-axis direction. A first distant hinge part is disposed under the distant upper plate. An intermediate flexure structure restricts the interference mirror in the X-axis direction and the Z-axis direction. The intermediate flexure structure includes an intermediate upper plate disposed between the datum upper plate and the distant upper plate. A first intermediate hinge part is disposed under the intermediate upper plate. Each of the datum hinge part, the first distant hinge part, and the first intermediate hinge part includes flexure hinges stacked in the Z-axis direction. The intermediate upper plate is spaced apart from the datum upper plate and the distant upper plate in the Y-axis direction.

The datum hinge part may include a vertical-type first yz datum flexure hinge extending in the Y-axis direction, a vertical-type second yz datum flexure hinge extending in the Y-axis direction, a vertical-type xz datum flexure hinge extending in the X-axis direction, and a cross-type zc datum flexure hinge extending in the Z-axis direction.

The second yz datum flexure hinge may be spaced apart from the first yz datum flexure hinge in the Z-axis direction.

A Y-axial horizontal length of the datum hinge part may increase far away from the datum upper plate.

The first distant hinge part may include a first yz distant flexure hinge disposed parallel to the first yz datum flexure hinge, a second yz distant flexure hinge disposed parallel to the second yz datum flexure hinge, a first xz distant flexure hinge disposed parallel to the xz datum flexure hinge, and a zc distant flexure hinge disposed parallel to the zc datum flexure hinge.

An order in which the first yz distant flexure hinge, the second yz distant flexure hinge, the first xz distant flexure hinge, and the zc distant flexure hinge are stacked may be different from an order in which the first yz datum flexure hinge, the second yz datum flexure hinge, the xz datum flexure hinge, and the zc datum flexure hinge are stacked.

The distant flexure structure may further include a first distant body spaced apart from the first distant hinge part in the Y-axis direction, and a second distant hinge part configured to restrict the distant upper plate in the Y-axis direction. The second distant hinge part may include flexure hinges disposed between an upper end of the first distant hinge part and an upper end of the first distant body and stacked in the Y-axis direction. The first distant hinge part may further include a vertical second xz distant flexure hinge extending in the X-axis direction.

The second distant hinge part may include a horizontal-type first xy distant flexure hinge extending in the X-axis direction, a horizontal-type second xy distant flexure hinge extending in the X-axis direction, a Y-axial type first zy distant flexure hinge extending in the Z-axis direction, a Y-axial type second zy distant flexure hinge extending in the Z-axis direction, and a cross-type yc distant flexure hinge extending in the Y-axis direction.

The distant flexure structure may further include a distant lower plate disposed under the first distant hinge part and extending in the Y-axis direction, a second distant body disposed under the second distant hinge part and fixed onto the distant lower plate, a horizontal-type xy rotation flexure hinge disposed between an upper end of the second distant body and the first distant body and extending in the X-axis direction, and a rotation control member disposed at a lower end of the first distant body. The first distant body may be spaced apart from the distant lower plate. A level of a bottom surface of the first distant body may be higher than a level of a bottom surface of the distant lower plate.

The first intermediate hinge part may include a vertical-type first yz intermediate flexure hinge extending in the Y-axis direction, a vertical-type first xz intermediate flexure hinge extending in the X-axis direction, a vertical-type second xz intermediate flexure hinge extending in the X-axis direction, and a cross-type zc intermediate flexure hinge extending in the Z-axis direction.

The intermediate flexure structure may further include an intermediate fixing body spaced apart from the first intermediate hinge part in the X-axis direction, and a second intermediate hinge part configured to restrict the intermediate upper plate in the X-axis direction. The second intermediate hinge part may include flexure hinges disposed between an upper end of the first intermediate hinge part and an upper end of the intermediate fixing body and stacked in the X-axis direction. The first intermediate hinge part may further include a vertical second yz intermediate flexure hinge extending in the Y-axis direction.

The second intermediate hinge part may include a horizontal-type first yx intermediate flexure hinge extending in the Y-axis direction, a horizontal-type second yx intermediate flexure hinge extending in the Y-axis direction, an X-axial type first zx intermediate flexure hinge extending in the Z-axis direction, an X-axial type second zx intermediate flexure hinge extending in the Z-axis direction, and a cross-type xc intermediate flexure hinge extending in the X-axis direction.

The intermediate flexure structure may further include an tilting control part configured to move the intermediate upper plate and the first intermediate hinge part in the Z-axis direction. The tilting control part may include an intermediate lower plate disposed under the intermediate fixing body and extending in the X-axis direction, an tilting fixing body disposed under the second distant hinge part and fixed onto the intermediate lower plate, a first tilting control body disposed between the intermediate fixing body and the tilting fixing body and spaced apart from the intermediate lower plate, a second tilting control body disposed between the second intermediate hinge part and the tilting fixing body, a third tilting control body disposed between the first intermediate hinge part and the tilting fixing body and spaced apart from the intermediate lower plate, a horizontal-type first yx tilting flexure hinge disposed between an upper end of the tilting fixing body and the first tilting control body and extending in the Y-axis direction, a horizontal-type second yx tilting flexure hinge disposed between the first tilting control body and the second tilting control body and extending in the Y-axis direction, a horizontal-type third yx tilting flexure hinge disposed between the second tilting control body and the third tilting control body and extending in the Y-axis direction, a horizontal-type fourth yx tilting flexure hinge disposed between a lower end of the tilting fixing body and the third tilting control body and extending in the Y-axis direction, and a tilting control element disposed at a lower end of the first tilting control body.

The third tilting control body may be connected to a lower end of the first intermediate hinge part. A level of a bottom surface of the third tilting control body may be higher than a level of a bottom surface of the intermediate lower plate.

In accordance with an exemplary embodiment of the inventive concept, a stage device includes a first flexure structure including a first upper plate and first flexure hinges configured to restrict the first upper plate in a Y-axis direction and a Z-axis direction, a second flexure structure spaced apart from the first flexure structure in an X-axis direction, the second flexure structure including a second upper plate and second flexure hinges configured to restrict the second upper plate in the Y-axis direction and the Z-axis direction, a third flexure structure disposed between the first flexure structure and the second flexure structure, the third flexure structure including a third upper plate and third flexure hinges configured to restrict the third upper plate in the X-axis direction and the Z-axis direction, and an interference mirror disposed on the first through third upper plates and extending in the X-axis direction. The first and second upper plates are disposed close to a first side surface of the interference mirror extending in the X-axis direction. The third upper plate is disposed close to a second side surface of the interference mirror opposite to the first side surface. A Y-axial horizontal length of each of the first through third upper plates is less than or equal to the half of a Y-axial horizontal length of the interference mirror.

According to an exemplary embodiment of the inventive concept, a stage device comprises a stage. A support is disposed on the stage. An interference mirror is disposed on the support. A first flexure structure is disposed adjacent to a first upper edge of the support between the support and the interference mirror. The first flexure structure restricts a movement of the interference mirror in a Y-axis direction and a Z-axis direction. A second flexure structure is disposed adjacent to the first upper edge of the support between the support and the interference mirror. The second flexure structure restricts a movement of the interference mirror in the Y-axis direction and the Z-axis direction. A third flexure structure is disposed adjacent to a second upper edge of the support between the support and the interference mirror. The second upper edge is opposite the first upper edge. The third flexure structure restricts a movement of the interference mirror in an X-axis direction and the Z-axis direction. The third flexure structure is positioned between the first flexure structure and the second flexure structure in the X-axis direction.

The stage device further comprises adaptors respectively attaching the first flexure structure, the second flexure structure, and the third flexure structure to the interference mirror.

The stage device further comprises a second support disposed on the stage. A second interference mirror is disposed on the second support. At least three flexure structures are disposed between the second support and the second interference mirror. The at least three flexure structures restrict a movement of the second interference mirror in the X-axis direction, the Y-axis direction, or the Z-axis direction.

Each of the first flexure structure, the second flexure structure, and the third flexure structure includes an upper plate, a lower plate, and a hinge set disposed between the upper plate and the lower plate.

The hinge set of the first flexure structure includes a plurality of hinges that are stacked in the Z-axis direction.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a perspective view of a stage device according to an exemplary embodiment of the inventive concept;

FIG. 2 is a top view of a stage device according to an exemplary embodiment of the inventive concept;

FIG. 3A is a sectional view taken along line I-I′ of FIG. 2, according to an exemplary embodiment of the inventive concept;

FIG. 3B is a sectional view taken along line II-IP of FIG. 2, according to an exemplary embodiment of the inventive concept;

FIG. 4 is an exploded perspective view of a Y-axis mirror support and a Y-axis interference mirror of a stage device according to an exemplary embodiment of the inventive concept;

FIGS. 5A and 5B are perspective views of a Y-axis datum flexure structure of a stage device according to an exemplary embodiment of the inventive concept;

FIGS. 5C through 5E are partial perspective views of a portion of a Y-axis datum flexure structure according to an exemplary embodiment of the inventive concept;

FIGS. 6A and 6B are perspective views of a Y-axis distant flexure structure of a stage device according to an exemplary embodiment of the inventive concept;

FIGS. 6C through 6E are partial perspective views of a Y-axis distant flexure structure according to an exemplary embodiment of the inventive concept;

FIGS. 6F and 6G are side views illustrating operations of a Y-axis distant flexure structure according to an exemplary embodiment of the inventive concept;

FIGS. 7A and 7B are perspective views of a Y-axis intermediate flexure structure of a stage device according to an exemplary embodiment of the inventive concept;

FIGS. 7C through 7E are partial perspective views of a Y-axis intermediate flexure structure according to an exemplary embodiment of the inventive concept;

FIGS. 7F and 7G are side views illustrating operations of a Y-axis intermediate flexure structure according to an exemplary embodiment of the inventive concept;

FIG. 8 is a plan view of a Y-axis datum flexure structure, a Y-axis distant flexure structure, and a Y-axis intermediate flexure structure of a stage device according to an exemplary embodiment of the inventive concept;

FIG. 9 is an exploded perspective view of an X-axis mirror support and an X-axis interference mirror of a stage device according to an exemplary embodiment of the inventive concept;

FIGS. 10A and 10B are perspective views of an X-axis datum flexure structure of a stage device according to an exemplary embodiment of the inventive concept;

FIGS. 11A and 11B are perspective views of an X-axis distant flexure structure of a stage device according to an exemplary embodiment of the inventive concept;

FIGS. 12A and 12B are perspective views of an X-axis intermediate flexure structure of a stage device according to an exemplary embodiment of the inventive concept;

FIG. 13 is a plan view of an X-axis datum flexure structure, an X-axis distant flexure structure, and an X-axis intermediate flexure structure of a stage device according to an exemplary embodiment of the inventive concept;

FIG. 14 is a perspective view of a Y-axis datum flexure structure of a stage device according to an exemplary embodiment of the inventive concept;

FIG. 15 is a perspective view of an X-axis datum flexure structure of a stage device according to an exemplary embodiment of the inventive concept;

FIG. 16 is an exploded perspective view of a Y-axis mirror support and a Y-axis interference mirror of a stage device according to an exemplary embodiment of the inventive concept;

FIG. 17 is an exploded perspective view of an X-axis mirror support and an X-axis interference mirror of a stage device according to an exemplary embodiment of the inventive concept;

FIG. 18 is an exploded perspective view of a Y-axis mirror support and a Y-axis interference mirror of a stage device according to an exemplary embodiment of the inventive concept;

FIGS. 19A and 19B are perspective views of a first Y-axis fixing flexure structure of a stage device according to an exemplary embodiment of the inventive concept;

FIG. 20 is an exploded perspective view of an X-axis mirror support and an X-axis interference mirror of a stage device according to an exemplary embodiment of the inventive concept;

FIGS. 21A and 21B are perspective views of a first X-axis fixing flexure structure of a stage device according to an exemplary embodiment of the inventive concept;

FIG. 22 is a perspective view of a stage device according to an exemplary embodiment of the inventive concept;

FIG. 23 is a top view of a stage device according to an exemplary embodiment of the inventive concept;

FIG. 24A is a sectional view taken along line of FIG. 23, according to an exemplary embodiment of the inventive concept;

FIG. 24B is a sectional view taken along line IV-IV′ of FIG. 23, according to an exemplary embodiment of the inventive concept; and

FIGS. 25 through 27 are schematic diagrams of semiconductor fabrication apparatuses including a stage device according to exemplary embodiments of the inventive concept.

### DETAILED DESCRIPTION OF EMBODIMENTS

Various exemplary embodiments of the inventive concept will now be described in detail with reference to the accompanying drawings. This inventive concept may, however, be embodied in different forms and should not be construed as limited to the embodiments set forth herein. It will also be understood that when an element is referred to as being “on” or “connected to” another element, it can be directly on the other element or intervening elements may also be present. Like numbers may refer to like or similar elements throughout the specification and the drawings.

As used herein, the singular forms “a,” “an,” and “the” are intended to include the plural forms as well, unless the context clearly indicates otherwise.

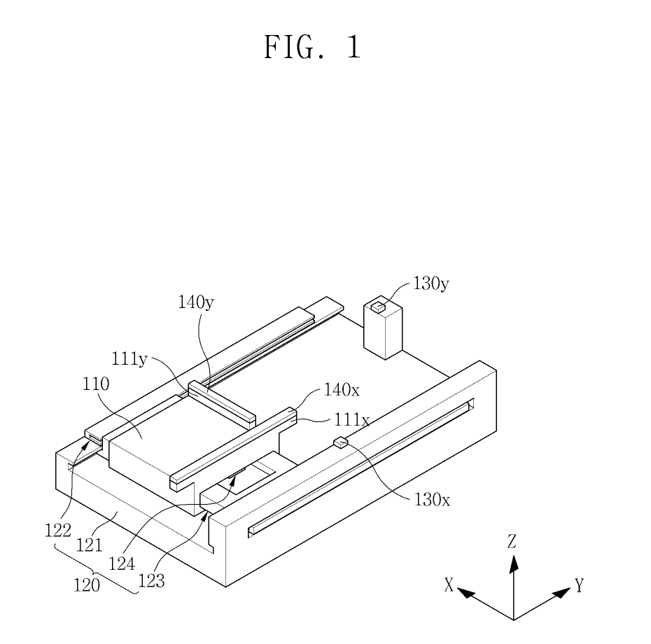

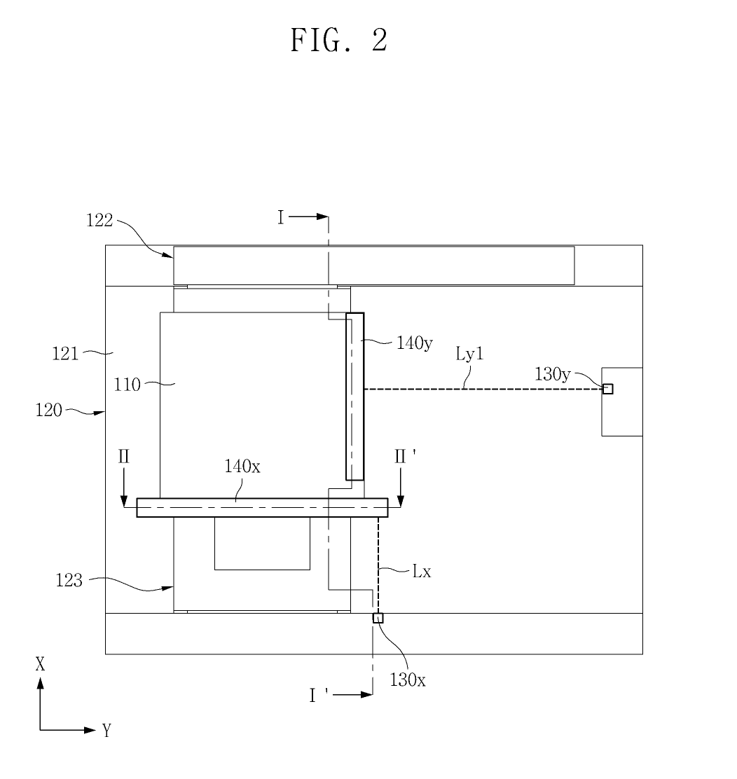

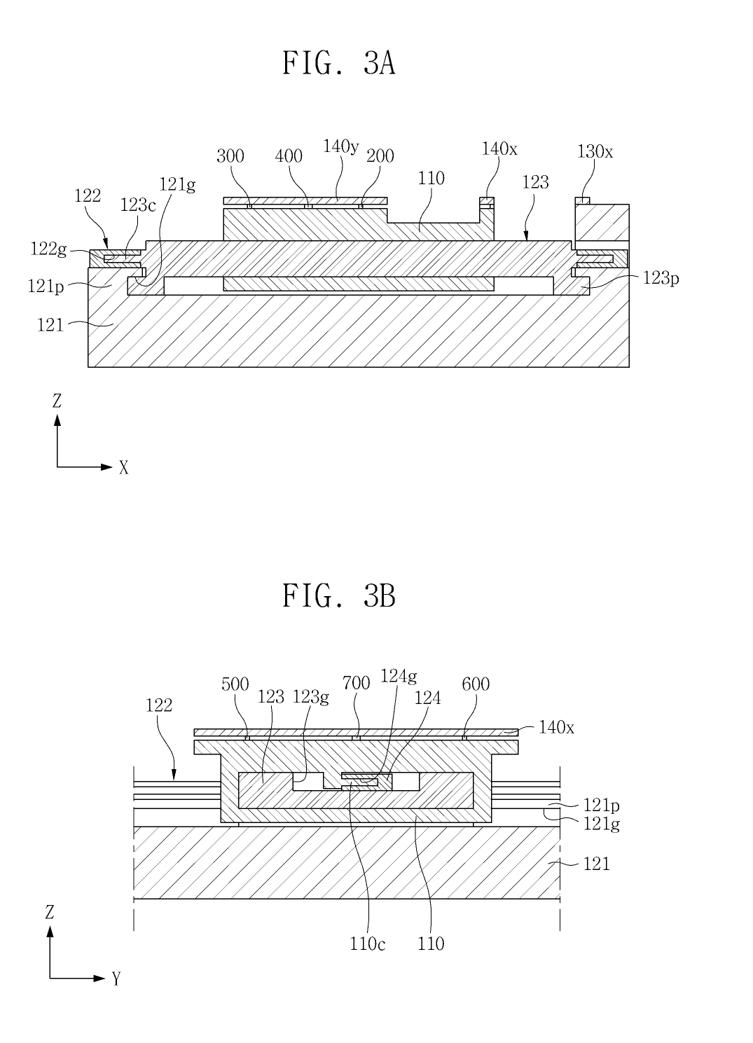

FIG. 1 is a perspective view of a stage device according to an exemplary embodiment of the inventive concept, and FIG. 2 is a top view of a stage device according to an exemplary embodiment of the inventive concept. FIG. 3A is a sectional view taken along line I-I′ of FIG. 2, according to an exemplary embodiment of the inventive concept, and FIG. 3B is a sectional view taken along line II-II′ of FIG. 2, according to an exemplary embodiment of the inventive concept.

Referring to FIGS. 1, 2, 3A, and 3B, a stage device according to an exemplary embodiment of the inventive concept may include a stage 110, a stage base 120, a Y-axis interferometer 130y, an X-axis interferometer 130x, a Y-axis interference mirror 140y, an X-axis interference mirror 140x, a Y-axis datum flexure structure 200, a Y-axis distant flexure structure 300, a Y-axis intermediate flexure structure 400, an X-axis datum flexure structure 500, an X-axis distant flexure structure 600, and an X-axis intermediate flexure structure 700.

The stage 110 may support a wafer. The wafer may be fixed onto the stage 110 during a fabrication process. The stage 110 may be in direct contact with the wafer. The stage 110 may include a Y-axis mirror support 111y and an X-axis mirror support 111x.

The Y-axis mirror support 111y may support the Y-axis interference mirror 140y. The Y-axis mirror support 111y may be disposed on a top surface of the stage 110. The Y-axis mirror support 111y may be disposed close to the Y-axis interferometer 130y.

The Y-axis mirror support 111y may extend in the same direction as the Y-axis interference mirror 140y. The Y-axis mirror support 111y may extend in the X-axis direction. An X-axial horizontal length of the Y-axis mirror support 111y may be smaller than an X-axial horizontal length of the stage 110.

The X-axis mirror support 111x may support the X-axis interference mirror 140x. The X-axis mirror support 111x may be disposed on the top surface of the stage 110. The X-axis mirror support 111x may be disposed close to the X-axis interferometer 130x.

The X-axis mirror support 111x may be spaced apart from the Y-axis mirror support 111y. For instance, the X-axis mirror support 111x may be spaced apart from the Y-axis mirror support 111y in the X-axis direction. The X-axis mirror support 111x may be disposed between the X-axis interferometer 130x and the Y-axis mirror support 111y.

The X-axis mirror support 111x may extend in the same direction as the X-axis interference mirror 140x. The X-axis mirror support 111x may extend in the Y-axis direction. A Y-axial horizontal length of the X-axis mirror support 111x may be greater than a Y-axial horizontal length of the X-axis interference mirror 140x.

The stage base 120 may support the stage 110. The stage 110 may be disposed on a top surface of the stage base 120. The stage base 120 may move the stage 110. The stage 110 may be moved by the stage base 120 in the X-axis direction and the Y-axis direction.

The stage base 120 may include a base body 121, a Y-axis driving members 122, a guide block 123, and an X-axis driving member 124.

The base body 121 may provide a space for moving the stage 110. For instance, a top surface of the base body 121 may be parallel to a plane surface formed by the X-axis direction and the Y-axis direction. The Y-axis driving members 122, the guide block 123, and the X-axis driving member 124 may be disposed on the top surface of the base body 121.

The base body 121 may have a rectangular shape. For instance, an X-axial horizontal length of the base body 121 may be smaller than a Y-axial horizontal length of the base body 121. A distance by which the stage 110 moves in the Y-axis direction may be greater than a distance by which the stage 110 moves in the X-axis direction.

The base body 121 may include body protrusions 121p. The body protrusions 121p may be disposed on an edge of the top surface of the base body 121. The body protrusions 121p may be disposed close to opposite side surfaces of the base body 121. For instance, each of the body protrusions 121p may be disposed close to a side surface of the base body 121, which may extend in the Y-axis direction. The body protrusions 121p may be spaced apart from each other in the X-axis direction.

The body protrusions 121p may extend in the Y-axis direction. A Y-axial horizontal length of the body protrusions 121p may be equal to the Y-axial horizontal length of the base body 121. The stage 110 may move between the body protrusions 121p.

Each of the body protrusions 121p may include a block guide groove 121g. The block guide groove 121g may be disposed on a side surface of the corresponding body protrusion 121p. For instance, the block guide groove 121g may be disposed on a side surface of the corresponding body protrusion 121p, which may be opposite the stage 110. The block guide groove 121g may be opposite a side surface of the stage 110.

The block guide groove 121g may extend along the corresponding body protrusion 121p. For instance, the block guide groove 121g may extend in the Y-axis direction. A Y-axial horizontal length of the block guide groove 121g may be equal to the Y-axial horizontal length of the corresponding body protrusion 121p.

The Y-axis driving members 122 may move the stage 110 in the Y-axis direction. The stage 110 may be prevented by the Y-axis driving members 122 from deviating from the top surface of the stage base 120. The wafer may be moved by the Y-axis driving members 122 in the Y-axis direction.

The Y-axis driving members 122 may be disposed on the top surface of the base body 121. The Y-axis driving members 122 may be disposed on the body protrusions 121p. Each of the Y-axis driving member 122 may be in contact with a top surface of the corresponding body protrusion 121p.

The Y-axis driving members 122 may extend in the Y-axis direction. A Y-axial horizontal length of the Y-axis driving members 122 may be smaller than the Y-axial horizontal length of the body protrusions 121p. The Y-axial horizontal length of the Y-axis driving members 122 may be smaller than the Y-axial horizontal length of the base body 121. The Y-axial horizontal length of the Y-axis driving members 122 may be smaller than the Y-axial horizontal length of the stage base 120.

Each of the Y-axis driving members 122 may include a block combination groove 122g. The block combination groove 122g may be disposed on a side surface of the corresponding Y-axis driving member 122. For instance, the block combination groove 122g may be disposed on a side surface of the corresponding Y-axis driving member 122, which may be opposite the stage 110. The block combination groove 122g may be opposite the side surface of the stage 110.

The block combination groove 122g may extend along the corresponding Y-axis driving member 122 in the Y-axis direction. An Y-axial horizontal length of the block combination groove 122g may be equal to the Y-axial horizontal length of the corresponding Y-axis driving member 122.

The block combination groove 122g may be disposed on the block guide groove 121g in parallel to the block guide groove 121g. The Y-axial horizontal length of the block combination groove 122g may be smaller than the Y-axial horizontal length of the block guide groove 121g.

The guide block 123 may provide a path along which the stage 110 moves in the X-axis direction. The stage 110 may move along the guide block 123 in the X-axis direction.

The guide block 123 may extend in the X-axis direction. The guide block 123 may connect the Y-axis driving members 122. The guide block 123 may connect the body protrusions 121p. The stage 110 may surround the guide block 123. A bottom surface of the stage 110 may be spaced apart from the top surface of the base body 121.

The guide block 123 may include guide protrusions 123p, guide connecting portions 123c, and a stage guide groove 123g.

The guide protrusions 123p may extend to the block guide grooves 121g of the body protrusions 121p. The guide protrusions 123p may move along the body protrusions 121p in the Y-axis direction.

The guide connecting portions 123c may be disposed on side surfaces of the guide block 123, which may be opposite the Y-axis driving members 122. The guide connecting portions 123c may extend to the block combination grooves 122g of the Y-axis driving members 122. Each of the guide connecting portions 123c may be combined with the corresponding block combination groove 122g. The guide connecting portions 123c may be moved by the Y-axis driving members 122 in the Y-axis direction.

The stage guide groove 123g may be disposed on a top surface of the guide block 123. The stage guide groove 123g may extend in the same direction as the guide block 123. For instance, the stage guide groove 123g may extend in the X-axis direction. An X-axial horizontal length of the stage guide groove 123g may be smaller than an X-axial horizontal length of the guide block 123. The X-axial horizontal length of the stage guide groove 123g may be greater than the X-axial horizontal length of the stage 110.

The X-axis driving member 124 may move the stage 110 in the X-axis direction. The stage 110 may be moved by the X-axis driving member 124 along the guide block 123.

The X-axis driving member 124 may be disposed within the stage guide groove 123g. The X-axis driving member 124 may extend in the X-axis direction. An X-axial horizontal length of the X-axis driving member 124 may be greater than the X-axial horizontal length of the stage 110. The X-axial horizontal length of the X-axis driving member 124 may be smaller than the X-axial horizontal length of the stage guide groove 123g. A Y-axial horizontal length of the X-axis driving member 124 may be smaller than a Y-axial horizontal length of the stage guide groove 123g.

The X-axis driving member 124 may be in direct contact with the guide block 123. The X-axis driving member 124 may be in direct contact with a bottom surface of the stage guide groove 123g. A top surface of the X-axis driving member 124 may be positioned at a lower level than a top level of the guide block 123. The X-axis driving member 124 may be spaced apart from the stage 110.

The X-axis driving member 124 may include a stage combination groove 124g. The stage combination groove 124g may be disposed on a side surface of the X-axis driving member 124. The stage combination groove 124g may extend in the X-axis direction. The stage combination groove 124g may extend along the side surface of the X-axis driving member 124.

In a stage device according to an exemplary embodiment of the inventive concept, the stage 110 may be combined with the X-axis driving member 124. For instance, the stage 110 may further include a stage connecting portion 110c. The stage connecting portion 110c may extend to the stage combination groove 124g. The stage connecting portion 110c may be combined with the stage combination groove 124g. The X-axis driving member 124 may move the stage connecting portion 110c in the X-axis direction.

The Y-axis interferometer 130y may measure a Y-axial position of the stage 110. For instance, the Y-axis interferometer 130y may measure the Y-axial position of the stage 110 using the Y-axis interference mirror 140y. For instance, a method of measuring the Y-axial position of the stage 110 may include radiating beams from a light source to the Y-axis interferometer 130y, splitting beams using a beam splitter in directions of the Y-axis interference mirror 140y and a datum mirror direction, comparing beams Ly reflected by the Y-axis interference mirror 140y with beams reflected by the datum mirror, and measuring the Y-axial position of the stage 110 using a frequency or phase change of the beams Ly reflected by the Y-axis interference mirror 140y.

The Y-axis interferometer 130y may be spaced apart from the stage 110 in the Y-axis direction. The Y-axis interferometer 130y may be disposed on the stage base 120. The Y-axis interferometer 130y may be disposed on the top surface of the base body 121. For instance, the Y-axis interferometer 130y may be disposed on a Y-axial end portion of the base body 121. The Y-axis interferometer 130y may be opposite a side surface of the Y-axis interference mirror 140y, which may extend in the X-axis direction.

The X-axis interferometer 130x may measure an X-axial position of the stage 110. For instance, the X-axis interferometer 130x may measure the X-axial position of the stage 110 using the X-axis interference mirror 140x. The X-axis interferometer 130x may have substantially the same structure as the Y-axis interferometer 130y. For instance, a method of measuring the X-axial position of the stage 110 may include radiating beams from a light source to the X-axis interferometer 130x, splitting beams using a beam splitter toward the X-axis interference mirror 140x and the datum mirror direction, comparing beams Lx reflected by the X-axis interference mirror 140x with beams reflected by the datum mirror, and measuring the X-axial position of the stage 110 using a change in frequency or phase of beams Lx reflected by the X-axis interference mirror 140x.

The X-axis interferometer 130x may be spaced apart from the stage 110 in the X-axis direction. For instance, the X-axis interferometer 130x may be disposed on the body protrusion 121p of the base body 121. The X-axis interferometer 130x may be disposed on the Y-axis driving members 122. The X-axis interferometer 130x may be opposite a side surface of the X-axis interference mirror 140x, which may extend in the Y-axis direction.

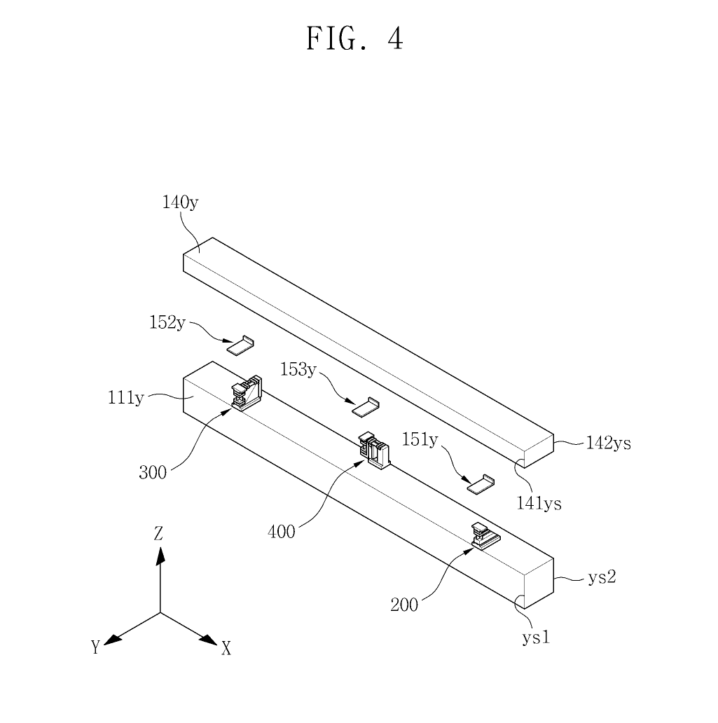

FIG. 4 is an exploded perspective view of a Y-axis mirror support and a Y-axis interference mirror of a stage device according to an exemplary embodiment of the inventive concept.

Referring to FIGS. 1 and 4, in the stage device according to an exemplary embodiment of the inventive concept, the Y-axis interference mirror 140y may be disposed on the Y-axis mirror support 111y. The Y-axis datum flexure structure 200, the Y-axis distant flexure structure 300, and the Y-axis intermediate flexure structure 400 may be disposed between the Y-axis mirror support 111y and the Y-axis interference mirror 140y.

The Y-axis interference mirror 140y may reflect beams radiated by the Y-axis interferometer 130y toward the Y-axis interferometer 130y. The frequency and phase of beams Ly reflected by the Y-axis interference mirror 140y may be different from the frequency and phase of beams radiated by the Y-axis interferometer 130y according to the Y-axial position of the stage 110.

The Y-axis interference mirror 140y may extend in the X-axis direction. An X-axial horizontal length of the Y-axis interference mirror 140y may be smaller than the X-axis horizontal length of the stage 110. The X-axial horizontal length of the Y-axis interference mirror 140y may be equal to the X-axial horizontal length of the Y-axis mirror support 111y.

A Y-axial horizontal length of the Y-axis interference mirror 140y may be equal to a Y-axial horizontal length of the Y-axis mirror support 111y. The Y-axis interference mirror 140y may have the same area as the Y-axis mirror support 111y. For instance, side surfaces of the Y-axis mirror support 111y may be vertically aligned with side surfaces of the Y-axis interference mirror 140y.

The Y-axis datum flexure structure 200, the Y-axis distant flexure structure 300, and the Y-axis intermediate flexure structure 400 may fix the Y-axis interference minor 140y. The Y-axis interference mirror 140y may be fixed onto the Y-axis mirror support lily by the Y-axis datum flexure structure 200, the Y-axis distant flexure structure 300 and the Y-axis intermediate flexure structure 400.

The Y-axis datum flexure structure 200, the Y-axis distant flexure structure 300, and the Y-axis intermediate flexure structure 400 may be arranged in the X-axis direction. The Y-axis datum flexure structure 200, the Y-axis distant flexure structure 300, and the Y-axis intermediate flexure structure 400 may be spaced apart from each other in the X-axis direction. The Y-axis distant flexure structure 300 may be spaced apart from the Y-axis datum flexure structure 200 in the X-axis direction. The Y-axis intermediate flexure structure 400 may be disposed between the Y-axis datum flexure structure 200 and the Y-axis distant flexure structure 300.

The Y-axis datum flexure structure 200 may be disposed close to a first side surface ys1 of the Y-axis mirror support 111y. The first side surface ys1 of the Y-axis mirror support 111y may extend in the X-axis direction. The first side surface ys1 of the Y-axis mirror support 111y may be vertically aligned with a first side surface 141ys of the Y-axis interference mirror 140y. The Y-axis datum flexure structure 200 may be disposed close to the first side surface 141ys of the Y-axis interference mirror 140y.

The Y-axis distant flexure structure 300 may be disposed close to the first side surface ys1 of the Y-axis mirror support 111y. The Y-axis distant flexure structure 300 may be disposed close to the first side surface 141ys of the Y-axis interference mirror 140y.

The Y-axis intermediate flexure structure 400 may be disposed close to a second side surface ys2 of the Y-axis mirror support 111y. The second side surface ys2 of the Y-axis mirror support 111y may extend in the X-axis direction. The second side surface ys2 of the Y-axis mirror support 111y may be opposite the first side surface ys1 of the Y-axis mirror support 111y. The second side surface ys2 of the Y-axis mirror support 111y may be vertically aligned with a second side surface 142ys of the Y-axis interference mirror 140y. The Y-axis intermediate flexure structure 400 may be disposed close to the second side surface 142ys of the Y-axis interference mirror 140y.

The stage device according to an exemplary embodiment of the inventive concept may further include a first Y-axis adaptor 151y, a second Y-axis adaptor 152y, and a third Y-axis adaptor 153y.

The first Y-axis adaptor 151y may combine the first Y-axis datum flexure structure 200 with the Y-axis interference mirror 140y. The Y-axis datum flexure structure 200 may be combined with the Y-axis interference mirror 140y by the first Y-axis adaptor 151y. The first Y-axis adaptor 151y may be disposed between the Y-axis datum flexure structure 200 and the Y-axis interference mirror 140y.

The first Y-axis adaptor 151y may have the same thermal strain characteristics as the Y-axis interference mirror 140y. The first Y-axis adaptor 151y may be harder than the Y-axis interference mirror 140y. For instance, the first Y-axis adaptor 151y may include a metal.

The second Y-axis adaptor 152y may combine the Y-axis distant flexure structure 300 with the Y-axis interference mirror 140y. The Y-axis distant flexure structure 300 may be combined with the Y-axis interference mirror 140y by the second Y-axis adaptor 152y. The second Y-axis adaptor 152y may be disposed between the Y-axis distant flexure structure 300 and the Y-axis interference mirror 140y.

The second Y-axis adaptor 152y may have the same thermal strain characteristics as the Y-axis interference mirror 140y. The second Y-axis adaptor 152y may be harder than the Y-axis interference mirror 140y. The second Y-axis adaptor 152y may include the same material as the first Y-axis adaptor 151y. For instance, the second Y-axis adaptor 152y may include a metal.

The third Y-axis adaptor 153y may combine the Y-axis intermediate flexure structure 400 with the Y-axis interference mirror 140y. The Y-axis intermediate flexure structure 400 may be combined with the Y-axis interference mirror 140y by the third Y-axis adaptor 153y. The third Y-axis adaptor 153y may be disposed between the Y-axis intermediate flexure structure 400 and the Y-axis interference mirror 140y.

The third Y-axis adaptor 153y may have the same thermal strain characteristics as the Y-axis interference mirror 140y. The third Y-axis adaptor 153y may be harder than the Y-axis interference mirror 140y. The third Y-axis adaptor 153y may include the same material as the first Y-axis adaptor 151y. For instance, the third Y-axis adaptor 153y may include a metal.

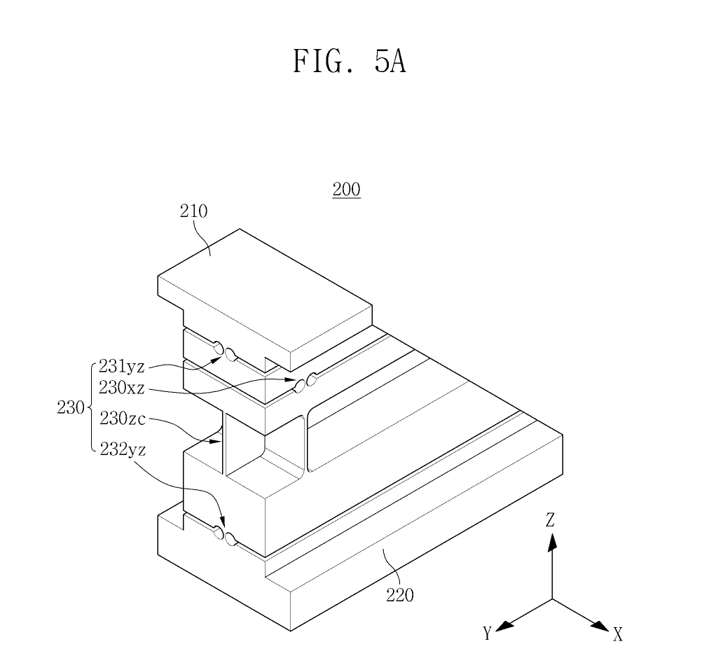

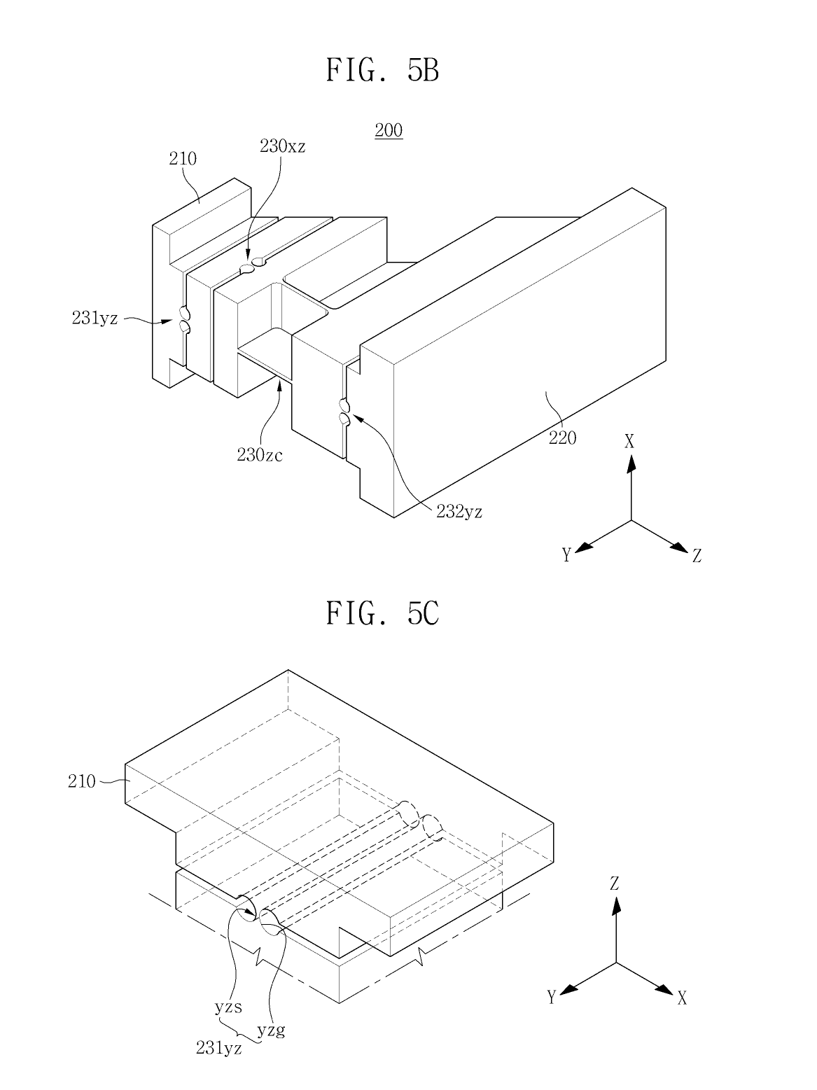

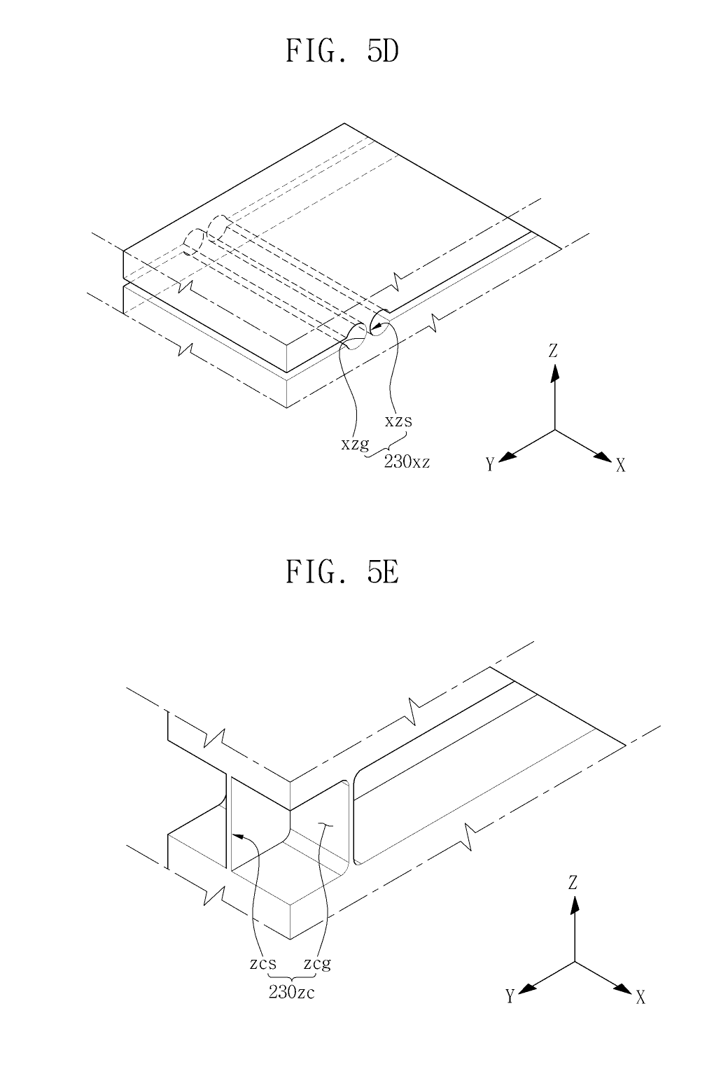

FIGS. 5A and 5B are perspective views of a Y-axis datum flexure structure of a stage device according to an exemplary embodiment of the inventive concept. FIGS. 5C through 5E are partial perspective views of a Y-axis datum flexure structure shown in FIGS. 5A and 5B, according to an exemplary embodiment of the inventive concept.

Referring to FIGS. 4 and 5A through 5E, the Y-axis datum flexure structure 200 of the stage device according to an exemplary embodiment of the inventive concept may include a Y-axis datum upper plate 210, a Y-axis datum lower plate 220, and a Y-axis datum hinge part 230.

The Y-axis datum upper plate 210 may be combined with the Y-axis interference mirror 140y. The Y-axis datum upper plate 210 may be combined with the Y-axis interference mirror 140y by the first Y-axis adaptor 151y.

A Y-axial horizontal length of the Y-axis datum upper plate 210 may be smaller than the Y-axial horizontal length of the Y-axis mirror support 111y. The Y-axial horizontal length of the Y-axis datum upper plate 210 may be smaller than the Y-axial horizontal length of the Y-axis interference mirror 140y. For instance, the Y-axial horizontal length of the Y-axis datum upper plate 210 may be less than or equal to half of the Y-axial horizontal length of the Y-axis interference mirror 140y.

The Y-axis datum lower plate 220 may be combined with the Y-axis mirror support 111y. The Y-axis datum lower plate 220 may support the Y-axis datum upper plate 210 and the Y-axis datum hinge part 230.

The Y-axis datum lower plate 220 may extend in the Y-axis direction. A Y-axial horizontal length of the Y-axis datum lower plate 220 may be greater than the Y-axial horizontal length of the Y-axis datum upper plate 210. The Y-axial horizontal length of the Y-axis datum lower plate 220 may be smaller than the Y-axial horizontal length of the Y-axis mirror support 111y. A Y-axis horizontal length of the Y-axis datum lower plate 220 may be smaller than the Y-axial horizontal length of the Y-axis interference mirror 140y.

The Y-axis datum hinge part 230 may fix the Y-axis datum upper plate 210 in the Y-axis direction and the Z-axis direction. A region vertically overlapping the Y-axis datum upper plate 210 of the Y-axis interference mirror 140y may be fixed by the Y-axis datum hinge part 230 in the Y-axis direction and the Z-axis direction.

The Y-axis datum hinge part 230 may be disposed between the Y-axis datum upper plate 210 and the Y-axis datum lower plate 220. A Y-axis horizontal length of the Y-axis datum hinge part 230 may increase in a direction away from the Y-axis datum upper plate 210. A minimum Y-axial horizontal length of the Y-axis datum hinge part 230 may be equal to the Y-axial horizontal length of the Y-axis datum upper plate 210. A maximum Y-axial horizontal length of the Y-axis datum hinge part 230 may be equal to the Y-axis horizontal length of the Y-axis datum lower plate 220.

The Y-axis datum hinge part 230 may include a first yz Y-axis datum flexure hinge 231yz, an xz Y-axis datum flexure hinge 230xz, a zc Y-axis datum flexure hinge 230zc, and a second yz Y-axis datum flexure hinge 232yz.

The first yz Y-axis datum flexure hinge 231yz may fix the Y-axis datum upper plate 210 in the X-axis direction. A degree of freedom for X-axial motion of the Y-axis datum upper plate 210 may be restricted by the first yz Y-axis datum flexure hinge 231yz. The first yz Y-axis datum flexure hinge 231yz may fix the Y-axis datum upper plate 210 in the Y-axis direction. A degree of freedom for Y-axial motion of the Y-axis datum upper plate 210 may be restricted by the first yz Y-axis datum flexure hinge 231yz. The first yz Y-axis datum flexure hinge 231yz may fix the Y-axis datum upper plate 210 in the Z-axis direction. A degree of freedom for Z-axial motion of the Y-axis datum upper plate 210 may be restricted by the first yz Y-axis datum flexure hinge 231yz. The first yz Y-axis datum flexure hinge 231yz may prevent the Y-axis datum upper plate 210 from rotating about the X-axis. A degree of freedom for the X-axial rotation of the Y-axis datum upper plate 210 may be restricted by the first yz Y-axis datum flexure hinge 231yz. The first yz Y-axis datum flexure hinge 231yz may prevent the Y-axis datum upper plate 210 from rotating about the Z-axis. A degree of freedom for the Z-axial rotation of the Y-axis datum upper plate 210 may be restricted by the first yz Y-axis datum flexure hinge 231yz.

The Y-axis datum upper plate 210 may be rotated about the Y-axis by the first yz Y-axis datum flexure hinge 231yz. The first yz Y-axis datum flexure hinge 231yz might not restrict the degree of freedom for the Y-axial rotation of the Y-axis datum upper plate 210.

The first yz Y-axis datum flexure hinge 231yz may be stacked on the Y-axis datum upper plate 210 in the Z-axis direction. For instance, the first yz Y-axis datum flexure hinge 231yz may be disposed under the Y-axis datum upper plate 210. The first yz Y-axis datum flexure hinge 231yz may be disposed close to the Y-axis datum upper plate 210.

The first yz Y-axis datum flexure hinge 231yz may be a vertical-type flexure hinge extending in the Y-axis direction. As shown in FIG. 5C, the first yz Y-axis datum flexure hinge 231yz may include a yz flexure support yzs and yz flexure grooves yzg.

The yz flexure support yzs may fix the Y-axis datum upper plate 210 in the X-axis direction, the Y-axis direction, and the Z-axis direction. Degrees of freedom for the X-axial motion, Y-axial motion, and Z-axial motion of the Y-axis datum upper plate 210 may be restricted by the yz flexure support yzs. The yz flexure support yzs may prevent the Y-axis datum upper plate 210 from rotating about the X-axis or the Z-axis. Degrees of freedom for the X-axial rotation and Z-axial rotation of the Y-axis datum upper plate 210 may be restricted by the yz flexure support yzs.

The yz flexure support yzs may extend in the same direction as the first yz Y-axis datum flexure hinge 231yz. The yz flexure support yzs may extend in the Y-axis direction. The yz flexure support yzs may be parallel to a plane surface formed by the Y-axis direction and the Z-axis direction.

The yz flexure grooves yzg may provide a space in which the Y-axis datum upper plate 210 may rotate about the Y-axis. The Y-axis datum upper plate 210 may be rotated about the Y-axis by the yz flexure grooves yzg. A degree of freedom for the Y-axial rotation of the Y-axis datum upper plate 210 might not be restricted by the yz flexure grooves yzg.

The yz flexure grooves yzg may be disposed on a side surface of the yz flexure support yzs. The yz flexure grooves yzg may extend in the same direction as the yz flexure support yzs. The yz flexure grooves yzg may extend in the Y-axis direction. The yz flexure grooves yzg may penetrate the Y-axis datum hinge part 230 of the Y-axis datum flexure structure 200 in the Y-axis direction. For instance, the first yz Y-axis datum flexure hinge 231yz may be shaped like i-beams extending in the Y-axis direction.

The yz flexure grooves yzg may extend in the X-axis direction from the side surface of the yz flexure support yzs. The yz flexure grooves yzg may enable a component disposed on the first yz Y-axis datum flexure hinge 231yz and a component disposed under the first yz Y-axis datum flexure hinge 231yz to be connected by the yz flexure support yzs. For instance, the Y-axis datum upper plate 210 may be supported by the yz flexure support yzs.

The xz Y-axis datum flexure hinge 230xz may fix the Y-axis datum upper plate 210 in the X-axis direction, the Y-axis direction, and the Z-axis direction. Degrees of freedom for the X-axial motion, the Y-axial motion, and the Z-axial motion of the Y-axis datum upper plate 210 may be restricted by the xz Y-axis datum flexure hinge 230xz. The xz Y-axis datum flexure hinge 230xz may prevent the Y-axis datum upper plate 210 from rotating about the Y-axis or the Z-axis. Degrees of freedom for the Y-axial rotation and the Z-axial rotation of the Y-axis datum upper plate 210 may be restricted by the xz Y-axis datum flexure hinge 230xz.

The Y-axis datum upper plate 210 may be rotated about the X-axis by the xz Y-axis datum flexure hinge 230xz. The xz Y-axis datum flexure hinge 230xz might not restrict a degree of freedom for the X-axial rotation of the Y-axis datum upper plate 210.

The xz Y-axis datum flexure hinge 230xz may be stacked on the first yz Y-axis datum flexure hinge 231yz in the Z-axis direction. For instance, the xz Y-axis datum flexure hinge 230xz may be disposed under the first yz Y-axis datum flexure hinge 231yz. The first yz Y-axis datum flexure hinge 231yz may be disposed between the Y-axis datum upper plate 210 and the xz Y-axis datum flexure hinge 230xz. The xz Y-axis datum flexure hinge 230xz may be disposed between the first yz Y-axis datum flexure hinge 231yz and the Y-axis datum lower plate 220.

The xz Y-axis datum flexure hinge 230xz may be a vertical-type flexure hinge extending in the X-axis direction. As shown in FIG. SD, the xz Y-axis datum flexure hinge 230xz may include an xz flexure support xzs and xz flexure grooves xzg.

The xz flexure support xzs may fix the Y-axis datum upper plate 210 in the X-axis direction, the Y-axis direction, and the Z-axis direction. Degrees of freedom for X-axial motion, Y-axial motion, and Z-axial motion of the Y-axis datum upper plate 210 may be restricted by the xz flexure support xzs. The xz flexure support xzs may prevent the Y-axis datum upper plate 210 from rotating about the Y-axis or the Z-axis. Degrees of freedom for Y-axial rotation and Z-axial rotation of The Y-axis datum upper plate 210 may be restricted by the xz flexure support xzs.

The xz flexure support xzs may extend in the same direction as the xz Y-axis datum flexure hinge 230xz. The xz flexure support xzs may extend in the X-axis direction. The xz flexure support xzs may be parallel to a plane surface formed by the X-axis direction and the Z-axis direction.

The xz flexure grooves xzg may provide a space in which the Y-axis datum upper plate 210 may rotate about the X-axis. The Y-axis datum upper plate 210 may be rotated about the X-axis by the xz flexure grooves xzg. A degree of freedom for the X-axial rotation of the Y-axis datum upper plate 210 might not be restricted by the xz flexure grooves xzg.

The xz flexure grooves xzg may be disposed on a side surface of the xz flexure support xzs. The xz flexure grooves xzg may extend in the same direction as the xz flexure support xzs. The xz flexure grooves xzg may extend in the X-axis direction. The xz flexure grooves xzg may penetrate the Y-axis datum hinge part 230 of the Y-axis datum flexure structure 200 in the X-axis direction. For example, the xz Y-axis datum flexure hinge 230xz may be shaped like i-beams extending in the X-axis direction.

The xz flexure grooves xzg may extend in the Y-axis direction from the side surface of the xz flexure support xzs. The xz flexure grooves xzg may enable a component disposed on the xz Y-axis datum flexure hinge 230xz and a component disposed under the xz Y-axis datum flexure hinge 230xz to be connected by the xz flexure support xzs. For instance, the first yz Y-axis datum flexure hinge 231yz may be supported by the xz flexure support xzs.

A zc Y-axis datum flexure hinge 230zc may restrict degrees of freedom for the X-axial motion, the Y-axial motion, and the Z-axial motion of the Y-axis datum upper plate 210. The zc Y-axis datum flexure hinge 230zc may restrict degrees of freedom for the X-axial rotation and the Y-axial rotation of the Y-axis datum upper plate 210. The zc Y-axis datum flexure hinge 230zc might not restrict a degree of freedom for the Z-axial rotation of the Y-axis datum upper plate 210.

The zc Y-axis datum flexure hinge 230zc may be stacked on the xz Y-axis datum flexure hinge 230xz in the Z-axis direction. For instance, the zc Y-axis datum flexure hinge 230zc may be located under the xz Y-axis datum flexure hinge 230xz. The xz Y-axis datum flexure hinge 230xz may be disposed between the first yz Y-axis datum flexure hinge 231yz and the zc Y-axis datum flexure hinge 230zc.

The zc Y-axis datum flexure hinge 230zc may be a cross-type flexure hinge extending in the Z-axis direction. As shown in FIG. 5E, the zc Y-axis datum flexure hinge 230zc may include a zc flexure support zcs and zc flexure grooves zcg.

The zc flexure support zcs may restrict degrees of freedom for the X-axial motion, the Y-axial motion, and the Z-axial motion of the Y-axis datum upper plate 210. The zc flexure support zcs may restrict degrees of freedom for the X-axial rotation and the Y-axial rotation of the Y-axis datum upper plate 210.

The zc flexure support zcs may extend on the zc Y-axis datum flexure hinge 230zc in the Z-axis direction. A longitudinal section of the zc flexure support zcs may have a cross shape extending in the X-axis direction and the Y-axis direction.

The zc flexure grooves zcg may provide a space in which the Y-axis datum upper plate 210 may rotate about the Z-axis. The Y-axis datum upper plate 210 may be rotated about the Z-axis by the zc flexure grooves zcg.

The zc flexure grooves zcg may be disposed between the zc flexure supports zcs. The zc flexure grooves zcg may enable a component disposed on the zc Y-axis datum flexure hinge 230zc and a component disposed under the zc Y-axis datum flexure hinge 230zc to be connected by the zc flexure support zcs. For instance, the xz Y-axis datum flexure hinge 230xz may be supported by the zc flexure support zcs.

The second yz Y-axis datum flexure hinge 232yz may restrict degrees of freedom for the X-axial motion, the Y-axial motion, and the Z-axial motion of the Y-axis datum upper plate 210. The second yz Y-axis datum flexure hinge 232yz may restrict degrees of freedom for the X-axial rotation and the Z-axial rotation of the Y-axis datum upper plate 210. The second yz Y-axis datum flexure hinge 232yz might not restrict a degree of freedom for the Y-axial rotation of the Y-axis datum upper plate 210.

The second yz Y-axis datum flexure hinge 232yz may be stacked on the zc Y-axis datum flexure hinge 230zc in the Z-axis direction. The second yz Y-axis datum flexure hinge 232yz may be spaced apart from the first yz Y-axis datum flexure hinge 231yz in the Z-axis direction. For instance, the second yz Y-axis datum flexure hinge 232yz may be disposed under the zc Y-axis datum flexure hinge 230zc. The zc Y-axis datum flexure hinge 230zc may be disposed between the xz Y-axis datum flexure hinge 230xz and the second yz Y-axis datum flexure hinge 232yz.

The second yz Y-axis datum flexure hinge 232yz may be a vertical-type flexure hinge extending in the Y-axis direction. The second yz Y-axis datum flexure hinge 232yz may have the same structure as the first yz Y-axis datum flexure hinge 231yz. For instance, the second yz Y-axis datum flexure hinge 232yz may be shaped like i-beams extending in the Y-axis direction. The second yz Y-axis datum flexure hinge 232yz may include the yz flexure support yzs and the yz flexure grooves yzg.

The Y-axis datum hinge part 230 of the Y-axis datum flexure structure 200 according to an exemplary embodiment of the inventive concept may include a first yz Y-axis datum flexure hinge 231yz, an xz Y-axis datum flexure hinge 230xz, a zc Y-axis datum flexure hinge 230zc, and a second yz Y-axis datum flexure hinge 232yz, which may be stacked in the Z-axis direction. The Y-axis datum upper plate 210 of the Y-axis datum flexure structure 200 may be rotated about the Y-axis by the first yz Y-axis datum flexure hinge 231yz. The Y-axis datum upper plate 210 may be rotated about the X-axis by the xz Y-axis datum flexure hinge 230xz. The Y-axis datum upper plate 210 may be rotated about the Z-axis by the zc Y-axis datum flexure hinge 230zc. The Y-axis datum upper plate 210 may be rotated about the Y-axis by the second yz Y-axis datum flexure hinge 232yz.

The Y-axis datum upper plate 210 of the Y-axis datum flexure structure 200 according to an exemplary embodiment of the inventive concept may be moved in the X-axis direction by the first yz Y-axis datum flexure hinge 231yz and the second yz Y-axis datum flexure hinge 232yz. A degree of freedom for the X-axial motion of the Y-axis datum upper plate 210 might not be restricted by the first yz Y-axis datum flexure hinge 231yz and the second yz Y-axis datum flexure hinge 232yz.

Accordingly, the Y-axis datum hinge part 230 of the stage device according to an exemplary embodiment of the inventive concept may fix the Y-axis datum upper plate 210 in the Y-axis direction and the Z-axis direction. In the Y-axis datum flexure structure 200 of the stage device according to an exemplary embodiment of the inventive concept, the Y-axis datum hinge part 230 may restrict degrees of freedom for the Y-axial motion and the Z-axial motion of the Y-axis datum upper plate 210.

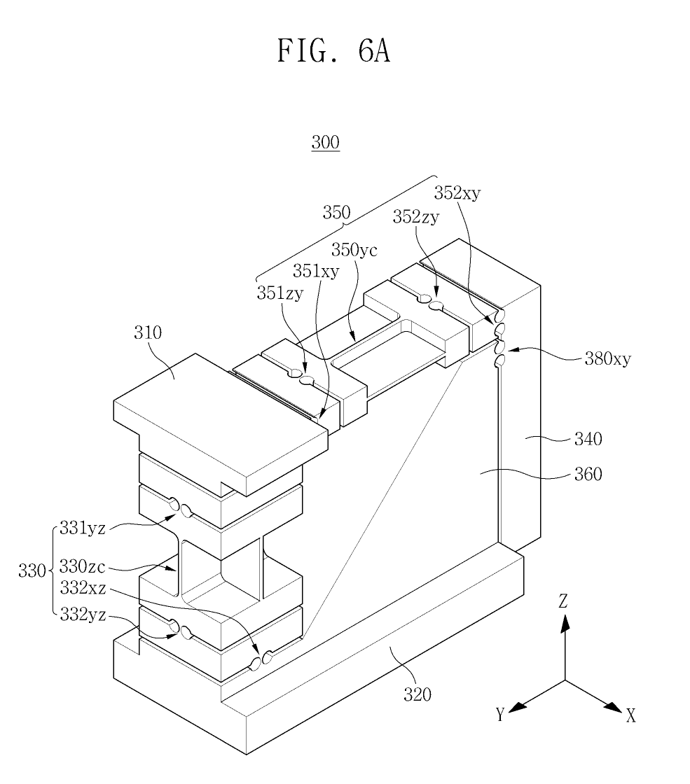

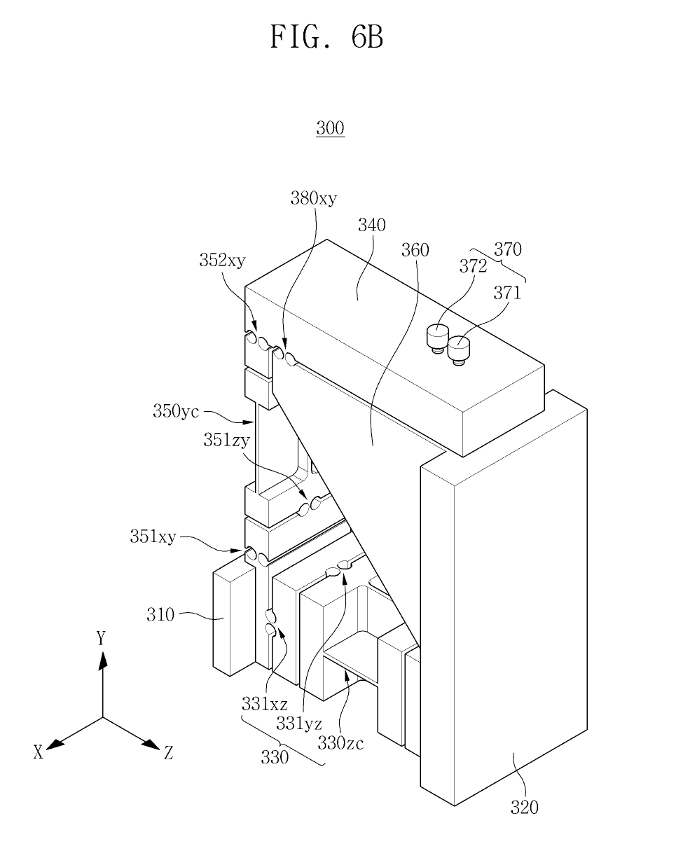

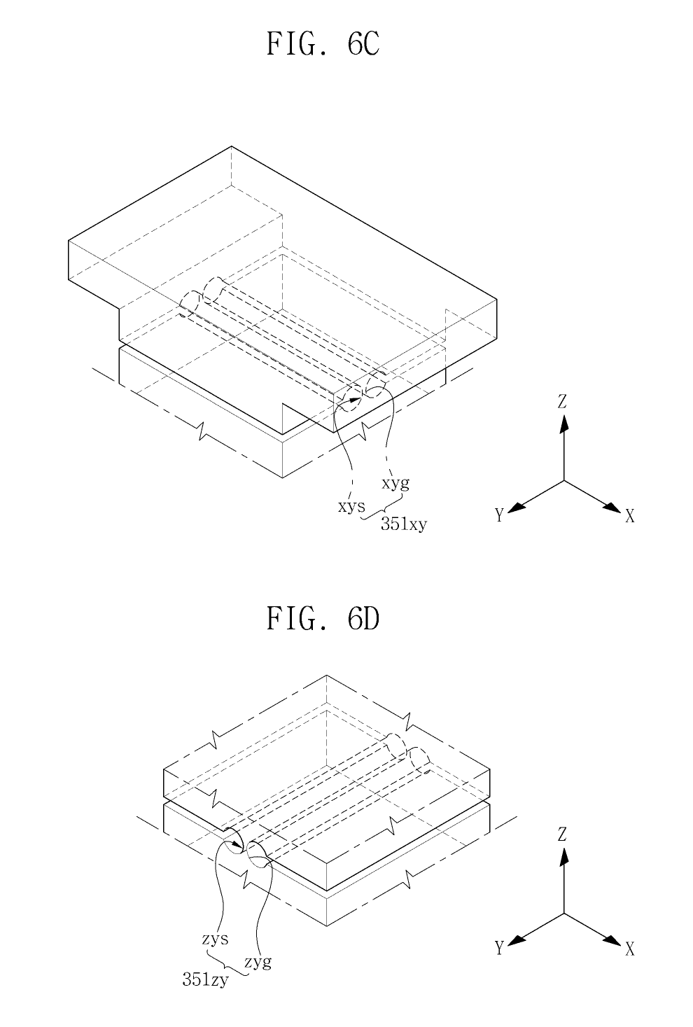

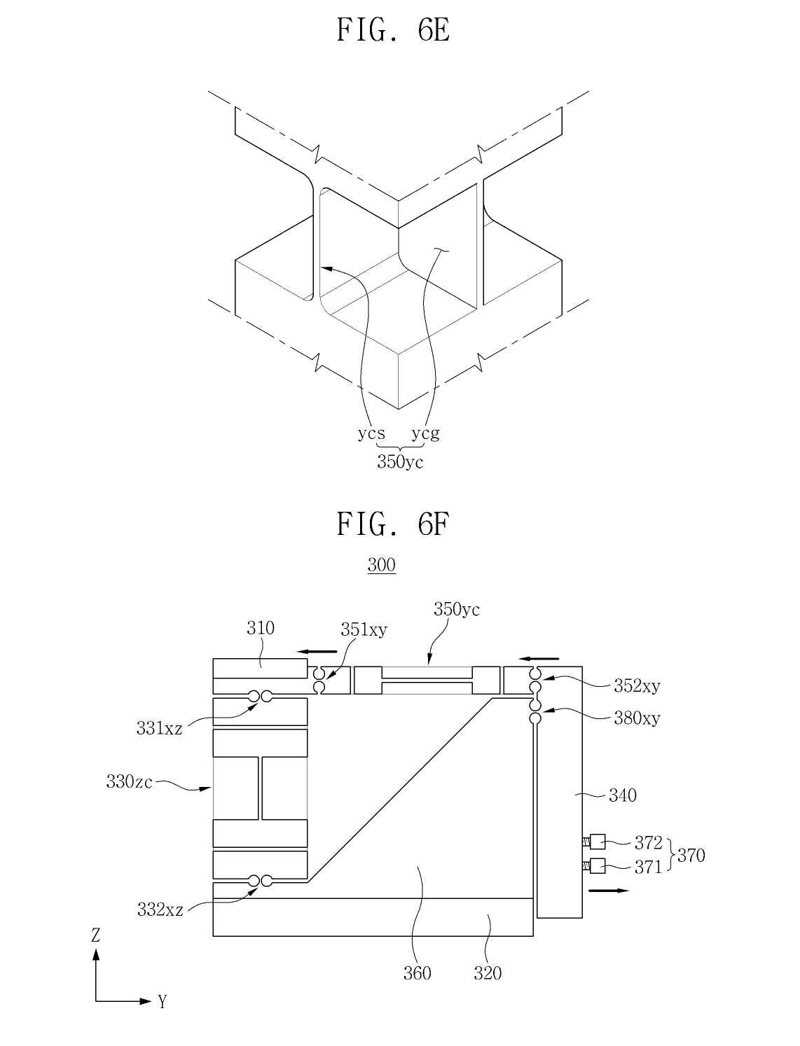

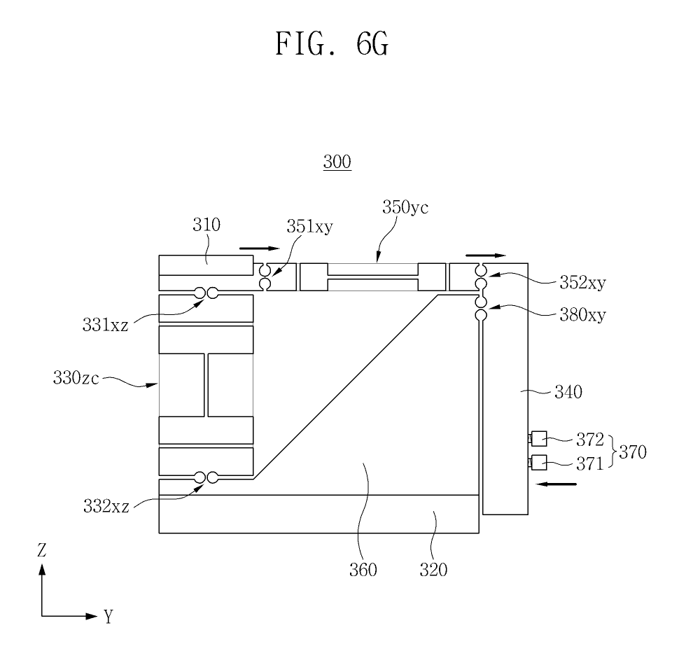

FIGS. 6A and 6B are perspective views of a Y-axis distant flexure structure 300 of a stage device according to an exemplary embodiment of the inventive concept. FIGS. 6C through 6E are partial perspective views of a Y-axis distant flexure structure shown in FIGS. 6A and 6B, according to an exemplary embodiment of the inventive concept. FIGS. 6F and 6G are side views illustrating operations of a Y-axis distant flexure structure shown in FIGS. 6A and 6B, according to an exemplary embodiment of the inventive concept.

Referring to FIGS. 4 and 6A through 6G, the Y-axis distant flexure structure 300 of the stage device according to an exemplary embodiment of the inventive concept may include a Y-axis distant upper plate 310, a Y-axis distant lower plate 320, a first Y-axis distant hinge part 330, a first Y-axis distant body 340, a second Y-axis distant hinge part 350, a second Y-axis distant body 360, a Y-axial rotation control member 370, and an xy Y-axial rotation flexure hinge 380xy.

The Y-axis distant upper plate 310 may be combined with the Y-axis interference mirror 140y. The Y-axis distant upper plate 310 may be combined with the Y-axis interference mirror 140y by the second Y-axis adaptor 152y.

A Y-axial horizontal length of the Y-axis distant upper plate 310 may be smaller than the Y-axial horizontal length of the Y-axis mirror support 111y. The Y-axial horizontal length of the Y-axis distant upper plate 310 may be smaller than the Y-axial horizontal length of the Y-axis interference mirror 140y. The Y-axial horizontal length of the Y-axis distant upper plate 310 may be equal to the Y-axial horizontal length of the Y-axis datum upper plate 210. For instance, the Y-axial horizontal length of the Y-axis distant upper plate 310 may be less than or equal to half of the Y-axial horizontal length of the Y-axis interference mirror 140y.

The Y-axis distant lower plate 320 may be combined with the Y-axis mirror support 111y. The Y-axis distant lower plate 320 may support the Y-axis distant upper plate 310, the first Y-axis distant hinge part 330, and the second Y-axis distant body 360.

The Y-axis distant lower plate 320 may extend in the Y-axis direction. A Y-axial horizontal length of the Y-axis distant lower plate 320 may be greater than the Y-axial horizontal length of the Y-axis distant upper plate 310. The Y-axial horizontal length of the Y-axis distant lower plate 320 may be smaller than the Y-axial horizontal length of the Y-axis mirror support 111y. The Y-axial horizontal length of the Y-axis distant lower plate 320 may be smaller than the Y-axial horizontal length of the Y-axis interference mirror 140y. The Y-axial horizontal length of the Y-axis distant lower plate 320 may be different from the Y-axial horizontal length of the Y-axis datum lower plate 220.

The first Y-axis distant hinge part 330 may fix the Y-axis distant upper plate 310 in the Z-axis direction. A region of the Y-axis interference mirror 140y, which may vertically overlap the Y-axis distant upper plate 310, may be fixed by the first Y-axis distant hinge part 330 in the Z-axis direction.

The first Y-axis distant hinge part 330 may be disposed between the Y-axis distant upper plate 310 and the Y-axis distant lower plate 320. A Y-axial horizontal length of an upper end of the first Y-axis distant hinge part 330 may be equal to a Y-axial horizontal length of a lower end of the first Y-axis distant hinge part 330. For instance, the Y-axial horizontal length of each of the upper and lower ends of the first Y-axis distant hinge part 330 may be equal to the Y-axial horizontal length of the first Y-axis distant upper plate 310.

The first Y-axis distant hinge part 330 may include a first xz Y-axis distant flexure hinge 331xz, a first yz Y-axis distant flexure hinge 331yz, a zc Y-axis distant flexure hinge 330zc, a second yz Y-axis distant flexure hinge 332yz, and a second xz Y-axis distant flexure hinge 332xz.

The first xz Y-axis distant flexure hinge 331xz may restrict degrees of freedom for the X-axial motion, the Y-axial motion, and the Z-axial motion of the Y-axis distant upper plate 310. The first xz Y-axis distant flexure hinge 331xz may restrict degrees of freedom for the Y-axial rotation and the Z-axial rotation of the Y-axis distant upper plate 310. The first xz Y-axis distant flexure hinge 331xz might not restrict a degree of freedom for the X-axial rotation of the Y-axis distant upper plate 310.

The first xz Y-axis distant flexure hinge 331xz may be stacked on the Y-axis distant upper plate 310 in the Z-axis direction. For instance, the first xz Y-axis distant flexure hinge 331xz may be disposed under the Y-axis distant upper plate 310. The first xz Y-axis distant flexure hinge 331xz may be disposed close to the Y-axis distant upper plate 310.

The first xz Y-axis distant flexure hinge 331xz may be a vertical-type flexure hinge extending in the X-axis direction. The first xz Y-axis distant flexure hinge 331xz may be parallel to the xz Y-axis datum flexure hinge 230xz shown in FIGS. 5A and 5B. The first xz Y-axis distant flexure hinge 331xz may have substantially the same structure as the xz Y-axis datum flexure hinge 230xz shown in FIG. 5D. For instance, the first xz Y-axis distant flexure hinge 331xz may be shaped like i-beams extending in the X-axis direction. The first xz Y-axis distant flexure hinge 331xz may include the xz flexure support xzs and xz flexure grooves xzg shown in FIG. 5D.

The first yz Y-axis distant flexure hinge 331yz may restrict degrees of freedom for the X-axial motion, the Y-axial motion, and the Z-axial motion of the Y-axis distant upper plate 310. The first yz Y-axis distant flexure hinge 331yz may restrict degrees of freedom for the X-axial rotation and the Z-axial rotation of the Y-axis distant upper plate 310. The first yz Y-axis distant flexure hinge 331yz might not restrict a degree of freedom for the Y-axial rotation of the Y-axis distant upper plate 310.

The first yz Y-axis distant flexure hinge 331yz may be stacked on the first xz Y-axis distant flexure hinge 331xz in the Z-axis direction. For instance, the first yz Y-axis distant flexure hinge 331yz may be disposed under the first xz Y-axis distant flexure hinge 331xz. The first xz Y-axis distant flexure hinge 331xz may be disposed between the Y-axis distant upper plate 310 and the first yz Y-axis distant flexure hinge 331yz.

The first yz Y-axis distant flexure hinge 331yz may be a vertical-type flexure hinge extending in the Y-axis direction. The first yz Y-axis distant flexure hinge 331yz may be parallel to the first yz Y-axis datum flexure hinge 231yz shown in FIGS. 5A and 5B. The first yz Y-axis distant flexure hinge 331yz may have substantially the same structure as the first yz Y-axis datum flexure hinge 231yz shown in FIG. 5C. For instance, the first yz Y-axis distant flexure hinge 331yz may be shaped like i-beams extending in the Y-axis direction. The first yz Y-axis distant flexure hinge 331yz may include the yz flexure support yzs and yz flexure grooves yzg shown in FIG. 5C.

The zc Y-axis distant flexure hinge 330zc may restrict degrees of freedom for the X-axial motion, the Y-axial motion, and the Z-axial motion of the Y-axis distant upper plate 310. The zc Y-axis distant flexure hinge 330zc may restrict degrees of freedom for the X-axial rotation and the Y-axial rotation of the Y-axis distant upper plate 310. The zc Y-axis distant flexure hinge 330zc might not restrict a degree of freedom for the Z-axial rotation of the Y-axis distant upper plate 310.

The zc Y-axis distant flexure hinge 330zc may be stacked on the first yz Y-axis distant flexure hinge 331yz in the Z-axis direction. For instance, the zc Y-axis distant flexure hinge 330zc may be disposed under the first yz Y-axis distant flexure hinge 331yz. The first yz Y-axis distant flexure hinge 331yz may be disposed between the first xz Y-axis distant flexure hinge 331xz and the zc Y-axis distant flexure hinge 330zc.

The zc Y-axis distant flexure hinge 330zc may be a cross-type flexure hinge extending in the Z-axis direction. The zc Y-axis distant flexure hinge 330zc may be parallel to the zc Y-axis datum flexure hinge 230zc shown in FIGS. 5A and 5B. The zc Y-axis distant flexure hinge 330zc may have substantially the same structure as the zc Y-axis datum flexure hinge 230zc shown in FIG. 5E. For instance, the zc Y-axis distant flexure hinge 330zc may include the zc flexure support zcs and zc flexure grooves zcg shown in FIG. 5E.

The second yz Y-axis distant flexure hinge 332yz may restrict degrees of freedom for the X-axial motion, the Y-axial motion, and the Z-axial motion of the Y-axis distant upper plate 310. The second yz Y-axis distant flexure hinge 332yz may restrict degrees of freedom for the X-axial rotation and the Z-axial rotation of the Y-axis distant upper plate 310. The second yz Y-axis distant flexure hinge 332yz might not restrict a degree of freedom for the Y-axial rotation of the Y-axis distant upper plate 310.

The second yz Y-axis distant flexure hinge 332yz may be stacked on the zc Y-axis distant flexure hinge 330zc in the Z-axis direction. The second yz Y-axis distant flexure hinge 332yz may be spaced apart from the first yz Y-axis distant flexure hinge 331yz in the Z-axis direction. For instance, the second yz Y-axis distant flexure hinge 332yz may be disposed under the zc Y-axis distant flexure hinge 330zc. The zc Y-axis distant flexure hinge 330zc may be disposed between the first yz Y-axis distant flexure hinge 331yz and the second yz Y-axis distant flexure hinge 332yz.

The second yz Y-axis distant flexure hinge 332yz may be a vertical-type flexure hinge extending in the Y-axis direction. The second yz Y-axis distant flexure hinge 332yz may be parallel to the second yz Y-axis datum flexure hinge 232yz shown in FIGS. 5A and 5B. The second yz Y-axis distant flexure hinge 332yz may have substantially the same structure as the first yz Y-axis distant flexure hinge 331yz. The second yz Y-axis distant flexure hinge 332yz may have substantially the same structure as the first yz Y-axis datum flexure hinge 231yz shown in FIG. 5C. For instance, the second yz Y-axis distant flexure hinge 332 may be shaped like i-beams extending in the Y-axis direction. The second yz Y-axis distant flexure hinge 332yz may include the yz flexure support yzs and yz flexure grooves yzg shown in FIG. 5C.

The second xz Y-axis distant flexure hinge 332xz may restrict degrees of freedom for the X-axial motion, the Y-axial motion, and the Z-axial motion of the Y-axis distant upper plate 310. The second xz Y-axis distant flexure hinge 332xz may restrict degrees of freedom for the Y-axial rotation and the Z-axial rotation of the Y-axis distant upper plate 310. The second xz Y-axis distant flexure hinge 332xz might not restrict a degree of freedom for the X-axial rotation of the Y-axis distant upper plate 310.

The second xz Y-axis distant flexure hinge 332xz may be stacked on the second yz Y-axis distant flexure hinge 332yz in the Z-axis direction. The second xz Y-axis distant flexure hinge 332xz may be spaced apart from the first xz Y-axis distant flexure hinge 331xz in the Z-axis direction. For instance, the second xz Y-axis distant flexure hinge 332xz may be disposed under the second yz Y-axis distant flexure hinge 332yz. The second xz Y-axis distant flexure hinge 332xz may be disposed between the second yz Y-axis distant flexure hinge 332yz and the Y-axis distant lower plate 320.

The second xz Y-axis distant flexure hinge 332xz may be a vertical-type flexure hinge extending in the X-axis direction. The second xz Y-axis distant flexure hinge 332xz may have substantially the same structure as the first xz Y-axis distant flexure hinge 331xz. The second xz Y-axis distant flexure hinge 332xz may have substantially the same structure as the xz Y-axis datum flexure hinge 230xz shown in FIGS. 5A and 5B. For instance, the second xz Y-axis distant flexure hinge 332xz may be shaped like i-beams extending in the X-axis direction. The second xz Y-axis distant flexure hinge 332xz may include the xz flexure support xzs and xz flexure grooves xzg shown in FIG. 5D.

The first Y-axis distant hinge part 330 of the Y-axis distant flexure structure 300 according to an exemplary embodiment of the inventive concept may include a first xz Y-axis distant flexure hinge 331xz, a first yz Y-axis distant flexure hinge 331yz, a zc Y-axis distant flexure hinge 330zc, a second yz Y-axis distant flexure hinge 332yz, and a second xz Y-axis distant flexure hinge 332xz, which may be stacked in the Z-axis direction. The Y-axis distant upper plate 310 of the Y-axis distant flexure structure 300 may be rotated about the X-axis by the first xz Y-axis distant flexure hinge 331xz. The Y-axis distant upper plate 310 may be rotated about the Y-axis by the first yz Y-axis distant flexure hinge 331yz. The Y-axis distant upper plate 310 may be rotated about the Z-axis by the zc Y-axis distant flexure hinge 330zc. The Y-axis distant upper plate 310 may be rotated about the Y-axis by the second yz Y-axis distant flexure hinge 332yz. The Y-axis distant upper plate 310 may be rotated about the X-axis by the second xz Y-axis distant flexure hinge 332xz.

In addition, the Y-axis distant upper plate 310 of the Y-axis distant flexure structure 300 according to an exemplary embodiment of the inventive concept may be moved in the X-axis direction by the first yz Y-axis distant flexure hinge 331yz and the second yz Y-axis distant flexure hinge 332yz. A degree of freedom for the X-axial motion of the Y-axis distant upper plate 310 might not be restricted by the first yz Y-axis distant flexure hinge 331yz and the second yz Y-axis distant flexure hinge 332yz.

Furthermore, the Y-axis distant upper plate 310 of the Y-axis distant flexure structure 300 according to an exemplary embodiment of the inventive concept may be moved in the Y-axis direction by the first xz Y-axis distant flexure hinge 331xz and the second xz Y-axis distant flexure hinge 332xz. A degree of freedom for the Y-axial motion of the Y-axis distant upper plate 310 might not be restricted by the first xz Y-axis distant flexure hinge 331xz and the second xz Y-axis distant flexure hinge 332xz.

Accordingly, the first Y-axis distant hinge part 330 of the stage device according to an exemplary embodiment of the inventive concept may fix the Y-axis distant upper plate 310 in the Z-axis direction. In the Y-axis distant flexure structure 300 of the stage device according to an exemplary embodiment of the inventive concept, the first Y-axis distant hinge part 330 may restrict a degree of freedom for the Z-axial motion of the Y-axis distant upper plate 310.

The first Y-axis distant body 340 may be spaced apart from the first Y-axis distant hinge part 330 in the Y-axis direction. The first Y-axis distant body 340 may be spaced apart from the Y-axis distant lower plate 320.

The first Y-axis distant body 340 may extend in the Z-axis direction. A bottom surface of the first Y-axis distant body 340 may be positioned at a higher level than a bottom surface of the Y-axis distant lower plate 320. The bottom surface of the first Y-axis distant body 340 may be positioned at a lower level than a bottom surface of the first Y-axis distant hinge part 330. A top surface of the first Y-axis distant body 340 may be positioned at a lower level than a top surface of the Y-axis distant upper plate 310. The top surface of the first Y-axis distant body 340 may be positioned at a lower level than a top surface of the first Y-axis distant hinge part 330.

The second Y-axis distant hinge part 350 may fix the Y-axis distant upper plate 310 in the Y-axis direction. A region of the Y-axis interference mirror 140y, which may vertically overlap the Y-axis distant upper plate 310, may be fixed by the second Y-axis distant hinge part 350 in the Y-axis direction.

The second Y-axis distant hinge part 350 may be disposed between the first Y-axis distant hinge part 330 and the first Y-axis distant body 340. For instance, the second Y-axis distant hinge part 350 may be disposed between the upper end of the first Y-axis distant hinge part 330 and an upper end of the first Y-axis distant body 340. A Y-axial horizontal length of the second Y-axis distant hinge part 350 may be equal to a Y-axial horizontal distance between the first Y-axis distant hinge part 330 and the first Y-axis distant body 340.

The second Y-axis distant hinge part 350 may include a first xy Y-axis distant flexure hinge 351xy, a first zy Y-axis distant flexure hinge 351zy, a yc Y-axis distant flexure hinge 350yc, a second zy Y-axis distant flexure hinge 352zy, and a second xy Y-axis distant flexure hinge 352xy.

The first xy Y-axis distant flexure hinge 351xy may restrict degrees of freedom for the X-axial motion, the Y-axial motion, the Z-axial motion, the Y-axial rotation, and the Z-axial rotation of the Y-axis distant upper plate 310. The first xy Y-axis distant flexure hinge 351xy might not restrict a degree of freedom for the X-axial rotation of the Y-axis distant upper plate 310.

The first xy Y-axis distant flexure hinge 351xy may be stacked on the Y-axis distant upper plate 310 in the Y-axis direction. For instance, the first xy Y-axis distant flexure hinge 351xy may be stacked on a lower end of the Y-axis distant upper plate 310 in the Y-axis direction. The first xy Y-axis distant flexure hinge 351xy may be disposed close to the Y-axis distant upper plate 310. The first xy Y-axis distant flexure hinge 351xy may be disposed on an xz flexure support of the first xz Y-axis distant flexure hinge 331xz.

The first xy Y-axis distant flexure hinge 351xy may be a horizontal-type flexure hinge extending in the X-axis direction. As shown in FIG. 6C, the first xy Y-axis distant flexure hinge 351xy may include an xy flexure support xys and xy flexure grooves xyg.

The xy flexure support xys may restrict degrees of freedom for the X-axial motion, the Y-axial motion, the Z-axial motion, the Y-axial rotation, and the Z-axial rotation of the Y-axial distant upper plate 310.

The xy flexure support xys may extend in the X-axis direction. The xy flexure support xys may be parallel to a plane surface formed by the X-axis direction and the Y-axis direction.

The xy flexure grooves xyg may provide a space in which the Y-axis distant upper plate 310 may rotate about the X-axis. The Y-axis distant upper plate 310 may be rotated about the X-axis by the xy flexure grooves xyg.

The xy flexure grooves xyg may be disposed at upper and lower portions of the xy flexure support xys. The xy flexure grooves xyg may extend in the X-axis direction. The xy flexure grooves xyg may penetrate the second Y-axis distant hinge part 350 of the Y-axis distant flexure structure 300 in the X-axis direction. For instance, the first xy Y-axis distant flexure hinge 351xy may be shaped like H-beams extending in the X-axis direction.

The xy flexure grooves xyg may extend from the xy flexure support xys in the Z-axis direction. The xy flexure grooves xyg may enable components disposed on side surfaces of the first xy Y-axis distant flexure hinge 351xy to be connected by the xy flexure support xys. For instance, a side surface of the Y-axis distant upper plate 310 may be connected to the xy flexure support xys.

The first zy Y-axis distant flexure hinge 351zy may restrict degrees of freedom for the X-axial motion, the Y-axial motion, the Z-axial motion, the X-axial rotation, and the Y-axial rotation of the Y-axis distant upper plate 310. The first zy Y-axis distant flexure hinge 351zy might not restrict a degree of freedom for the Z-axial rotation of the Y-axis distant upper plate 310.

The first zy Y-axis distant flexure hinge 351zy may be stacked on the first xy Y-axis distant flexure hinge 351xy in the Y-axis direction. For instance, the first xy Y-axis distant flexure hinge 351xy may be disposed between the Y-axis distant upper plate 310 and the first zy Y-axis distant flexure hinge 351zy.

The first zy Y-axis distant flexure hinge 351zy may be a Y-axial flexure hinge extending in the Z-axis direction. As shown in FIG. 6D, the first zy Y-axis distant flexure hinge 351zy may include a zy flexure support zys and zy flexure grooves zyg.

The zy flexure support zys may restrict degrees of freedom for the X-axial motion, the Y-axial motion, the Z-axial motion, the X-axial rotation, and the Y-axial rotation of the Y-axis distant upper plate 310.

The zy flexure support zys may extend in the Z-axis direction. The zy flexure support zys may be parallel to a plane surface formed by the Y-axis direction and the Z-axis direction.

The zy flexure grooves zyg may provide a space in which the Y-axis distant upper plate 310 may rotate about the Z-axis. The Y-axis distant upper plate 310 may be rotated about the Z-axis by the zy flexure grooves zyg.

The zy flexure grooves zyg may be disposed on side surfaces of the zy flexure support zys. The zy flexure grooves zyg may extend in the Z-axis direction. The zy flexure grooves zyg may penetrate the second Y-axis distant hinge part 350 of the Y-axis distant flexure structure 300 in the Z-axis direction. For instance, the first zy Y-axis distant flexure hinge 351zy may be shaped like i-beams extending in the Z-axis direction.

The zy flexure grooves zyg may extend in the X-axis direction from the side surfaces of the zy flexure support zys. The zy flexure grooves zyg may enable components disposed on side surfaces of the first zy Y-axis distant flexure hinge 351zy to be connected by the zy flexure support zys.

The yc Y-axis distant flexure hinge 350yc may restrict degrees of freedom for the X-axial motion, the Y-axial motion, the Z-axial motion, the X-axial rotation, and the Z-axial rotation of the Y-axis distant upper plate 310. The yc Y-axis distant flexure hinge 350yc might not restrict a degree of freedom for the Y-axial rotation of the Y-axis distant upper plate 310.

The yc Y-axis distant flexure hinge 350yc may be stacked on the first zy Y-axis distant flexure hinge 351zy in the Y-axis direction. For instance, the first zy Y-axis distant flexure hinge 351zy may be disposed between the first xy Y-axis distant flexure hinge 351xy and the yc Y-axis distant flexure hinge 350yc.

The yc Y-axis distant flexure hinge 350yc may have a cross-type flexure hinge extending in the Y-axis direction. As shown in FIG. 6E, the yc Y-axis distant flexure hinge 350yc may include a yc flexure support ycs and yc flexure grooves ycg.

The yc flexure support ycs may restrict degrees of freedom for the X-axial motion, the Y-axial motion, the Z-axial motion, the X-axial rotation, and the Z-axial rotation of the Y-axis distant upper plate 310.

The yc flexure support ycs may extend in the Y-axis direction. A cross section of the yc flexure support ycs may have a cross shape extending in the X-axis direction and the Z-axis direction.

The yc flexure grooves ycg may provide a space in which the Y-axis distant upper plate 310 may rotate about the Y-axis. The Y-axis distant upper plate 310 may be rotated about the Y-axis by the yc flexure grooves ycg.

The yc flexure grooves ycg may be disposed between the yc flexure supports ycs. The yc flexure grooves ycg may enable components disposed on side surfaces of the yc Y-axis distant flexure hinge 350yc to be connected by the yc flexure support ycs.

The second zy Y-axis distant flexure hinge 352zy may restrict degrees of freedom for the X-axial motion, the Y-axial motion, the Z-axial motion, the X-axial rotation and the Y-axial rotation of the Y-axis distant upper plate 310. The second zy Y-axis distant flexure hinge 352zy might not restrict a degree of freedom for the Z-axial rotation of the Y-axis distant upper plate 310.

The second zy Y-axis distant flexure hinge 352zy may be stacked on the yc Y-axis distant flexure hinge 350yc in the Y-axis direction. For instance, the yc Y-axis distant flexure hinge 350yc may be disposed between the first zy Y-axis distant flexure hinge 351zy and the second zy Y-axis distant flexure hinge 352zy.

The second zy Y-axis distant flexure hinge 352zy may be a Y-axis flexure hinge extending in the Z-axis direction. The second zy Y-axis distant flexure hinge 352zy may have substantially the same structure as the first Y-axis distant flexure hinge 351zy. For instance, the second zy Y-axis distant flexure hinge 352zy may be shaped like i-beams extending in the Z-axis direction. The second zy Y-axis distant flexure hinge 352zy may include the zy flexure support zys and the zy flexure grooves zyg.

The second xy Y-axis distant flexure hinge 352xy may restrict degrees of freedom for the X-axial motion, the Y-axial motion, the Z-axial motion, the Y-axial rotation, and the Z-axial rotation of the Y-axis distant upper plate 310. The second xy Y-axis distant flexure hinge 352xy might not restrict a degree of freedom for the X-axial rotation of the Y-axis distant upper plate 310.

The second xy Y-axis distant flexure hinge 352xy may be stacked on the second zy Y-axis distant flexure hinge 352zy in the Y-axis direction. For instance, the second zy Y-axis distant flexure hinge 352zy may be disposed between the yc Y-axis distant flexure hinge 350yc and the second xy Y-axis distant flexure hinge 352xy.

The second xy Y-axis distant flexure hinge 352xy may be a horizontal-type flexure hinge extending in the X-axis direction. The second xy Y-axis distant flexure hinge 352xy may have substantially the same structure as the first xy Y-axis distant flexure hinge 351xy. For instance, the second xy Y-axis distant flexure hinge 352xy may be shaped like H-beams extending in the X-axis direction. The second xy Y-axis distant flexure hinge 352xy may include the xy flexure support xys and the xy flexure grooves xyg.

The second Y-axis distant hinge part 350 of the Y-axis distant flexure structure 300 according to an exemplary embodiment of the inventive concept may include a first xy Y-axis distant flexure hinge 351xy, a first zy Y-axis distant flexure hinge 351zy, a yc Y-axis distant flexure hinge 350yc, a second zy Y-axis distant flexure hinge 352zy, and a second xy Y-axis distant flexure hinge 352xy, which may be stacked in the Y-axis direction. The Y-axis distant upper plate 310 of the Y-axis distant flexure structure 300 may be rotated about the X-axis by the first xy Y-axis distant flexure hinge 351xy. The Y-axis distant upper plate 310 may be rotated about the Z-axis by the first zy Y-axis distant flexure hinge 351zy. The Y-axis distant upper plate 310 may be rotated about the Y-axis by the yc Y-axis distant flexure hinge 350yc. The Y-axis distant upper plate 310 may be rotated about the Z-axis by the second zy Y-axis distant flexure hinge 352zy. The Y-axis distant upper plate 310 may be rotated about the X-axis by the second xy Y-axis distant flexure hinge 352xy.

The Y-axis distant upper plate 310 of the Y-axis distant flexure structure 300 according to an exemplary embodiment of the inventive concept may be moved in the X-axis direction by the first zy Y-axis distant flexure hinge 351zy and the second zy Y-axis distant flexure hinge 352zy. A degree of freedom for the X-axial motion of the Y-axis distant upper plate 310 might not be restricted by the first zy Y-axis distant flexure hinge 351zy and the second zy Y-axis distant flexure hinge 352zy.

The Y-axis distant upper plate 310 of the Y-axis distant flexure structure 300 according to an exemplary embodiment of the inventive concept may be moved in the Z-axis direction by the first xy Y-axis distant flexure hinge 351xy and the second xy Y-axis distant flexure hinge 352xy. A degree of freedom for the Z-axial motion of the Y-axis distant upper plate 310 might not be restricted by the first xy Y-axis distant flexure hinge 351xy and the second xy Y-axis distant flexure hinge 352xy.

Accordingly, the second Y-axis distant hinge part 350 of the stage device according to an exemplary embodiment of the inventive concept may fix the Y-axis distant upper plate 310 in the Y-axis direction. For example, in the Y-axis distant flexure structure 300 of the stage device according to an exemplary embodiment of the inventive concept, the second Y-axis distant hinge part 350 may restrict a degree of freedom for the Y-axial motion of the Y-axis distant upper plate 310.

The second Y-axis distant body 360 may be disposed between the first Y-axis distant hinge part 330 and the first Y-axis distant body 340. The second Y-axis distant body 360 may be disposed under the second Y-axis distant hinge part 350. The second Y-axis distant body 360 may be fixed onto the Y-axis distant lower plate 320.

A top surface of the second Y-axis distant body 360 may be positioned at a lower level than a top surface of the first Y-axis distant body 340. The second Y-axis distant body 360 may be disposed close to the first Y-axis distant body 340.

A side surface of the second Y-axis distant body 360, which may be opposite the first Y-axis distant body 340, may be vertically aligned with a side surface of the Y-axis distant lower plate 320. A side surface of the second Y-axis distant body 360, which may face the first Y-axis distant hinge part 330, may be inclined. For instance, a Y-axial horizontal length of the second Y-axis distant body 360 may be reduced in a direction away from the Y-axis distant lower plate 320.

The Y-axial rotation control member 370 may regulate a space between the first Y-axis distant body 340 and the second Y-axis distant body 360. The Y-axial rotation control member 370 may be disposed at a lower end of the first Y-axis distant body 340. The Y-axial rotation control member 370 may include a Y-axis distant spacing member 371 and a Y-axis distant fixing member 372.

The Y-axis distant spacing member 371 may move the first Y-axis distant body 340 from the second Y-axis distant body 360. A Y-axial horizontal distance between the first Y-axis distant body 340 and the second Y-axis distant body 360 may be regulated by the Y-axis distant spacing member 371.

The Y-axis distant fixing member 372 may fix a position of the first Y-axis distant body 340. A Y-axial horizontal distance between the first Y-axis distant body 340 and the second Y-axis distant body 360 may be maintained by the Y-axis distant fixing member 372.

The xy Y-axial rotation flexure hinge 380xy may connect the first Y-axis distant body 340 and the second Y-axis distant body 360. The first Y-axis distant body 340 may be connected to the second Y-axis distant body 360 by the xy Y-axial rotation flexure hinge 380xy.

The xy Y-axial rotation flexure hinge 380xy may be disposed between an upper end of the second Y-axis distant body 360 and the first Y-axis distant body 340. The xy Y-axial rotation flexure hinge 380xy may be disposed on the Y-axial rotation control member 370. For instance, the xy Y-axial rotation flexure hinge 380xy may be disposed under the second xy Y-axis distant flexure hinge 352xy of the second Y-axis distant hinge part 350.

The xy Y-axial rotation flexure hinge 380xy may be a horizontal-type flexure hinge extending in the X-axis direction. The xy Y-axial rotation flexure hinge 380xy may have substantially the same structure as the first xy Y-axis distant flexure hinge 351xy. For instance, the xy Y-axial rotation flexure hinge 380xy may be shaped like H-beams extending in the X-axis direction. The xy Y-axial rotation flexure hinge 380xy may include the xy flexure support xys and the xy flexure grooves xyg.

In the Y-axis distant flexure structure 300 of the stage device according to an exemplary embodiment of the inventive concept, when a space between the first Y-axis distant body 340 and the second Y-axis distant body 360 is regulated by the Y-axial rotation control member 370, the Y-axis distant upper plate 310 and the second Y-axis distant hinge part 350 may be moved in the Y-axis direction by the first Y-axis distant body 340.

FIG. 6F is a side view illustrating operations when a space between a first Y-axis distant body 340 and a second Y-axis distant body 360 of a Y-axis distant flexure structure 300 according to an exemplary embodiment of the inventive concept is increased by the Y-axial rotation control member 370.

Referring to FIGS. 4 and 6F, when the lower end of the first Y-axis distant body 340 becomes away from the second Y-axis distant body 360 by the Y-axial rotation control member 370, the first Y-axis distant body 340 may be rotated about the X-axis by the xy Y-axial rotation flexure hinge 380xy. Thus, the upper end of the first Y-axis distant body 340 may push the second Y-axis distant hinge part 350 in the Y-axis direction. For example, the second Y-axis distant hinge part 350 may be moved by the first Y-axis distant body 340 toward the first side surface ys1 of the Y-axis mirror support 111y.

The first Y-axis distant body 340 may be connected with the second xy Y-axial distant flexure hinge 352xy of the second Y-axis distant hinge part 350. The second Y-axis distant hinge part 350 may move in the Y-axis direction without moving the second Y-axis distant hinge part 350 in the X-axis or the Z-axis direction.

The Y-axis distant upper plate 310 may be moved by the second Y-axis distant hinge part 350 toward the first side surface ys1 of the Y-axis mirror support 111y. The Y-axis distant upper plate 310 may be moved by the first Y-axis distant body 340 toward the first side surface ys1 of the Y-axis mirror support 111y.

FIG. 6G is a side view illustrating operations when a space between the first Y-axis distant body 340 and the second Y-axis distant body 360 of the Y-axis distant flexure structure 300 according to an exemplary embodiment of the inventive concept is reduced by the Y-axial rotation control member 370.

Referring to FIGS. 4 and 6F, when a space between the first Y-axis distant body 340 and the second Y-axis distant body 360 is reduced by the Y-axial rotation control member 370, the xy Y-axial rotation flexure hinge 380xy may be rotated about the X-axis by the first Y-axis distant body 340. Thus, the upper end of the first Y-axis distant body 340 may pull the second Y-axis distant hinge part 350 in the Y-axis direction. For example, the second Y-axis distant hinge part 350 may be moved by the first Y-axis distant body 340 toward the second side surface ys2 of the Y-axis mirror support 111y. Since the second Y-axis distant hinge part 350 fixes the Y-axis distant upper plate 310 in the Y-axis direction, the Y-axis distant upper plate 310 may be moved on the second Y-axis distant hinge part 350 by the first Y-axis distant body 340 toward the second side surface ys2 of the Y-axis mirror support 111y.

Since the Y-axis distant upper plate 310 is combined with the Y-axis interference mirror 140y, a region of the Y-axis interference mirror 140y, which may be combined with the Y-axis distant upper plate 310, may be moved by the first Y-axis distant body 340 toward the first side surface ys1 of the Y-axis mirror support 111y. Accordingly, the Y-axis interference mirror 140y may be rotated about the Z-axis by the Y-axial rotation control member 370.

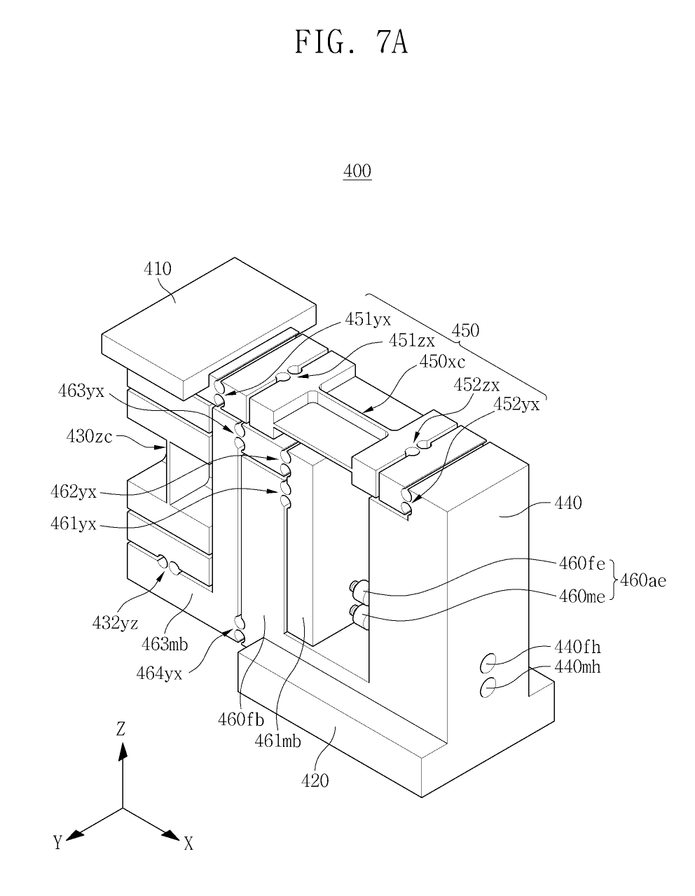

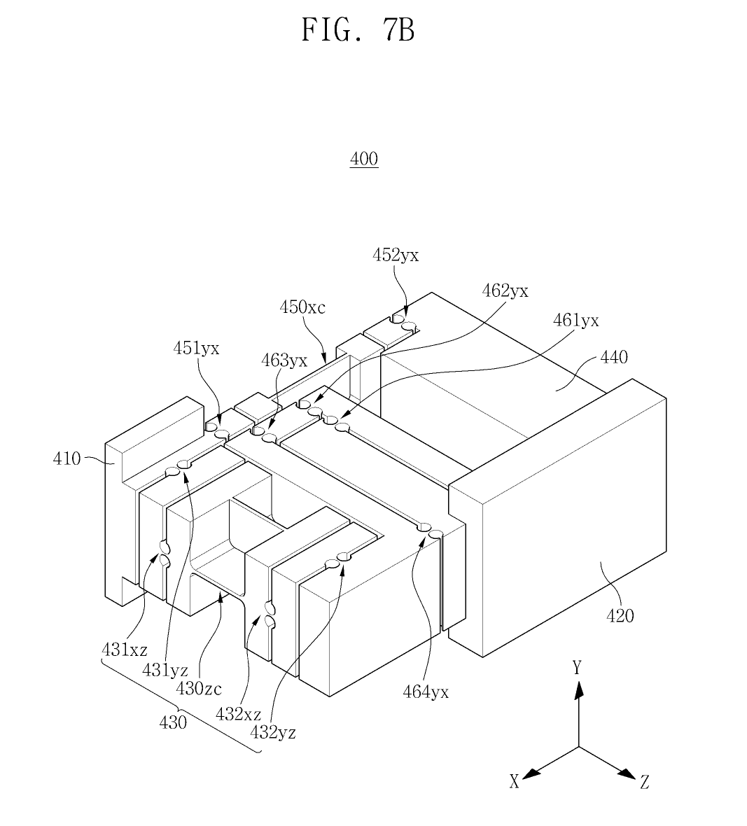

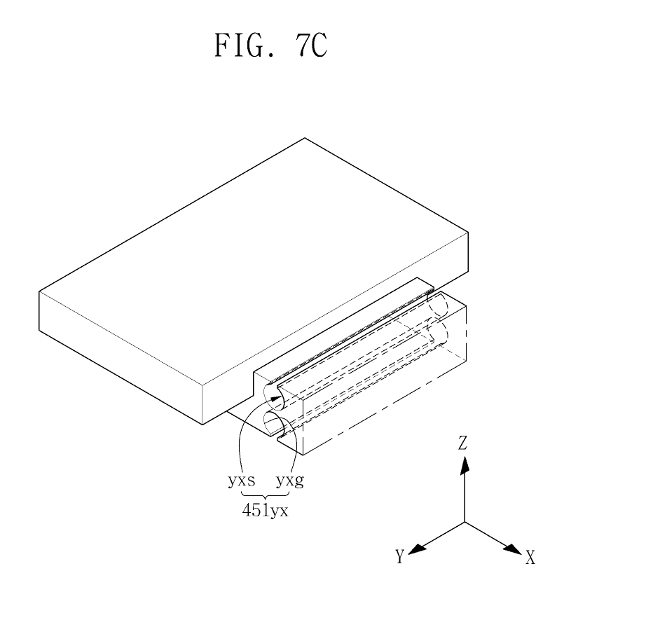

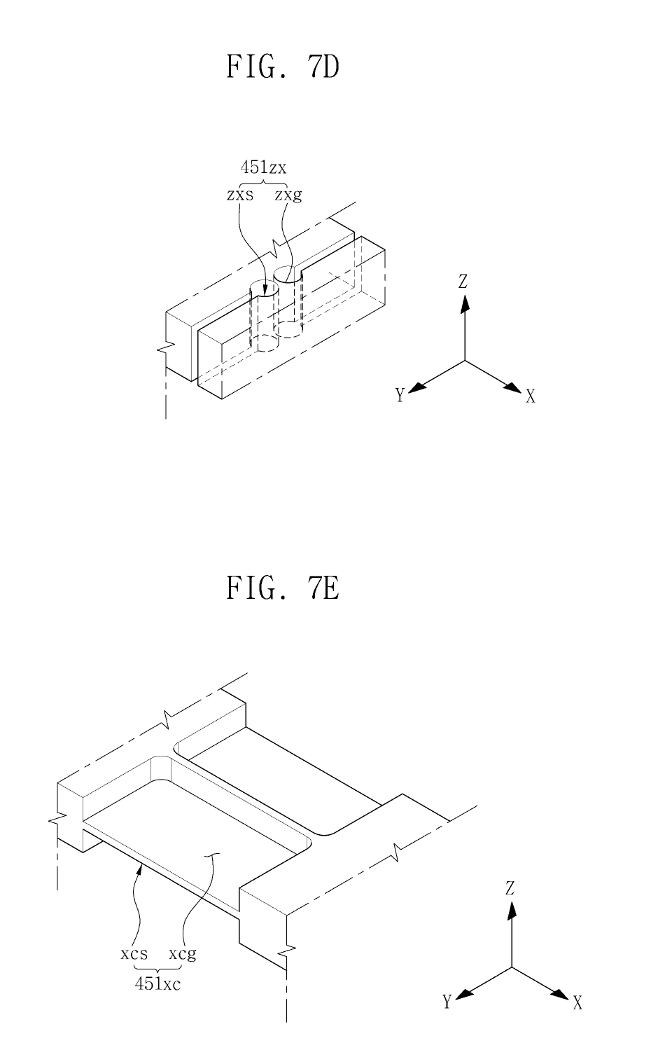

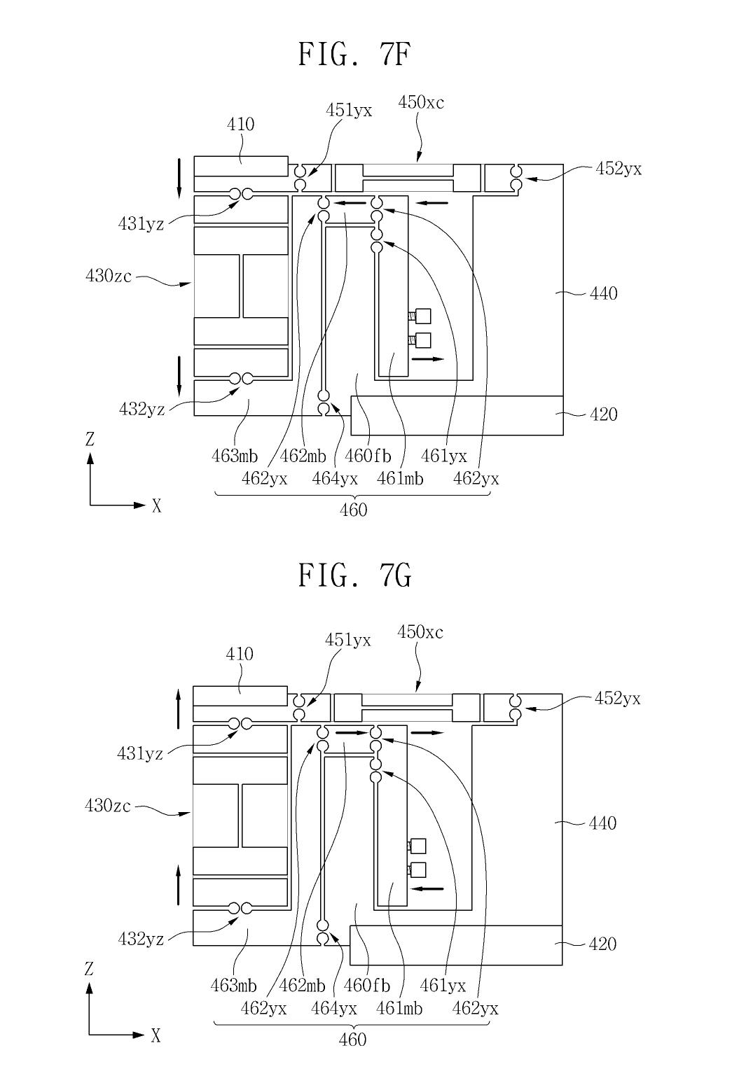

FIGS. 7A and 7B are perspective views of a Y-axis intermediate flexure structure 400 of a stage device according to an exemplary embodiment of the inventive concept. FIGS. 7C through 7E are partial perspective views of the Y-axis intermediate flexure structure shown in FIGS. 7A and 7B, according to an exemplary embodiment of the inventive concept. FIGS. 7F and 7G are side views illustrating operations of the Y-axis intermediate flexure structure shown in FIGS. 7A and 7B, according to an exemplary embodiment of the inventive concept.

Referring to FIGS. 4 and 7A through 7G, the Y-axis intermediate flexure structure 400 of the stage device according to an exemplary embodiment of the inventive concept may include a Y-axis intermediate upper plate 410, a Y-axis intermediate lower plate 420, a first Y-axis intermediate hinge part 430, a Y-axis intermediate fixing body 440, a second Y-axis intermediate hinge part 450, and a Y-axis tilting control part 460.

The Y-axis intermediate upper plate 410 may be combined with the Y-axis interference mirror 140y. The Y-axis intermediate upper plate 410 may be combined with the Y-axis interference mirror 140y by the third Y-axis adaptor 153y.

A Y-axial horizontal length of the Y-axis intermediate upper plate 410 may be smaller than the Y-axial horizontal length of the Y-axis mirror support 111y. The Y-axial horizontal length of the Y-axis intermediate upper plate 410 may be smaller than the Y-axial horizontal length of the Y-axis interference mirror 140y. For instance, the Y-axial horizontal length of the Y-axis intermediate upper plate 410 may be less than or equal to the half of the Y-axial horizontal length of the Y-axis interference mirror 140y.

The Y-axis intermediate lower plate 420 may be combined with the Y-axis mirror support 111y. The Y-axis intermediate lower plate 420 may be spaced apart from the Y-axis intermediate upper plate 410 in the X-axis direction. The Y-axis intermediate lower plate 420 may be spaced apart from the first Y-axis intermediate hinge part 430 in the X-axis direction. A bottom surface of the Y-axis intermediate lower plate 420 may be positioned at a lower level than a bottom surface of the first Y-axis intermediate hinge part 430. The Y-axis intermediate lower plate 420 may support the Y-axis intermediate fixing body 440 and the tilting control part 460.

The Y-axis intermediate lower plate 420 may extend in the X-axis direction. An X-axial horizontal length of the Y-axis intermediate lower plate 420 may be smaller than an X-axial horizontal distance between the Y-axis datum flexure structure 200 and the Y-axis distant flexure structure 300.

A Y-axial horizontal length of the Y-axis intermediate lower plate 420 may be smaller than the Y-axial horizontal length of the Y-axis mirror support 111y. The Y-axial horizontal length of the Y-axis intermediate lower plate 420 may be smaller than the Y-axial horizontal length of the Y-axis interference mirror 140y. The Y-axial horizontal length of the Y-axis intermediate lower plate 420 may be equal to the Y-axial horizontal length of the Y-axis intermediate upper plate 410.

The first Y-axis intermediate hinge part 430 may fix the Y-axis intermediate upper plate 410 in the Z-axis direction. A region of the Y-axis interference mirror 140y, which may vertically overlap the Y-axis intermediate upper plate 410, may be fixed by the first Y-axis intermediate hinge part 430 in the Z-axis direction.

The first Y-axis intermediate hinge part 430 may be disposed under the Y-axis intermediate upper plate 410. An X-axial horizontal length of an upper end of the first Y-axis intermediate hinge part 430 may be equal to an X-axial horizontal length of a lower end of the first Y-axis intermediate hinge part 430. For instance, each of the X-axial horizontal lengths of the upper and lower ends of the first Y-axis intermediate hinge part 430 may be equal to the X-axial horizontal length of the first Y-axis intermediate upper plate 410.

The first Y-axis intermediate hinge part 430 may include the first yz Y-axis intermediate flexure hinge 431yz, a first xz Y-axis intermediate flexure hinge 431xz, a zc Y-axis intermediate flexure hinge 430zc, a second xz Y-axis intermediate flexure hinge 432xz, and a second yz Y-axis intermediate flexure hinge 432yz.

The first yz Y-axis intermediate flexure hinge 431yz may restrict degrees of freedom for the X-axial motion, the Y-axial motion, the Z-axial motion, the X-axial rotation, and the Z-axial rotation of the Y-axis intermediate upper plate 410. The first yz Y-axis intermediate flexure hinge 431yz might not restrict a degree of freedom for the Y-axial rotation of the Y-axis intermediate upper plate 410.

The first yz Y-axis intermediate flexure hinge 431yz may be stacked on the Y-axis intermediate upper plate 410 in the Z-axis direction. For instance, the first yz Y-axis intermediate flexure hinge 431yz may be stacked under the Y-axis intermediate upper plate 410. The first yz Y-axis intermediate flexure hinge 431yz may be disposed close to the Y-axis intermediate upper plate 410.

The first yz Y-axis intermediate flexure hinge 431yz may be a vertical-type flexure hinge extending in the Y-axis direction. The first yz Y-axis intermediate flexure hinge 431yz may be parallel to the first yz Y-axis datum flexure hinge 231yz shown in FIGS. 5A and 5B. The first yz Y-axis intermediate flexure hinge 431yz may have substantially the same structure as the first yz Y-axis datum flexure hinge 231yz shown in FIG. 5C. For instance, the first yz Y-axis intermediate flexure hinge 431yz may be shaped like i-beams extending in the Y-axis direction. The first yz Y-axis intermediate flexure hinge 431yz may include the yz flexure support yzs and yz flexure grooves yzg shown in FIG. 5C.

The first xz Y-axis intermediate flexure hinge 431xz may restrict degrees of freedom for the X-axial motion, the Y-axial motion, the Z-axial motion, the Y-axial rotation, and the Z-axial rotation of the Y-axis intermediate upper plate 410. The first xz Y-axis intermediate flexure hinge 431xz might not restrict a degree of freedom for the X-axial rotation of the Y-axis intermediate upper plate 410.

The first xz Y-axis intermediate flexure hinge 431xz may be stacked on the first yz Y-axis intermediate flexure hinge 431yz in the Z-axis direction. For instance, the first xz Y-axis intermediate flexure hinge 431xz may be disposed under the first yz Y-axis intermediate flexure hinge 431yz. The first yz Y-axis intermediate flexure hinge 431yz may be disposed between the Y-axis intermediate upper plate 410 and the first xz Y-axis intermediate flexure hinge 431xz.

The first xz Y-axis intermediate flexure hinge 431xz may be a vertical-type flexure hinge extending in the Y-axis direction. The first xz Y-axis intermediate flexure hinge 431xz may be parallel to the xz Y-axis datum flexure hinge 230xz shown in FIGS. 5A and 5B. The first xz Y-axis intermediate flexure hinge 431xz may have substantially the same structure as the xz Y-axis datum flexure hinge 230xz shown in FIG. 5D. For instance, the first xz Y-axis intermediate flexure hinge 431xz may be shaped like i-beams extending in the X-axis direction. The first xz Y-axis intermediate flexure hinge 431xz may include the xz flexure support xzs and xz flexure grooves xzg shown in FIG. 5D.

The zc Y-axis intermediate flexure hinge 430zc may restrict degrees of freedom for the X-axial motion, the Y-axial motion, the Z-axial motion, the X-axial rotation, and the Y-axial rotation of the Y-axis intermediate upper plate 410. The zc Y-axis intermediate flexure hinge 430zc might not restrict a degree of freedom for the Z-axial rotation of the Y-axis intermediate upper plate 410.

The zc Y-axis intermediate flexure hinge 430zc may be stacked on the first xz Y-axis intermediate flexure hinge 431xz in the Z-axis direction. For instance, the zc Y-axis intermediate flexure hinge 430zc may be disposed under the first xz Y-axis intermediate flexure hinge 431xz. The first xz Y-axis intermediate flexure hinge 431xz may be disposed between the first yz Y-axis intermediate flexure hinge 431yz and the zc Y-axis intermediate flexure hinge 430zc.

The zc Y-axis intermediate flexure hinge 430zc may be a cross-type flexure hinge extending in the Z-axis direction. The zc Y-axis intermediate flexure hinge 430zc may be parallel to the zc Y-axis datum flexure hinge 230zc shown in FIGS. 5A and 5B. The zc Y-axis intermediate flexure hinge 430zc may have substantially the same structure as the zc Y-axis datum flexure hinge 230zc shown in FIG. 5E. For instance, the zc Y-axis intermediate flexure hinge 430zc may include the zc flexure support zcs and zc flexure grooves zcg shown in FIG. 5E.

The second xz Y-axis intermediate flexure hinge 432xz may restrict degrees of freedom for the X-axial motion, the Y-axial motion, the Z-axial motion, the Y-axial rotation, and the Z-axial rotation of the Y-axis intermediate upper plate 410. The second xz Y-axis intermediate flexure hinge 432xz might not restrict a degree of freedom for the X-axial rotation of the Y-axis intermediate upper plate 410.

The second xz Y-axis intermediate flexure hinge 432xz may be spaced apart from the first xz Y-axis intermediate flexure hinge 431xz in the Z-axis direction. For instance, the second xz Y-axis intermediate flexure hinge 432xz may be disposed under the zc Y-axis intermediate flexure hinge 430zc. The zc Y-axis intermediate flexure hinge 430zc may be disposed between the first xz Y-axis intermediate flexure hinge 431xz and the second xz Y-axis intermediate flexure hinge 432xz.

The second xz Y-axis intermediate flexure hinge 432xz may be a vertical-type flexure hinge extending in the Y-axis direction. The second xz Y-axis intermediate flexure hinge 432xz may be parallel to the second xz Y-axis datum flexure hinge 232xz shown in FIGS. 5A and 5B. The second xz Y-axis intermediate flexure hinge 432xz may have substantially the same structure as the first xz Y-axis intermediate flexure hinge 431xz. The second xz Y-axis intermediate flexure hinge 432xz may have substantially the same structure as the first xz Y-axis datum flexure hinge 231xz shown in FIG. 5D. For instance, the second xz Y-axis intermediate flexure hinge 432xz may be shaped like i-beams extending in the X-axis direction. The second xz Y-axis intermediate flexure hinge 432xz may include the xz flexure support xzs and xz flexure grooves xzg shown in FIG. 5D.

The second yz Y-axis intermediate flexure hinge 432yz may restrict degrees of degree for the X-axial motion, the Y-axial motion, the Z-axial motion, the X-axial rotation, and the Z-axial rotation of the Y-axis intermediate upper plate 410. The second yz Y-axis intermediate flexure hinge 432yz might not restrict a degree of freedom of the Y-axial rotation of the Y-axis intermediate upper plate 410.

The second yz Y-axis intermediate flexure hinge 432yz may be stacked on the second xz Y-axis intermediate flexure hinge 432xz in the Z-axis direction. The second yz Y-axis intermediate flexure hinge 432yz may be spaced apart from the first yz Y-axis intermediate flexure hinge 431yz in the Z-axis direction. For instance, the second yz Y-axis intermediate flexure hinge 432yz may be disposed under the second xz Y-axis intermediate flexure hinge 432xz.

The second yz Y-axis intermediate flexure hinge 432yz may be a vertical-type flexure hinge extending in the Y-axis direction. The second yz Y-axis intermediate flexure hinge 432yz may have substantially the same structure as the first yz Y-axis intermediate flexure hinge 431yz. The second yz Y-axis intermediate flexure hinge 432yz may have the same structure as the first yz Y-axis datum flexure hinge 231yz shown in FIGS. 5A and 5B. For instance, the second yz Y-axis intermediate flexure hinge 432yz may be shaped like i-beams extending in the Y-axis direction. The second yz Y-axis intermediate flexure hinge 432yz may include the yz flexure support yzs and yz flexure grooves yzg shown in FIG. 5C.

The first Y-axis intermediate hinge part 430 of the Y-axial intermediate flexure structure 400 according to an exemplary embodiment of the inventive concept may include a first yz Y-axis intermediate flexure hinge 431yz, a first xz Y-axis intermediate flexure hinge 431xz, a zc Y-axis intermediate flexure hinge 430zc, a second xz Y-axis intermediate flexure hinge 432xz, and a second yz Y-axis intermediate flexure hinge 432yz, which may be stacked in the Z-axis direction. Thus, in the stage device according to an exemplary embodiment of the inventive concept, the first Y-axis intermediate hinge part 430 may fix the Y-axis intermediate upper plate 410 in the Z-axis direction. Accordingly, in the stage device according to embodiments of the inventive concept, a degree of freedom for the Z-axial motion of the Y-axis intermediate upper plate 410 may be restricted by the first Y-axis intermediate hinge part 430.

The Y-axis intermediate fixing body 440 may be spaced apart from the first Y-axis intermediate hinge part 430 in the X-axis direction. The Y-axis intermediate fixing body 440 may be fixed onto the Y-axis intermediate lower plate 420.

The first Y-axis intermediate fixing body 440 may extend in the Z-axis direction. A top surface of the first Y-axis intermediate fixing body 440 may be positioned at a lower level than a top surface of the Y-axis intermediate upper plate 410.

The second Y-axis intermediate hinge part 450 may fix the Y-axis intermediate upper plate 410 in the X-axis direction. A region of the Y-axis interference mirror 140y, which may vertically overlap the Y-axis intermediate upper plate 410, may be fixed by the second Y-axis intermediate hinge part 450 in the X-axis direction.

The second Y-axis intermediate hinge part 450 may be disposed between the first Y-axis intermediate hinge part 430 and the Y-axis intermediate fixing body 440. For instance, the second Y-axis intermediate hinge part 450 may be disposed between an upper end of the first Y-axis intermediate hinge part 430 and an upper end of the Y-axis intermediate fixing body 440. An X-axial horizontal length of the second Y-axis intermediate hinge part 450 may be equal to an X-axial horizontal distance between the first Y-axis intermediate hinge part 430 and the Y-axis intermediate fixing body 440.

The second Y-axis intermediate hinge part 450 may include a first yx Y-axis intermediate flexure hinge 451yx, a first zx Y-axis intermediate flexure hinge 451zx, an xc Y-axis intermediate flexure hinge 450xc, a second zx Y-axis intermediate flexure hinge 452zx, and a second yx Y-axis intermediate flexure hinge 452yx.

The first yx Y-axis intermediate flexure hinge 451yx may restrict degrees of freedom for the X-axial motion, the Y-axial motion, the Z-axial motion, the X-axial rotation, and the Z-axial rotation of the Y-axis intermediate upper plate 410. The first yx Y-axis intermediate flexure hinge 451yx might not restrict a degree of freedom for the Y-axial rotation of the Y-axis intermediate upper plate 410.

The first yx Y-axis intermediate flexure hinge 451yx may be stacked on the Y-axis intermediate upper plate 410 in the X-axis direction. For instance, the first yx Y-axis intermediate flexure hinge 451yx may be stacked at a lower end of the Y-axis intermediate upper plate 410 in the Y-axis direction. The first yx Y-axis intermediate flexure hinge 451yx may be disposed close to the Y-axis intermediate upper plate 410. The first yx Y-axis intermediate flexure hinge 451yx may be disposed on a yz flexure support of the first yz Y-axis intermediate flexure hinge 431yz.

The first yx Y-axis intermediate flexure hinge 451yx may be a horizontal-type flexure hinge extending in the Y-axis direction. As shown in FIG. 7C, the first yx Y-axis intermediate flexure hinge 451yx may include a yx flexure support yxs and yx flexure grooves yxg.

The yx flexure support yxs may restrict degrees of freedom for the X-axial motion, the Y-axial motion, the Z-axial motion, the X-axial rotation, and the Z-axial rotation of the Y-axis intermediate upper plate 410.

The yx flexure support yxs may extend in the Y-axis direction. The yx flexure support yxs may be parallel to a plane surface formed by the X-axis direction and the Y-axis direction.

The yx flexure grooves yxg may provide a space in which the Y-axis intermediate upper plate 410 may rotate about the Y-axis. The Y-axis intermediate upper plate 410 may be rotated about the Y-axis by the yx flexure grooves yxg.

The yx flexure grooves yxg may be disposed above and under the yx flexure support yxs. The yx flexure grooves yxg may extend in the Y-axis direction. The yx flexure grooves yxg may penetrate the second Y-axis intermediate hinge part 450 of the Y-axis intermediate flexure structure 400 in the Y-axis direction. For instance, the first yx Y-axis intermediate flexure hinge 451yx may be shaped like H-beams extending in the Y-axis direction.

The yx flexure grooves yxg may extend from the yx flexure support yxs in the Z-axis direction. The yx flexure grooves yxg may enable components disposed on side surfaces of the first yx Y-axis intermediate flexure hinge 451yx to be connected by the yx flexure support yxs. For instance, a side surface of the Y-axis intermediate upper plate 410 may be connected to the yx flexure support yxs.

The first zx Y-axis intermediate flexure hinge 451zx may restrict degrees of freedom for the X-axial motion, the Y-axial motion, the Z-axial motion, the X-axial rotation and the Y-axial rotation of the Y-axis intermediate upper plate 410. The first zx Y-axis intermediate flexure hinge 451zx might not restrict a degree of freedom for the Z-axial rotation of the Y-axis intermediate upper plate 410.

The first zx Y-axis intermediate flexure hinge 451zx may be stacked on the first yx Y-axis intermediate flexure hinge 451yx in the Y-axis direction. For instance, the first yx Y-axis intermediate flexure hinge 451yx may be disposed between the Y-axis intermediate upper plate 410 and the first zx Y-axis intermediate flexure hinge 451zx.

The first zx Y-axis intermediate flexure hinge 451zx may be an X-axial flexure hinge extending in the Z-axis direction. As shown in FIG. 7D, the first zx Y-axis intermediate flexure hinge 451zx may include a zx flexure support zxs and zx flexure grooves zxg.

The zx flexure support zxs may restrict degrees of freedom for the X-axial motion, the Y-axial motion, the Z-axial motion, the X-axial rotation, and the Y-axial rotation of the Y-axis intermediate upper plate 410.

The zx flexure support zxs may extend in the Z-axis direction. The zx flexure support zxs may be parallel to a plane surface formed by the X-axis direction and the Z-axis direction.

The zx flexure grooves zxg may provide a space in which the Y-axis intermediate upper plate 410 may rotate about the Z-axis. The Y-axis intermediate upper plate 410 may rotate about the Z-axis by the zx flexure grooves zxg.

The zx flexure grooves zxg may be disposed on side surfaces of the zx flexure support zxs. The zx flexure grooves zxg may extend in the Z-axis direction. The zx flexure grooves zxg may penetrate the second Y-axis intermediate hinge part 450 of the Y-axis intermediate flexure structure 400 in the Z-axis direction. For instance, the first zx Y-axis intermediate flexure hinge 451zx may be shaped like i-beams extending in the Z-axis direction.

The zx flexure grooves zxg may extend in the Y-axis direction from side surfaces of the zx flexure support zxs. The zx flexure grooves zxg may enable components disposed on side surfaces of the first zx Y-axis intermediate flexure hinge 451zx to be connected by the zx flexure support zxs.

The xc Y-axis intermediate flexure hinge 450xc may restrict degrees of freedom for the X-axial motion, the Y-axial motion, the Z-axial motion, the Y-axial rotation, and the Z-axial rotation of the Y-axis intermediate upper plate 410. The xc Y-axis intermediate flexure hinge 450xc might not restrict a degree of freedom for the X-axial rotation of the Y-axis intermediate upper plate 410.

The xc Y-axis intermediate flexure hinge 450xc may be stacked on the first zx Y-axis intermediate flexure hinge 451zx in the Y-axis direction. For instance, the first zx Y-axis intermediate flexure hinge 451zx may be disposed between the first yx Y-axis intermediate flexure hinge 451yx and the xc Y-axis intermediate flexure hinge 450xc.

The xc Y-axis intermediate flexure hinge 450xc may be a cross-type flexure hinge extending in the X-axis direction. As shown in FIG. 7E, the xc Y-axis intermediate flexure hinge 450xc may include an xc flexure support xcs and xc flexure grooves xcg.

The xc flexure support xcs may restrict degrees of freedom for the X-axial motion, the Y-axial motion, the Z-axial motion, the Y-axial rotation, and the Z-axial rotation of the Y-axial intermediate upper plate 410.

The xc flexure support xcs may extend in the X-axis direction. A cross-section of the xc flexure support xcs may have a cross shape extending in the Y-axis direction and the Z-axis direction.

The xc flexure grooves xcg may provide a space in which the Y-axis intermediate upper plate 410 may rotate about the X-axis. The Y-axis intermediate upper plate 410 may be rotated about the X-axis by the xc flexure grooves xcg.

The xc flexure grooves xcg may be disposed between the xc flexure supports xcs. The xc flexure grooves xcg may enable components disposed on side surfaces of the xc Y-axis intermediate flexure hinge 450xc to be connected by the xc flexure support xcs.

The second zx Y-axis intermediate flexure hinge 452zx may restrict degrees of freedom for the X-axial motion, the Y-axial motion, the Z-axial motion, the X-axial rotation, and the Y-axial rotation of the Y-axis intermediate upper plate 410. The second zx Y-axis intermediate flexure hinge 452zx might not restrict a degree of freedom for the Z-axial rotation of the Y-axis intermediate upper plate 410.

The second zx Y-axis intermediate flexure hinge 452zx may be stacked on the xc Y-axis intermediate flexure hinge 450xc in the X-axis direction. For instance, the xc Y-axis intermediate flexure hinge 450xc may be disposed between the first zx Y-axis intermediate flexure hinge 451zx and the second zx Y-axis intermediate flexure hinge 452zx.

The second zx Y-axis intermediate flexure hinge 452zx may be an X-axial flexure hinge extending in the Z-axis direction. The second zx Y-axis intermediate flexure hinge 452zx may have substantially the same structure as the first zx Y-axis intermediate flexure hinge 451zx. For instance, the second zx Y-axis intermediate flexure hinge 452zx may be shaped like i-beams extending in the Z-axis direction. The second zx Y-axis intermediate flexure hinge 452zx may include the zx flexure support zxs and the zx flexure grooves zxg.

The second yx Y-axis intermediate flexure hinge 452yx may restrict degrees of freedom for the X-axial motion, the Y-axial motion, the Z-axial motion, the X-axial rotation, and the Z-axial rotation of the Y-axis intermediate upper plate 410. The second yx Y-axis intermediate flexure hinge 452yx might not restrict a degree of freedom for the Y-axial rotation of the Y-axis intermediate upper plate 410.

The second yx Y-axis intermediate flexure hinge 452yx may be stacked on the second zx Y-axis intermediate flexure hinge 452zx in the Y-axis direction. For instance, the second zx Y-axis intermediate flexure hinge 452zx may be disposed between the xc Y-axis intermediate flexure hinge 450xc and the second yx Y-axis intermediate flexure hinge 452yx.

The second yx Y-axis intermediate flexure hinge 452yx may be a horizontal-type flexure hinge extending in the Y-axis direction. The second yx Y-axis intermediate flexure hinge 452yx may have substantially the same structure as the first yx Y-axis intermediate flexure hinge 451yx. For instance, the second yx Y-axis intermediate flexure hinge 452yx may be shaped like H-beams extending in the Y-axis direction. The second yx Y-axis intermediate flexure hinge 452yx may include the yx flexure support yxs and the yx flexure grooves yxg.

The second Y-axis intermediate hinge part 450 of the Y-axis intermediate flexure structure 400 according to an exemplary embodiment of the inventive concept may include a first yx Y-axis intermediate flexure hinge 451yx, a first zx Y-axis intermediate flexure hinge 451zx, an xc Y-axis intermediate flexure hinge 450xc, a second zx Y-axis intermediate flexure hinge 452zx, and a second yx Y-axis intermediate flexure hinge 452yx, which may be stacked in the X-axis direction. Thus, in the stage device according to an exemplary embodiment of the inventive concept, the second Y-axis intermediate hinge part 450 may fix the Y-axis intermediate upper plate 410 only in the X-axis direction. Accordingly, in the stage device according to an exemplary embodiment of the inventive concept, a degree of freedom for the X-axial motion of the Y-axis intermediate upper plate 410 may be restricted by the second Y-axis intermediate hinge part 450.

The Y-axis tilting control part 460 may regulate a Z-axial position of the Y-axis intermediate upper plate 410. For instance, the Y-axis tilting control part 460 may move the Y-axis intermediate upper plate 410 and the first Y-axis intermediate hinge part 430 in the Z-axis direction. A region of the Y-axis interference mirror 140y, which may be combined with the Y-axis intermediate upper plate 410, may be moved by the Y-axis tilting control part 460 in the Z-axis direction.

The Y-axis tilting control part 460 may be disposed under the second Y-axis intermediate hinge part 450. The Y-axis tilting control part 460 may be spaced apart from the first Y-axis intermediate hinge part 430 in the X-axis direction. For instance, the Y-axis tilting control part 460 may be disposed between the first Y-axis intermediate hinge part 430 and the intermediate fixing body 440.

The Y-axis tilting control part 460 may include a Y-axis tilting fixing body 460fb, a first Y-axis tilting control body 461mb, a second Y-axis tilting control body 462mb, a third Y-axis tilting control body 463mb, a first yx Y-axis tilting flexure hinge 461yx, a second yx Y-axis tilting flexure hinge 462yx, a third yx Y-axis tilting flexure hinge 463yx, a fourth yx Y-axis tilting flexure hinge 464yx, and a Y-axis tilting control member 460ae.

The Y-axis tilting fixing body 460fb may be disposed between the first Y-axis intermediate hinge part 430 and the Y-axis intermediate fixing body 440. The Y-axis tilting fixing body 460fb may be disposed on the Y-axis intermediate lower plate 420. The Y-axis tilting fixing body 460fb may be fixed onto a top surface of the Y-axis intermediate lower plate 420.

The Y-axis tilting fixing body 460fb may extend in the Z-axis direction. A top surface of the Y-axis tilting fixing body 460fb may be positioned at a lower level than a bottom surface of the second Y-axis intermediate hinge part 450.

The first Y-axis tilting control body 461mb may be disposed between the Y-axis tilting fixing body 460fb and the Y-axis intermediate fixing body 440. The first Y-axis tilting control body 461mb may be disposed on the Y-axis intermediate lower plate 420. The first Y-axis tilting control body 461mb may be spaced apart from the Y-axis intermediate lower plate 420. A bottom surface of the first Y-axis tilting control body 461mb may be at a higher level than the top surface of the Y-axis intermediate lower plate 420.

The first Y-axis tilting control body 461mb may extend in the Z-axis direction. A top surface of the first Y-axis tilting control body 461mb may be positioned at a lower level than the bottom surface of the second Y-axis intermediate hinge part 450. The top surface of the first Y-axis tilting control body 461mb may be positioned at a higher level than the top surface of the Y-axis tilting fixing body 460fb.

The second Y-axis tilting control body 462mb may be disposed between the Y-axis tilting fixing body 460fb and the second Y-axis intermediate hinge part 450. The second Y-axis tilting control body 462mb may be spaced apart from the Y-axis tilting fixing body 460fb and the second Y-axis intermediate hinge part 450. A bottom surface of the second Y-axis tilting control body 462mb may be positioned at a higher level than the top surface of the Y-axis tilting fixing body 460fb. A top surface of the second Y-axis tilting control body 462mb may be at a lower level than the bottom surface of the second Y-axis intermediate hinge part 450. The top surface of the second Y-axis tilting control body 462mb may be positioned at the same level as the top surface of the first Y-axis tilting control body 461mb.

The third Y-axis tilting control body 463mb may be disposed between the first Y-axis intermediate hinge part 430 and the Y-axis tilting fixing body 460fb. The third Y-axis tilting control body 463mb may be spaced apart from the Y-axis intermediate lower plate 420 in the X-axis direction. A bottom surface of the third Y-axis tilting control body 463mb may be positioned at a higher level than the bottom surface of the Y-axis intermediate lower plate 420. A bottom surface of the third Y-axis tilting control body 463mb may be positioned at a lower level than the top surface of the Y-axis intermediate lower plate 420.

The third Y-axis tilting control body 463mb may extend in the Z-axis direction. A top surface of the third Y-axis tilting control body 463mb may be positioned at a lower level than the bottom surface of the second Y-axis intermediate hinge part 450. The top surface of the third Y-axis tilting control body 463mb may be positioned at a higher level than the top surface of the Y-axis tilting fixing body 460fb. The top surface of the third Y-axis tilting control body 463mb may be positioned at the same level as the top surface of the second Y-axis tilting control body 462mb.

The first yx Y-axis tilting flexure hinge 461yx may be disposed between the Y-axis tilting fixing body 460fb and the first Y-axis tilting control body 461mb. The first Y-axis tilting control body 461mb may be connected to the Y-axis tilting fixing body 460fb by the first yx Y-axis tilting flexure hinge 461yx.

The first yx Y-axis tilting flexure hinge 461yx may be disposed close to the top surface of the Y-axis tilting fixing body 460fb. For instance, the first yx Y-axis tilting flexure hinge 461yx may be disposed between an upper end of the Y-axis tilting fixing body 460fb and the first Y-axis tilting control body 461mb.

The first yx Y-axis tilting flexure hinge 461yx may be a horizontal-type flexure hinge extending in the Y-axis direction. The first yx Y-axis tilting flexure hinge 461yx may have substantially the same structure as the first yx Y-axis intermediate flexure hinge 451yx. For instance, the first yx Y-axis tilting flexure hinge 461yx may be shaped like H-beams extending in the Y-axis direction. The first yx Y-axis tilting flexure hinge 461yx may include the yx flexure support yxs and the yx flexure grooves yxg.

The second yx Y-axis tilting flexure hinge 462yx may be disposed between the first Y-axis tilting control body 461mb and the second Y-axis tilting control body 462mb. The second Y-axis tilting control body 462mb may be connected to the first Y-axis tilting control body 461mb by the second yx Y-axis tilting flexure hinge 462yx.

The second yx Y-axis tilting flexure hinge 462yx may be disposed on the first yx Y-axis tilting flexure hinge 461yx For instance, the second yx Y-axis tilting flexure hinge 462yx may be stacked on the first yx Y-axis tilting flexure hinge 461yx in the Z-axis direction.

The second yx Y-axis tilting flexure hinge 462yx may be a horizontal-type flexure hinge extending in the Y-axis direction. The second yx Y-axis tilting flexure hinge 462yx may have substantially the same structure as the first yx Y-axis tilting flexure hinge 461yx. The second yx Y-axis tilting flexure hinge 462yx may have substantially the same structure as the first yx Y-axis intermediate flexure hinge 451yx. For instance, the second yx Y-axis tilting flexure hinge 462yx may be shaped like H-beams extending in the Y-axis direction. The second yx Y-axis tilting flexure hinge 462yx may include the yx flexure support yxs and the yx flexure grooves yxg.

The third yx Y-axis tilting flexure hinge 463yx may be disposed between the second Y-axis tilting control body 462mb and the third Y-axis tilting control body 463mb. The third Y-axis tilting control body 463mb may be connected to the second Y-axis tilting control body 462mb by the third yx Y-axis tilting flexure hinge 463yx.

The third yx Y-axis tilting flexure hinge 463yx may be a horizontal-type flexure hinge extending in the Y-axis direction. The third yx Y-axis tilting flexure hinge 463yx may have substantially the same structure as the first yx Y-axis tilting flexure hinge 461yx. The third yx Y-axis tilting flexure hinge 463yx may have substantially the same structure as the first yx Y-axis intermediate flexure hinge 451yx. For instance, the third yx Y-axis tilting flexure hinge 463yx may be shaped like H-beams extending in the Y-axis direction. The third yx Y-axis tilting flexure hinge 463yx may include the yx flexure support yxs and the yx flexure grooves yxg.

The fourth yx Y-axis tilting flexure hinge 464yx may be disposed between the Y-axis tilting fixing body 460fb and the third Y-axis tilting control body 463mb. The third Y-axis tilting control body 463mb may be connected to the Y-axis tilting fixing body 460fb by the fourth yx Y-axis tilting flexure hinge 464yx.

The fourth yx Y-axis tilting flexure hinge 464yx may be disposed close to a bottom surface of the Y-axis tilting fixing body 460fb. For instance, the fourth yx Y-axis tilting flexure hinge 464yx may be disposed between a lower end of the Y-axis tilting fixing body 460fb and the third Y-axis tilting control body 463mb.

The fourth yx Y-axis tilting flexure hinge 464yx may be disposed under the third yx Y-axis tilting flexure hinge 463yx. For instance, the third yx Y-axis tilting flexure hinge 463yx may be stacked on the fourth yx Y-axis tilting flexure hinge 464yx in the Z-axis direction.

The fourth yx Y-axis tilting flexure hinge 464yx may be a horizontal-type flexure hinge extending in the Y-axis direction. The fourth yx Y-axis tilting flexure hinge 464yx may substantially have the same structure as the first yx Y-axis tilting flexure hinge 461yx. The fourth yx Y-axis tilting flexure hinge 464yx may substantially have the same structure as the first yx Y-axis intermediate flexure hinge 451yx. For instance, the fourth yx Y-axis tilting flexure hinge 464yx may be shaped like H-beams extending in the Y-axis direction. The fourth yx Y-axis tilting flexure hinge 464yx may include the yx flexure support yxs and the yx flexure grooves yxg.

The Y-axis tilting control member 460ae may regulate a space between the Y-axis tilting fixing body 460fb and the first Y-axis tilting control body 461mb. The Y-axis tilting control member 460ae may be disposed at a lower end of the first Y-axis tilting control body 461mb. The Y-axis tilting control member 460ae may include a Y-axis intermediate spacing member 460me and a Y-axis intermediate fixing member 460fe.

The Y-axis intermediate spacing member 460me may move the first Y-axis tilting control body 461mb from the Y-axis tilting fixing body 460fb. An X-axial horizontal distance between the Y-axis tilting fixing body 460fb and the first Y-axis tilting control body 461mb may be regulated by the Y-axis intermediate spacing member 460me.

The Y-axis intermediate fixing member 460fe may fix a position of the first Y-axis tilting control body 461mb. An X-axial horizontal distance between the Y-axis tilting fixing body 460fb and the first Y-axis tilting control body 461mb may be maintained by the Y-axis intermediate fixing member 460fe.

The Y-axis intermediate flexure structure 400 of the stage device according to an exemplary embodiment of the inventive concept may further include a component configured to efficiently regulate the Y-axis tilting control member 460ae. For instance, the Y-axis intermediate fixing body 440 may include a first through hole 440mh and a second through hole 440fh. The first through hole 440mh and the second through hole 440fh may penetrate the Y-axis intermediate fixing body 440 in the X-axis direction. A Z-axial height of the first through hole 440mh may be equal to a Z-axial height of the Y-axis intermediate spacing member 460me. A Z-axial height of the second through hole 440fh may be equal to a Z-axial height of the Y-axis intermediate fixing member 460fe.

The Y-axis intermediate flexure structure 400 of the stage device according to an exemplary embodiment of the inventive concept may regulate Z-axial positions of the Y-axis intermediate upper plate 410 and the first Y-axis intermediate hinge part 430 by the Y-axis tilting control member 460ae.

FIG. 7F is a side view illustrating operations when the Y-axis intermediate upper plate 410 and the first Y-axis intermediate hinge part 430 descend by the Y-axis tilting control member 460ae of the Y-axis intermediate flexure structure 400 according to an exemplary embodiment of the inventive concept.

Referring to FIGS. 4 and 7F, when a lower portion of the first Y-axis tilting control body 461mb is moved away from the Y-axis tilting fixing body 460fb by the Y-axis tilting control member 460ae, the first Y-axis tilting control body 461mb may be rotated about the Y-axis by the first yx Y-axis tilting flexure hinge 461yx. Thus, an upper end of the first Y-axis tilting control body 461mb may push the second Y-axis tilting control body 462mb in the X-axis direction. For example, the second Y-axis tilting control body 462mb may be moved by the first Y-axis tilting control body 461mb toward the Y-axis intermediate upper plate 410.

The first Y-axis tilting control body 461mb and the second Y-axis tilting control body 462mb may be connected by the second yx Y-axis tilting flexure hinge 462yx. The second Y-axis tilting control body 462mb may move in the X-axis direction without moving the second Y-axis tilting control body 462mb in the Y-axis or the Z-axis direction.

An upper end of the third Y-axis tilting control body 462mb may be moved in the X-axis direction by the X-axis motion of the second Y-axis tilting control body 462mb. The second Y-axis tilting control body 462mb and the third Y-axis tilting control body 463mb may be connected by the third yx Y-axis tilting flexure hinge 463yx. An upper end of the third Y-axis tilting control body 463mb may move in the X-axis direction without moving the upper end of the third Y-axis tilting control body 463mb in the Y-axis or the Z-axis direction.

When the upper end of the third Y-axis tilting control body 463mb moves in the X-axis direction, the third Y-axis tilting control body 463mb may be rotated about the Y-axis by the fourth Y-axis yx tilting flexure hinge 464yx. Thus, a region of the third Y-axis tilting control body 463mb, which may extend under the first Y-axis intermediate hinge part 430, may descend in the Z-axis direction. For example, the first Y-axis intermediate hinge part 430 may descend in the Z-axis direction by the third Y-axis tilting control body 463mb. The Y-axis intermediate upper plate 410 may be descended by the first Y-axis intermediate hinge part 430.

FIG. 7G is a side view illustrating operations when the Y-axis intermediate upper plate 410 and the first Y-axis intermediate hinge part 430 of the Y-axial intermediate flexure structure 400 according to an exemplary embodiment of the inventive concept are increased.

Referring to FIGS. 4 and 7G, when a lower end of the first Y-axis tilting control body 461mb is rendered close to the Y-axis tilting fixing body 460fb by the Y-axis tilting control member 460ae, the first Y-axis tilting control body 461mb may be rotated about the Y-axis by the first yx Y-axis tilting flexure hinge 461yx. Thus, the upper end of the first Y-axis tilting control body 461mb may pull the second Y-axis tilting control body 462mb in the X-axis direction. For example, the second Y-axis tilting control body 462mb may be rendered away from the Y-axis intermediate upper plate 410 by the first Y-axis tilting control body 461mb.

The upper end of the third Y-axis tilting control body 463mb may be pulled by the X-axial motion of the second Y-axis tilting control body 462mb. When the upper end of the third Y-axis tilting control body 463mb is pulled, the first Y-axis intermediate hinge part 430 may be ascended in the Z-axis direction by the fourth yx Y-axis tilting flexure hinge 464yx. The Y-axis intermediate upper plate 410 may be ascended by the first Y-axis intermediate hinge part 430.

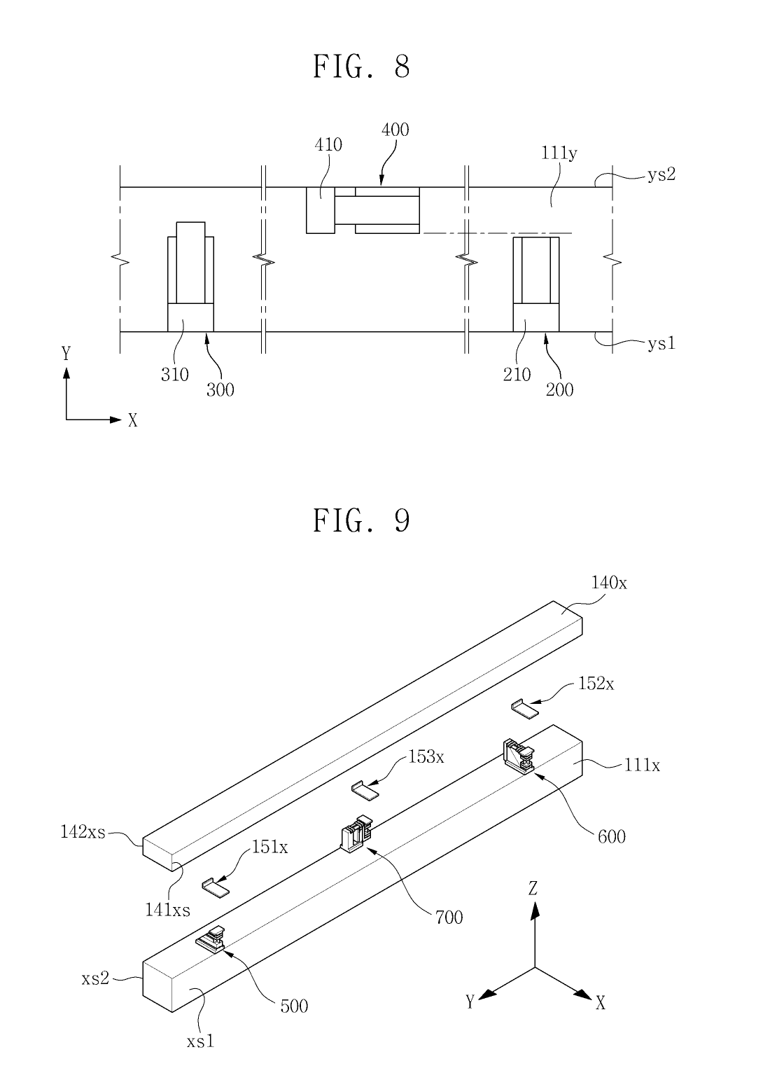

FIG. 8 is a plan view of a Y-axis datum flexure structure 200, a Y-axis distant flexure structure 300, and a Y-axis intermediate flexure structure 400 of a stage device according to an exemplary embodiment of the inventive concept.

Referring to FIG. 8, an intermediate upper plate 410 of the Y-axis intermediate flexure structure 400 according to an exemplary embodiment of the inventive concept may be spaced apart from the Y-axis datum flexure structure 200 in the Y-axis direction. The intermediate upper plate 410 may be spaced apart from a Y-axis distant upper plate 310 of the Y-axis distant flexure structure 300 in the Y-axis direction. The Y-axis intermediate flexure structure 400 might not be affected by the Y-axis datum flexure structure 200 and the Y-axis distant flexure structure 300.

FIG. 9 is an exploded perspective view of an X-axis mirror support 111x and an X-axis interference mirror 140x of a stage device according to an exemplary embodiment of the inventive concept.

Referring to FIGS. 1 and 9, in the stage device according to an exemplary embodiment of the inventive concept, the X-axis interference mirror 140x may be disposed on the X-axis mirror support 111x. The X-axis datum flexure structure 500, the X-axis distant flexure structure 600, and the X-axis intermediate flexure structure 700 may be disposed between the X-axis mirror support 111x and the X-axis interference mirror 140x.

The X-axis interference mirror 140x may reflect beams radiated by the X-axis interferometer 130x toward the X-axis interferometer 130x. The frequency and phase of beams radiated by the X-axis interferometer 130x may vary according to the frequency and phase of beams Lx reflected by the X-axis interference mirror 140x and an X-axial position of the stage 110.

The X-axis interference mirror 140x may extend in the Y-axis direction. A Y-axial horizontal length of the X-axis interference mirror 140x may be greater than the Y-axial horizontal length of the stage 110. The Y-axial horizontal length of the X-axis interference mirror 140x may be equal to the Y-axial horizontal length of the X-axis mirror support 111x.

The Y-axial horizontal length of the X-axis interference mirror 140x may be equal to the Y-axial horizontal length of the X-axis mirror support 111x. The X-axis interference mirror 140x may have the same area as the X-axis mirror support 111x. For instance, side surfaces of the X-axis mirror support 111x may be vertically aligned with the side surfaces of the X-axis interference mirror 140x.

The X-axis datum flexure structure 500, the X-axis distant flexure structure 600, and the X-axis intermediate flexure structure 700 may fix the X-axis interference mirror 140x. The X-axis interference mirror 140x may be fixed onto the X-axis mirror support 111x by the X-axis datum flexure structure 500, the X-axis distant flexure structure 600, and the X-axis intermediate flexure structure 700.

The X-axis datum flexure structure 500, the X-axis distant flexure structure 600, and the X-axis intermediate flexure structure 700 may be arranged in the Y-axis direction. The X-axis datum flexure structure 500, the X-axis distant flexure structure 600, and the X-axis intermediate flexure structure 700 may be spaced apart from one another in the Y-axis direction. The X-axis distant flexure structure 600 may be spaced apart from the X-axis datum flexure structure 500 in the Y-axis direction. The X-axis intermediate flexure structure 700 may be disposed between the X-axis datum flexure structure 500 and the X-axis distant flexure structure 600.

The X-axis datum flexure structure 500 may be disposed close to a first side surface xs1 of the X-axis mirror support 111x. The first side surface xs1 of the X-axis mirror support 111x may extend in the Y-axis direction. The first side surface xs1 of the X-axis mirror support 111x may be vertically aligned with a first side surface 141xs of the X-axis interference mirror 140x. The X-axis datum flexure structure 500 may be disposed close to the first side surface 141xs of the X-axis interference mirror 140x.

The X-axis distant flexure structure 600 may be disposed close to the first side surface xs1 of the X-axis mirror support 111x. The X-axis distant flexure structure 600 may be disposed close to the first side surface 141xs of the X-axis interference mirror 140x.

The X-axis intermediate flexure structure 700 may be disposed close to a second side surface xs2 of the X-axis mirror support 111x. The second side surface xs2 of the X-axis mirror support 111x may extend in the Y-axis direction. The second side surface xs2 of the X-axis mirror support 111x may be opposite the first side surface xs1 of the X-axis mirror support 111x. The second side surface xs2 of the X-axis mirror support 111x may be vertically aligned with a second side surface 142xs of the X-axis interference mirror 140x. The X-axis intermediate flexure structure 700 may be disposed close to the second side surface 142xs of the X-axis interference mirror 140x.

The stage device according to embodiments of the inventive concept may further include a first X-axis adaptor 151x, a second X-axis adaptor 152x, and a third X-axis adaptor 153x.

The first X-axis adaptor 151x may combine the X-axis datum flexure structure 500 with the X-axis interference mirror 140x. The X-axis datum flexure structure 500 may be combined with the X-axis interference mirror 140x by the first X-axis adaptor 151x. The first X-axis adaptor 151x may be disposed between the X-axis datum flexure structure 500 and the X-axis interference mirror 140x.

The first X-axis adaptor 151x may have the same thermal strain characteristics as the X-axis interference mirror 140x. The first X-axis adaptor 151x may be harder than the X-axis interference mirror 140x. For instance, the first X-axis adaptor 151x may include a metal.

The second X-axis adaptor 152x may combine the first X-axis distant flexure structure 600 with the X-axis interference mirror 140x. The X-axis distant flexure structure 600 may be combined with the X-axis interference mirror 140x by the second X-axis adaptor 152x. The second X-axis adaptor 152x may be disposed between the X-axis distant flexure structure 600 and the X-axis interference mirror 140x.

The second X-axis adaptor 152x may have the same thermal strain characteristics as the X-axis interference mirror 140x. The second X-axis adaptor 152x may be harder than the X-axis interference mirror 140x. The second X-axis adaptor 152x may include the same material as the first X-axis adaptor 151x. For instance, the second X-axis adaptor 152x may include a metal.

The third X-axis adaptor 153x may combine the first X-axis intermediate flexure structure 700 with the X-axis interference mirror 140x. The X-axis intermediate flexure structure 700 may be combined with the X-axis interference mirror 140x by the third X-axis adaptor 153x. The third X-axis adaptor 153x may be disposed between the X-axis intermediate flexure structure 700 and the X-axis interference mirror 140x.

The third X-axis adaptor 153x may have the same thermal strain characteristics as the X-axis interference minor 140x. The third X-axis adaptor 153x may be harder than the X-axis interference mirror 140x. The third X-axis adaptor 153x may include the same material as the first X-axis adaptor 151x. For instance, the third X-axis adaptor 153x may include a metal.

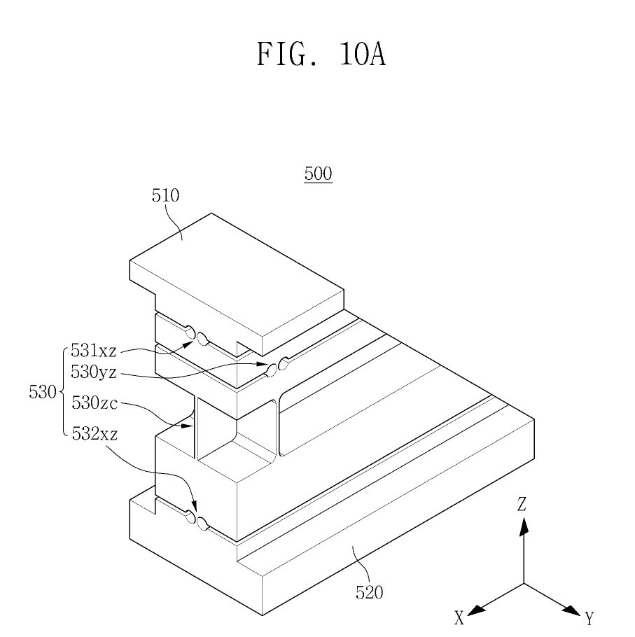

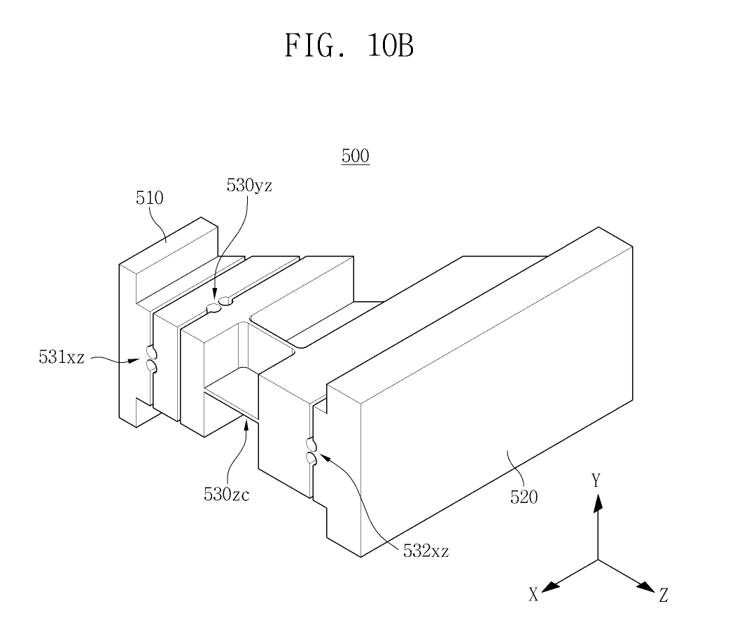

FIGS. 10A and 10B are perspective views of an X-axis datum flexure structure of a stage device according to an exemplary embodiment of the inventive concept.

Referring to FIGS. 9, 10A, and 10B, the X-axis datum flexure structure 500 of the stage device according to an exemplary embodiment of the inventive concept may include an X-axis datum upper plate 510, an X-axis datum lower plate 520 and an X-axis datum hinge part 530. For instance, the X-axis datum flexure structure 500 may be substantially the same as a structure obtained by rotating the Y-axis datum flexure structure 200 shown in FIGS. 5A and 5B by an tilting of about 90° about the Z-axis.

The X-axis datum upper plate 510 may be combined with the X-axis interference mirror 140x. The X-axis datum upper plate 510 may be combined with the X-axis interference mirror 140x by the first X-axis adaptor 151x. For instance, an X-axial horizontal length of the X-axis datum upper plate 510 may be less than or equal to the half of the X-axial horizontal length of the X-axis interference mirror 140x.

The X-axis datum lower plate 520 may be combined with the X-axis mirror support 111x. The X-axis datum lower plate 520 may extend in the Y-axis direction. A Y-axial horizontal length of the X-axis datum lower plate 520 may be greater than a Y-axial horizontal length of the X-axis datum upper plate 510. An X-axial horizontal length of the X-axis datum lower plate 520 may be less than the Y-axial horizontal length of the X-axis mirror support 111x. The Y-axial horizontal length of the X-axis datum lower plate 520 may be less than the Y-axial horizontal length of the X-axis interference mirror 140x.

The X-axis datum hinge part 530 may fix the X-axis datum upper plate 510 in the X-axis direction and the Z-axis direction. The X-axis datum hinge part 530 may be disposed between the X-axis datum upper plate 510 and the X-axis datum lower plate 520.

The X-axis datum hinge part 530 may include a first xz X-axis datum flexure hinge 531xz, a yz X-axis datum flexure hinge 530yz, a zc X-axis datum flexure hinge 530zc, and a second xz X-axis datum flexure hinge 532xz. The first xz X-axis datum flexure hinge 531xz, the yz X-axis datum flexure hinge 530yz, the zc X-axis datum flexure hinge 530zc, and the second xz X-axis datum flexure hinge 532xz may be stacked in the Z-axis direction.

The X-axis datum upper plate 510 may be rotated about the X-axis by the first xz X-axis datum flexure hinge 531xz. The X-axis datum upper plate 510 may be rotated about the Y-axis by the yz X-axis datum flexure hinge 530yz. The X-axis datum upper plate 510 may be rotated about the Z-axis by the zc X-axis datum flexure hinge 530zc. The X-axis datum upper plate 510 may be moved in the Y-axis direction by the first xz X-axis datum flexure hinge 531xz and the second xz Y-axis datum flexure hinge 532xz. The X-axis datum hinge part 530 may fix the X-axis datum upper plate 510 in the X-axis direction and the Z-axis direction.

Accordingly, in the stage device according to an exemplary embodiment of the inventive concept, the X-axis datum hinge part 530 may restrict degrees of freedom for the X-axial motion and the Z-axial motion of a region of the X-axis interference mirror 140x, which may be in contact with the X-axis datum upper plate 510.

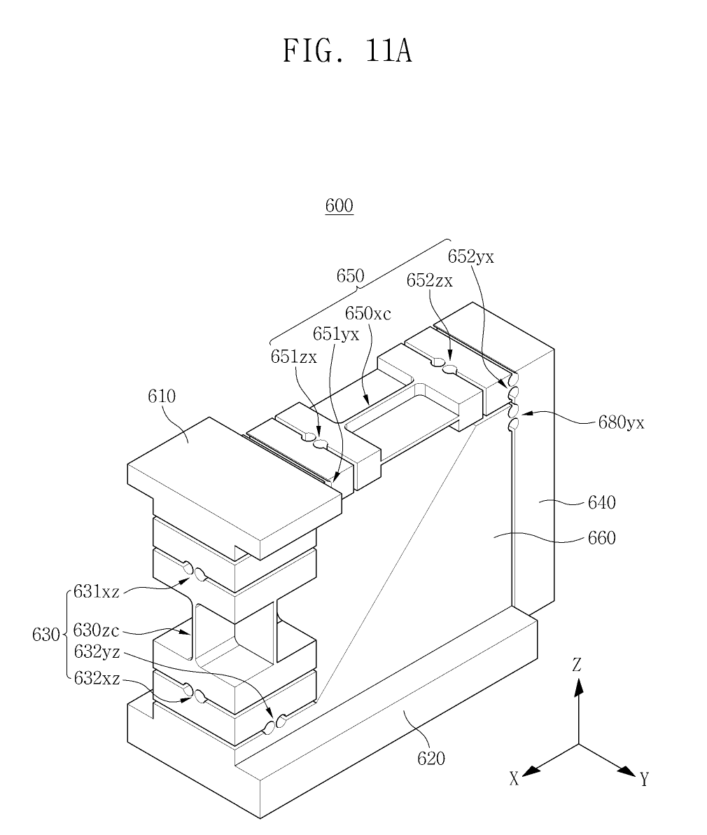

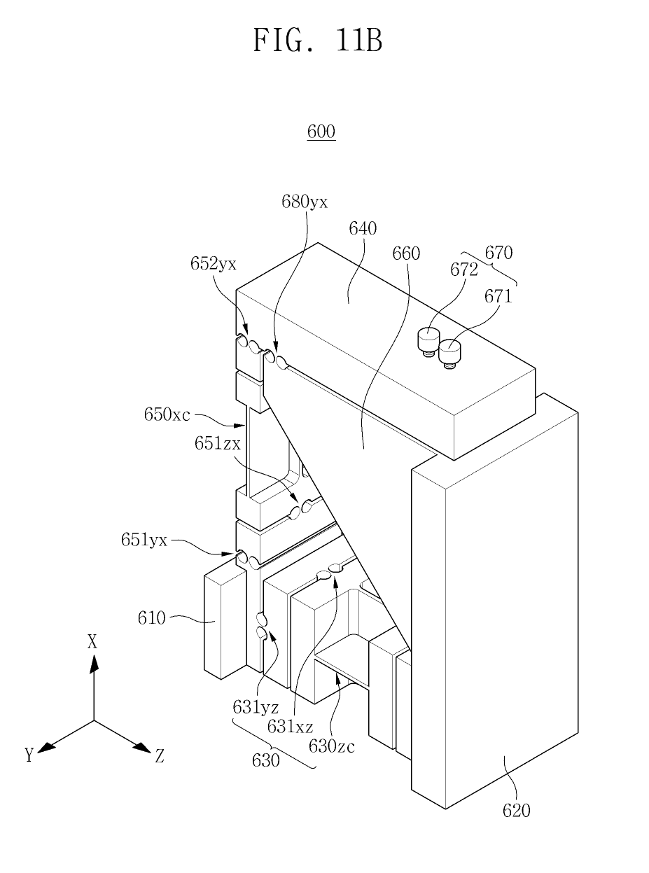

FIGS. 11A and 11B are perspective views of an X-axis distant flexure structure of a stage device according to an exemplary embodiment of the inventive concept.

Referring FIGS. 9, 11A, and 11B, an X-axial distant flexure structure 600 of a stage device according to an exemplary embodiment of the inventive concept may include an X-axis distant upper plate 610, an X-axis distant lower plate 620, a first X-axis distant hinge part 630, a first X-axis distant body 640, a second X-axis distant hinge part 650, a second X-axis distant body 660, an X-axial rotation control member 670, and a yx X-axial rotation flexure hinge 680. For instance, the X-axis distant flexure structure 600 may be substantially the same as a structure obtained by rotating the Y-axis distant flexure structure 300 shown in FIGS. 6A and 6B by an tilting of about 90° about the Z-axis.

The X-axis distant upper plate 610 may be combined with the X-axis interference mirror 140x. The X-axis distant upper plate 610 may be combined with the X-axis interference mirror 140x by the second X-axis adaptor 152x. For instance, an X-axial horizontal length of the X-axis distant upper plate 610 may be less than or equal to the half of the X-axial horizontal length of the X-axis interference mirror 140x.

The X-axis distant lower plate 620 may be combined with the X-axis mirror support 111x. The X-axis distant lower plate 620 may extend in the Y-axis direction. A Y-axial horizontal length of the X-axis distant lower plate 620 may be greater than the Y-axial horizontal length of the X-axis distant upper plate 610. The Y-axial horizontal length of the X-axis distant lower plate 620 may be smaller than the Y-axial horizontal length of the X-axis mirror support 111x. The Y-axial horizontal length of the X-axis distant lower plate 620 may be smaller than the Y-axial horizontal length of the X-axis interference mirror 140x. The Y-axial horizontal length of the X-axis distant lower plate 620 may be different from the Y-axial horizontal length of the X-axis datum lower plate 620.

The first X-axis distant hinge part 630 may fix the X-axis distant upper plate 610 in the Z-axis direction. The first X-axis distant hinge part 630 may be disposed between the X-axis distant upper plate 610 and the X-axis distant lower plate 620.

The first X-axis distant hinge part 630 may include a first yz X-axis distant flexure hinge 631yz, a first xz X-axis distant flexure hinge 631xz, a zc X-axis distant flexure hinge 630zc, a second xz X-axis distant flexure hinge 632xz, and a second yz X-axis distant flexure hinge 632yz. The first yz X-axis distant flexure hinge 631yz, the first xz X-axis distant flexure hinge 631xz, the zc X-axis distant flexure hinge 630zc, the second xz X-axis distant flexure hinge 632xz, and the second yz X-axis distant flexure hinge 632yz may be stacked in the Z-axis direction.

The first X-axis distant body 640 may be spaced apart from the X-axis distant lower plate 620. A bottom surface of the first X-axis distant body 640 may be positioned at a higher level than a bottom surface of the X-axis distant lower plate 620. A top surface of the first X-axis distant body 640 may be positioned at a lower level than a top surface of the first X-axis distant hinge part 630.

The second X-axis distant hinge part 650 may fix the X-axis distant upper plate 610 in the X-axis direction. The second X-axis distant hinge part 650 may be disposed between an upper end of the first X-axis distant hinge part 630 and an upper end of the first X-axis distant body 640.

The second X-axis distant hinge part 650 may include a first yx X-axis distant flexure hinge 651yx, a first zx X-axis distant flexure hinge 651zx, an xc X-axis distant flexure hinge 650xc, a second zx X-axis distant flexure hinge 652zx, and a second yx X-axis distant flexure hinge 652yx. The first yx X-axis distant flexure hinge 651yx, the first zx X-axis distant flexure hinge 651zx, the xc X-axis distant flexure hinge 650xc, the second zx X-axis distant flexure hinge 652zx, and the second yx X-axis distant flexure hinge 652yx may be stacked in the X-axis direction.

The X-axis distant upper plate 610 may be rotated about the Y-axis by the first yx X-axis distant flexure hinge 651yx. The X-axis distant upper plate 610 may be rotated about the Z-axis by the first zx X-axis distant flexure hinge 651zx. The X-axis distant upper plate 610 may be rotated about the X-axis by the xc X-axis distant flexure hinge 650xc. The X-axis distant upper plate 610 may be moved in the Y-axis direction by the first zx X-axis distant flexure hinge 651zx and the second zx X-axis distant flexure hinge 652zx. The X-axis distant upper plate 610 may be moved in the Z-axis direction by the first yx X-axis distant flexure hinge 651yx and the second yx X-axis distant flexure hinge 652yx.

Accordingly, in the stage device according to an exemplary embodiment of the inventive concept, the first X-axis distant hinge part 630 and the second X-axis distant hinge part 650 may restrict degrees of freedom for the X-axial motion and the Z-axial motion of a region of the X-axis interference mirror 140x, which may be in contact with the X-axis distant upper plate 610.

The second X-axis distant body 660 may be disposed between the first X-axis distant hinge part 630 and the first X-axis distant body 640. The second X-axis distant body 660 may be fixed onto the X-axis distant lower plate 620. A top surface of the second X-axis distant body 660 may be positioned at a lower level than a top surface of the first X-axis distant body 640.

The X-axial rotation control member 670 may control a space between the first X-axis distant body 640 and the second X-axis distant body 660. The X-axial rotation control member 670 may be disposed at a lower end of the first X-axis distant body 640. The X-axial rotation control member 670 may include an X-axis distant spacing member 671 and an X-axis distant fixing member 672.

The yx X-axial rotation flexure hinge 680 may be disposed between an upper end of the second X-axis distant body 660 and the first X-axis distant body 640. The yx X-axial rotation flexure hinge 680 may be a horizontal-type flexure hinge extending in the Y-axis direction.

Accordingly, in the stage device according to an exemplary embodiment of the inventive concept, the Z-axial rotation of a reflection surface of the X-axis interference mirror 140x may be controlled by the X-axis distant flexure structure 600.

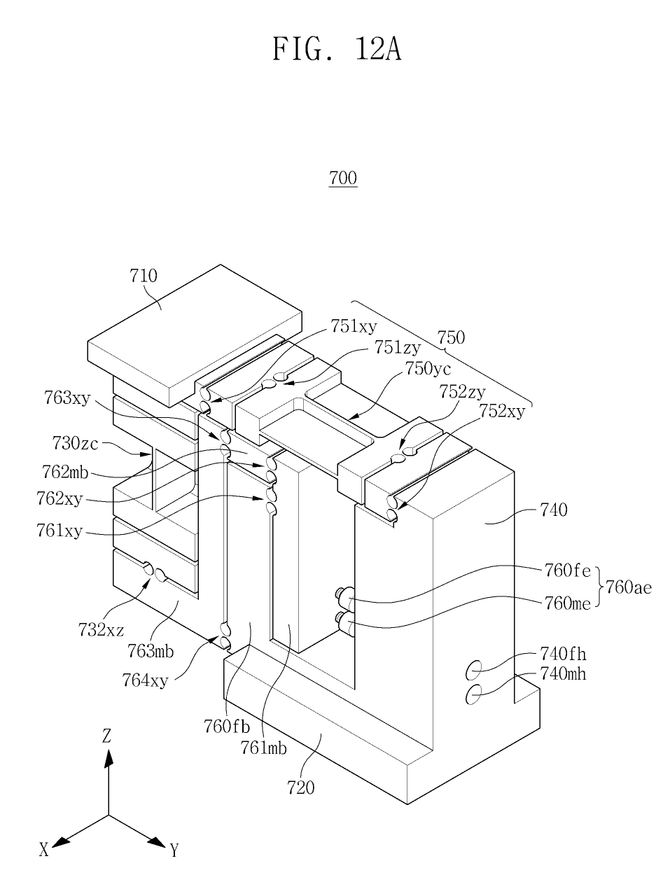

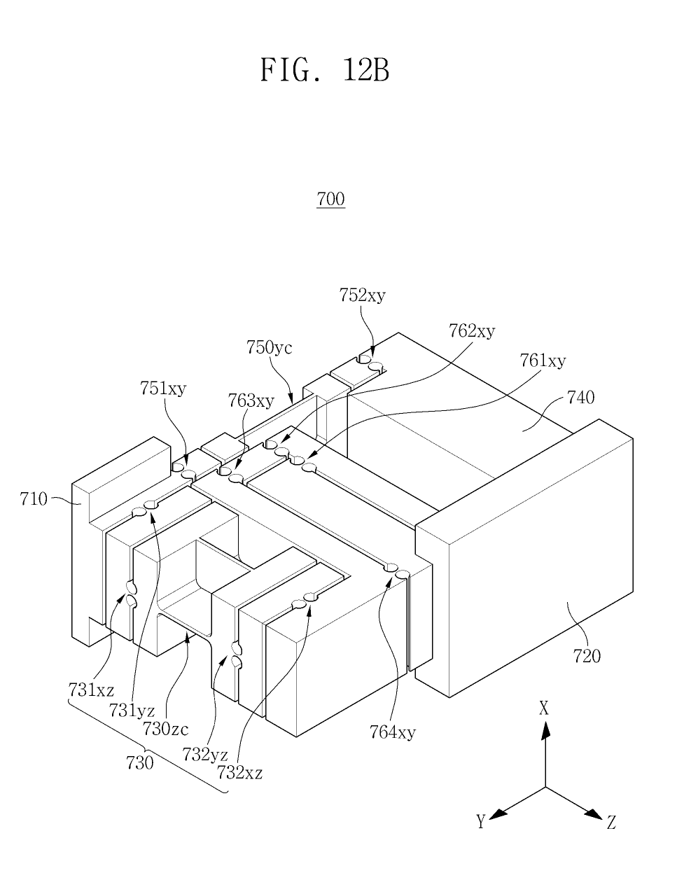

FIGS. 12A and 12B are perspective views of an X-axis intermediate flexure structure 700 of a stage device according to an exemplary embodiment of the inventive concept.

Referring to FIGS. 9, 12A, and 12B, the X-axis intermediate flexure structure 700 of the stage device according to an exemplary embodiment of the inventive concept may include an X-axis intermediate upper plate 710, an X-axis intermediate lower plate 720, a first X-axis intermediate hinge part 730, an X-axis intermediate fixing body 740, a second X-axis intermediate hinge part 750, and an X-axis tilting control member 760. For instance, the X-axis intermediate flexure structure 700 may be substantially the same as a structure obtained by rotating the Y-axis intermediate flexure structure 400 shown in FIGS. 7A and 7B by about 90° about the Z-axis.

The X-axis intermediate upper plate 710 may be combined with the X-axis interference mirror 140x. The X-axis intermediate upper plate 710 may be combined with the X-axis interference mirror 140x by the third X-axis adaptor 153x. For instance, an X-axial horizontal length of the X-axis intermediate upper plate 710 may be less than or equal to the half of the X-axial horizontal length of the X-axis interference mirror 140x.

The X-axis intermediate lower plate 720 may be combined with the X-axis mirror support 111x. The X-axis intermediate lower plate 720 may be spaced apart from the X-axis intermediate upper plate 710 in the X-axis direction. A bottom surface of the X-axis intermediate lower plate 720 may be positioned at a lower level than the bottom surface of the first X-axis intermediate hinge part 730. The X-axis intermediate lower plate 720 may extend in the Y-axis direction.

An X-axial horizontal length of the X-axis intermediate lower plate 720 may be smaller than the X-axial horizontal length of the X-axis mirror support 111x. The X-axial horizontal length of the X-axis intermediate lower plate 720 may be smaller than the X-axial horizontal length of the X-axis interference mirror 140x. The X-axial horizontal length of the X-axis intermediate lower plate 720 may be equal to the X-axial horizontal length of the X-axis intermediate upper plate 710.

The first X-axis intermediate hinge part 730 may fix the X-axis intermediate upper plate 710 in the Z-axis direction. The first X-axis intermediate hinge part 730 may be disposed under the X-axis intermediate upper plate 710.

The first X-axis intermediate hinge part 730 may include a first xz X-axis intermediate flexure hinge 731xz, a first yz X-axis intermediate flexure hinge 731yz, a zc X-axis intermediate flexure hinge 730zc, a second yz X-axis intermediate flexure hinge 732yz, and a second xz X-axis intermediate flexure hinge 732xz. The first xz X-axis intermediate flexure hinge 731xz, the first yz X-axis intermediate flexure hinge 731yz, the zc X-axis intermediate flexure hinge 730zc, the second yz X-axis intermediate flexure hinge 732yz, and the second xz X-axis intermediate flexure hinge 732xz may be stacked in the Z-axis direction.

The X-axis intermediate fixing body 740 may be spaced apart from the first X-axis intermediate hinge part 730 in the X-axis direction. The X-axis intermediate fixing body 740 may be fixed onto the X-axis intermediate lower plate 720. The first X-axis intermediate fixing body 740 may extend in the Z-axis direction. A top surface of the first X-axis intermediate fixing body 740 may be positioned at a lower level than a top surface of the X-axis intermediate upper plate 710.

The second X-axis intermediate hinge part 750 may fix the X-axis intermediate upper plate 710 in the X-axis direction. The second X-axis intermediate hinge part 750 may be disposed between an upper end of the first X-axis intermediate hinge part 730 and an upper end of the X-axis intermediate fixing body 740.

The second X-axis intermediate hinge part 750 may include a first xy X-axis intermediate flexure hinge 751xy, a first zy X-axis intermediate flexure hinge 751zy, a yc X-axis intermediate flexure hinge 750yc, a second zy X-axis intermediate flexure hinge 752zy, and a second xy X-axis intermediate flexure hinge 752xy. The first xy X-axis intermediate flexure hinge 751xy, the first zy X-axis intermediate flexure hinge 751zy, the yc X-axis intermediate flexure hinge 750yc, the second zy X-axis intermediate flexure hinge 752zy, and the second xy X-axis intermediate flexure hinge 752xy may be stacked in the Y-axis direction.

Accordingly, in the stage device according to an exemplary embodiment of the inventive concept, the first X-axis intermediate hinge part 730 and the second X-axis intermediate hinge part 750 may restrict degrees of freedom for the Y-axial motion and the Z-axial motion of a region of the X-axis interference mirror 140x, which may be in contact with the X-axis intermediate upper plate 710.

The X-axis tilting control part 760 may control a Z-axial position of the X-axis intermediate upper plate 710. The X-axis tilting control part 760 may be disposed under the second X-axis intermediate hinge part 750.

The X-axis tilting control part 760 may include an X-axis tilting fixing body 760fb, a first X-axis tilting control body 761mb, a second X-axis tilting control body 762mb, a third X-axis tilting control body 763mb, a first xy X-axis tilting flexure hinge 761xy, a second xy X-axis tilting flexure hinge 762xy, a third xy X-axis tilting flexure hinge 763xy, a fourth xy X-axis tilting flexure hinge 764xy, and an X-axis tilting control member 760ae.

The X-axis tilting fixing body 760th may be disposed between the first X-axis intermediate hinge part 730 and the X-axis intermediate fixing body 740. The first X-axis tilting control body 761mb may be disposed between the X-axis tilting fixing body 760th and the X-axis intermediate fixing body 740. The second X-axis tilting control body 762mb may be surrounded with the X-axis tilting fixing body 760fb, the second X-axis intermediate hinge part 750, the first X-axis tilting control body 761mb, and the third X-axis tilting control body 763mb. The third X-axis tilting control body 763mb may be disposed between the first X-axis intermediate hinge part 730 and the X-axis tilting fixing body 760fb. The first xy X-axis tilting flexure hinge 761xy may be disposed between an upper end of the X-axis tilting fixing body 760fb and the first X-axis tilting control body 461mb. The second xy X-axis tilting flexure hinge 762xy may be disposed between the first X-axis tilting control body 761mb and the second X-axis tilting control body 762mb. The third xy X-axis tilting flexure hinge 763xy may be disposed between the second X-axis tilting control body 762mb and the third X-axis tilting control body 763mb. The fourth xy X-axis tilting flexure hinge 764xy may be disposed between a lower end of the X-axis tilting fixing body 760fb and the third X-axis tilting control body 763mb. The X-axis tilting control member 760ae may be disposed at a lower end of the first X-axis tilting control body 761mb.

The first to fourth xy X-axis tilting flexure hinge 761xy to 764xy may be a horizontal-type flexure hinge extending in the X-axis direction. The X-axis tilting control member 760ae may include an X-axis intermediate spacing member 760me and an X-axis intermediate fixing member 760fe. The X-axis intermediate fixing body 740 may include a first through hole 740mh and a second through hole 740fh.

In the X-axis intermediate flexure structure 700 of the stage device according to an exemplary embodiment of the inventive concept, Z-axial positions of the X-axis intermediate upper plate 710 and the first X-axis intermediate hinge part 730 may be controlled by the X-axis tilting control member 760ae.

Accordingly, in the stage device according to an exemplary embodiment of the inventive concept, the Y-axial rotation of the reflection surface of the X-axis interference mirror 140x may be controlled by the X-axis intermediate flexure structure 700.

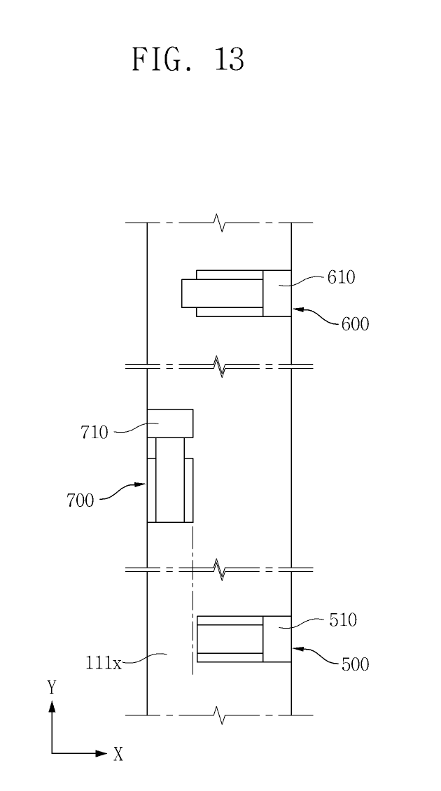

FIG. 13 is a plan view of an X-axis datum flexure structure 500, an X-axis distant flexure structure 600, and an X-axis intermediate flexure structure 700 of a stage device according to an exemplary embodiment of the inventive concept.

Referring to FIG. 13, in the stage device according to an exemplary embodiment of the inventive concept, an X-axis intermediate upper plate 710 of the X-axis intermediate flexure structure 700 may be spaced apart from an X-axis datum upper plate 510 of the X-axis datum flexure structure 500 and an X-axis distant upper plate 610 of the X-axis distant flexure structure 600 in the X-axis direction. Accordingly, in the stage device according to an exemplary embodiment of the inventive concept, the X-axis intermediate flexure structure 700 might not be affected by the X-axis datum flexure structure 500 and the X-axis distant flexure structure 600.

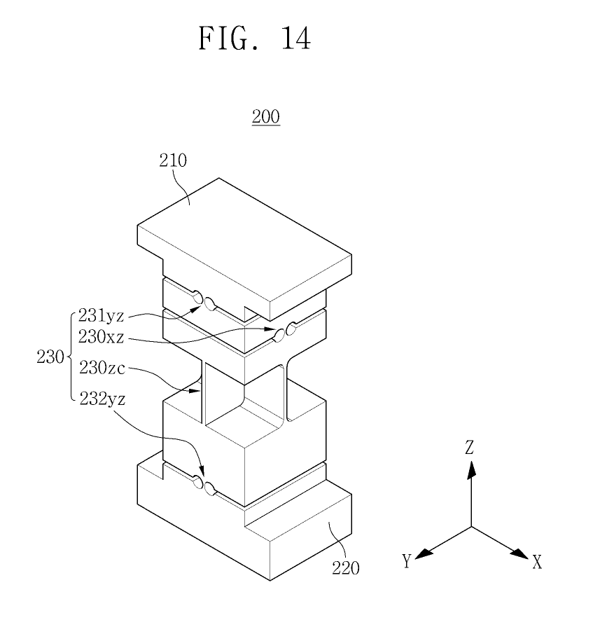

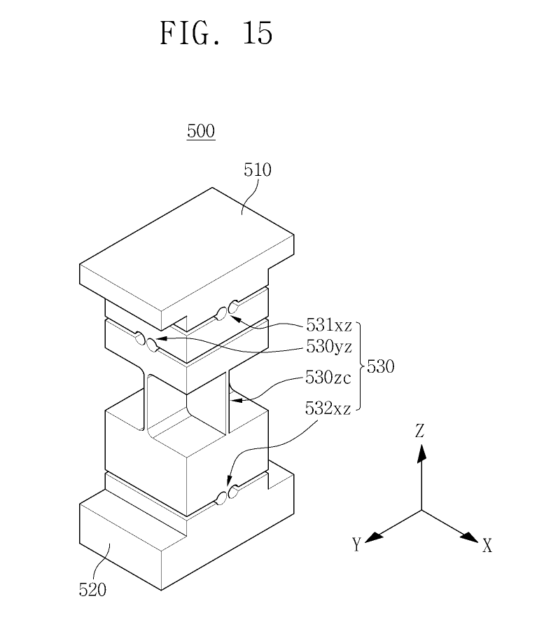

FIG. 14 is a perspective view of a Y-axis datum flexure structure of a stage device according to an exemplary embodiment of the inventive concept. FIG. 15 is a perspective view of an X-axis datum flexure structure of a stage device according to an exemplary embodiment of the inventive concept.

Referring to FIGS. 14 and 15, the stage device according to an exemplary embodiment of the inventive concept may include a Y-axis datum structure 200 and an X-axis datum structure 500. The Y-axis datum structure 200 may include a Y-axis datum upper plate 210, a Y-axis datum lower plate 220, and a Y-axis datum hinge part 230. The X-axis datum structure 500 may include an X-axis datum upper plate 510, an X-axis datum lower plate 520, and an X-axis datum hinge part 530.

A Y-axial horizontal length of the Y-axis datum lower plate 220 may be equal to the Y-axial horizontal length of the Y-axis datum upper plate 210.

The Y-axis datum hinge part 230 may include a first yz Y-axis datum flexure hinge 231yz, an xz Y-axis datum flexure hinge 230xz, a zc Y-axis datum flexure hinge 230zc, and a second yz Y-axis datum flexure hinge 232yz, which may be stacked in the Z-axis direction.

A Y-axial horizontal length of the first yz Y-axis datum flexure hinge 231yz may be equal to a Y-axial horizontal length of the xz Y-axis datum flexure hinge 230xz. The Y-axial horizontal length of the xz Y-axis datum flexure hinge 230xz may be equal to a Y-axial horizontal length of the zc Y-axis datum flexure hinge 230zc. The Y-axial horizontal length of the zc Y-axis datum flexure hinge 230zc may be equal to a Y-axial horizontal length of the second yz Y-axis datum flexure hinge 232yz. For instance, a Y-axial horizontal length of the Y-axis datum hinge part 230 may be equal to the Y-axial horizontal length of the Y-axis datum upper plate 210.

An X-axis horizontal length of the X-axis datum lower plate 520 may be equal to the X-axial horizontal length of the X-axis datum upper plate 510. For instance, an X-axial horizontal length of the X-axis datum upper plate 510 may be equal to the Y-axial horizontal length of the Y-axis datum upper plate 210.

The X-axis datum hinge part 530 may include a first xz X-axis datum flexure hinge 531xz, a yz X-axis datum flexure hinge 530yz, a zc X-axis datum flexure hinge 530zc, and a second xz X-axis datum flexure hinge 532xz, which may be stacked in the Z-axis direction.

An X-axial horizontal length of the first xz X-axis datum flexure hinge 531xz may be equal to an X-axial horizontal length of the yz X-axis datum flexure hinge 530yz. The X-axial horizontal length of the yz X-axis datum flexure hinge 530yz may be equal to an X-axial horizontal length of the zc X-axis datum flexure hinge 530zc. The X-axial horizontal length of the zc X-axis datum flexure hinge 530zc may be equal to an X-axial horizontal length of the second xz X-axis datum flexure hinge 532xz. For instance, an X-axial horizontal length of the X-axis datum hinge part 530 may be equal to the X-axial horizontal length of the X-axis datum upper plate 510.

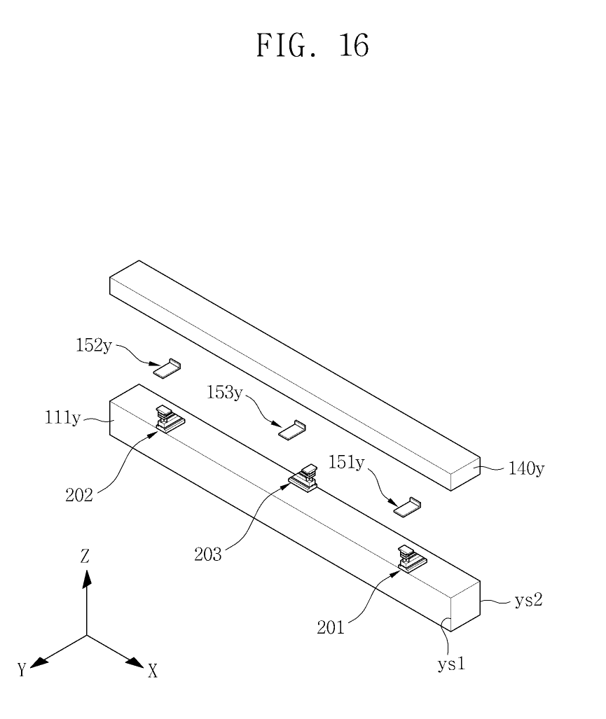

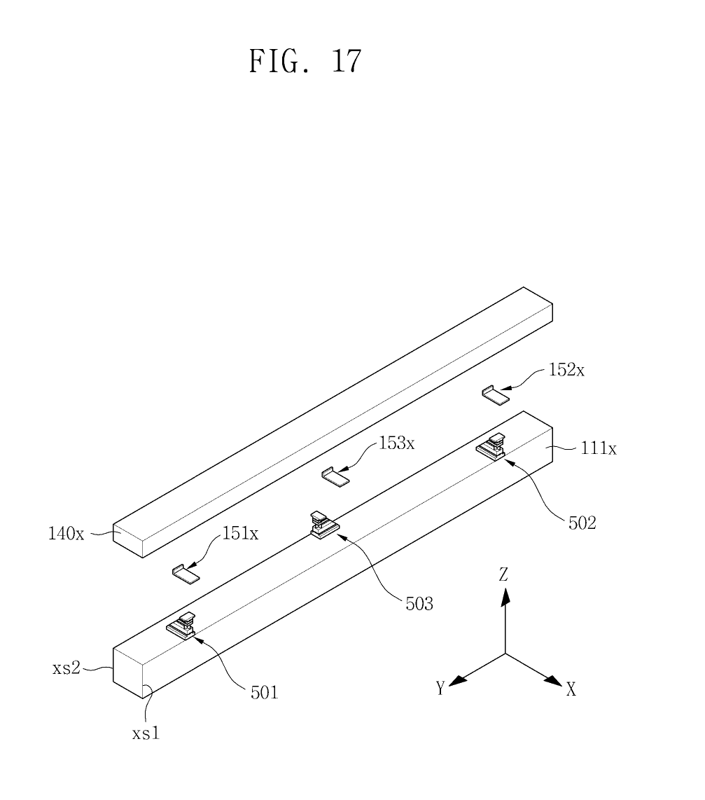

FIG. 16 is an exploded perspective view of a Y-axis mirror support and a Y-axis interference mirror of a stage device according to an exemplary embodiment of the inventive concept. FIG. 17 is an exploded perspective view of an X-axis mirror support and an X-axis interference mirror of a stage device according to an exemplary embodiment of the inventive concept.

Referring to FIGS. 16 and 17, the stage device according to an exemplary embodiment of the inventive concept may include first to third Y-axis datum flexure structures 201 to 203 configured to fix the Y-axis interference mirror 140y, and first to third X-axis datum flexure structures 501 to 503 configured to fix the X-axis interference mirror 140x.

The first to third Y-axis datum flexure structures 201 to 203 may be disposed on a top surface of the Y-axis mirror support 111y. The Y-axis interference mirror 140y may be disposed on the first to third Y-axis datum flexure structures 201 to 203. The first to third Y-axis datum flexure structures 201 to 203 may be disposed between the Y-axis mirror support 111y and the Y-axis interference mirror 140y. The Y-axis interference mirror 140y may be fixed onto the Y-axis mirror support 111y by the first to third Y-axis datum flexure structures 201 to 203.

The first Y-axis datum flexure structure 201 may fix a partial region of the Y-axis interference mirror 140y in the Y-axis direction and the Z-axis direction. The first Y-axis datum flexure structure 201 may be combined with a bottom surface of the Y-axis interference mirror 140y by the first Y-axis adaptor 151y.

The first Y-axis datum flexure structure 201 may be disposed close to the first side surface ys1 of the Y-axis mirror support 111y. The first Y-axis datum flexure structure 201 may include datum flexure hinges configured to fix a region combined with the Y-axis interference mirror 140y in the Y-axis direction and the Z-axis direction. The first Y-axis datum flexure structure 201 may have a shape extending in the Y-axis direction.

The second Y-axis datum flexure structure 202 may fix a partial region of the Y-axis interference mirror 140y in the Y-axis direction and the Z-axis direction. The second Y-axis datum flexure structure 202 may be combined with the bottom surface of the Y-axis interference mirror 140y by the second Y-axis adaptor 152y.

The second Y-axis datum flexure structure 202 may be spaced apart from the first Y-axis datum flexure structure 201 in the X-axis direction. The second Y-axis datum flexure structure 202 may be disposed close to the first side surface ys1 of the Y-axis mirror support 111y.

The second Y-axis datum flexure structure 202 may include datum flexure hinges configured to fix the region combined with the Y-axis interference mirror 140y in the Y-axis direction and the Z-axis direction. For instance, the second Y-axis datum flexure structure 202 may have substantially the same structure as the first Y-axis datum flexure structure 201. The second Y-axis datum flexure structure 202 may have a shape extending in the Y-axis direction.

The third Y-axis datum flexure structure 203 may fix a partial region of the Y-axis interference mirror 140y in the X-axis direction and the Z-axis direction. The third Y-axis datum flexure structure 203 may be combined with the bottom surface of the Y-axis interference mirror 140y by the third Y-axis adaptor 153y.

The third Y-axis datum flexure structure 203 may be disposed between the first Y-axis datum flexure structure 201 and the second Y-axis datum flexure structure 202. The third Y-axis datum flexure structure 203 may be disposed close to the second side surface ys2 of the Y-axis mirror support 111y.

The third Y-axis datum flexure structure 203 may include datum flexure hinges configured to fix the region combined with the Y-axis interference mirror 140y in the X-axis direction and the Z-axis direction. For instance, the third Y-axis datum flexure structure 203 may be substantially the same as a structure obtained by rotating the first Y-axis datum flexure structure 201 by about 90° about the Z-axis. The third Y-axis datum flexure structure 203 may have a shape extending in the X-axis direction.

The first to third X-axis datum flexure structures 501 to 503 may be disposed on a top surface of the X-axis mirror support 111x. The X-axis interference mirror 140x may be disposed on the first to third X-axis datum flexure structures 501 to 503. The first to third X-axis datum flexure structures 501 to 503 may be disposed between the X-axis mirror support 111x and the X-axis interference mirror 140x. The X-axis interference mirror 140x may be fixed onto the X-axis mirror support 111x by the first to third X-axis datum flexure structures 501 to 503.

The first X-axis datum flexure structure 501 may fix a partial region of the X-axis interference mirror 140x in the X-axis direction and the Z-axis direction. The first X-axis datum flexure structure 501 may be combined with the bottom surface of the X-axis interference mirror 140x by first X-axis adaptor 151x.

The first X-axis datum flexure structure 501 may be disposed close to the first side surface xs1 of the X-axis mirror support 111x. The first X-axis datum flexure structure 501 may include datum flexure hinges configured to fix the region combined with the X-axis interference mirror 140x in the X-axis direction and the Z-axis direction. The first X-axis datum flexure structure 501 may have a shape extending in the X-axis direction.

The second X-axis datum flexure structure 502 may fix a partial region of the X-axis interference mirror 140x in the X-axis direction and the Z-axis direction. The second X-axis datum flexure structure 502 may be combined with the bottom surface of the X-axis interference mirror 140x by the second X-axis adaptor 152x.

The second X-axis datum flexure structure 502 may be spaced apart from the first X-axis datum flexure structure 501 in the X-axis direction. The second X-axis datum flexure structure 502 may be disposed close to the first side surface xs1 of the X-axis mirror support 111x.

The second X-axis datum flexure structure 502 may include datum flexure hinges configured to fix the region combined with the X-axis interference mirror 140x in the X-axis direction and the Z-axis direction. For instance, the second X-axis datum flexure structure 502 may have substantially the same structure as the first X-axis datum flexure structure 501. The second X-axis datum flexure structure 502 may have a shape extending in the X-axis direction.

The third X-axis datum flexure structure 503 may fix a partial region of the X-axis interference mirror 140x in the Y-axis direction and the Z-axis direction. The third X-axis datum flexure structure 503 may be combined with the bottom surface of the X-axis interference mirror 140x by the third X-axis adaptor 153x.

The third X-axis datum flexure structure 503 may be disposed between the first X-axis datum flexure structure 501 and the second X-axis datum flexure structure 502. The third X-axis datum flexure structure 503 may be disposed close to the second side surface xs2 of the X-axis minor support 111x.

The third X-axis datum flexure structure 503 may include datum flexure hinges configured to fix the region combined with the X-axis interference mirror 140x in the Y-axis direction and the Z-axis direction. For instance, the third X-axis datum flexure structure 503 may be substantially the same as a structure obtained by rotating the first X-axis datum flexure structure 501 by about 90° about the Z-axis. The third X-axis datum flexure structure 503 may have a shape extending in the Y-axis direction.

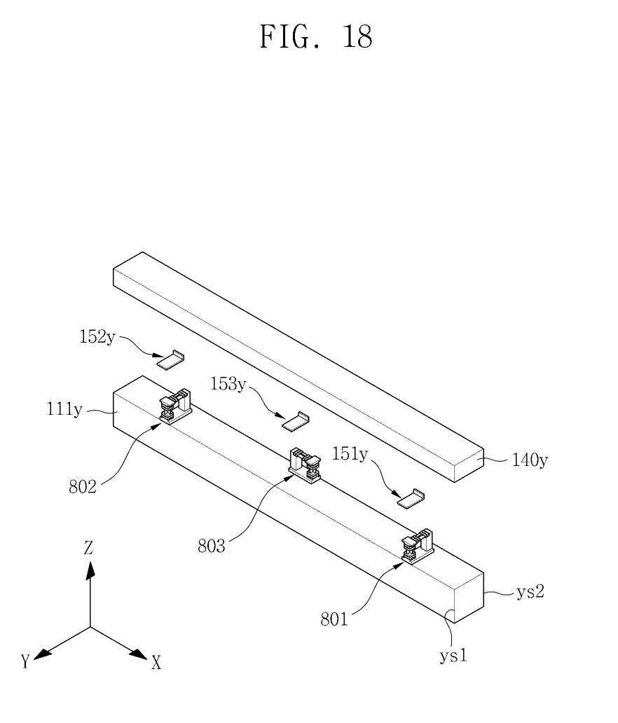

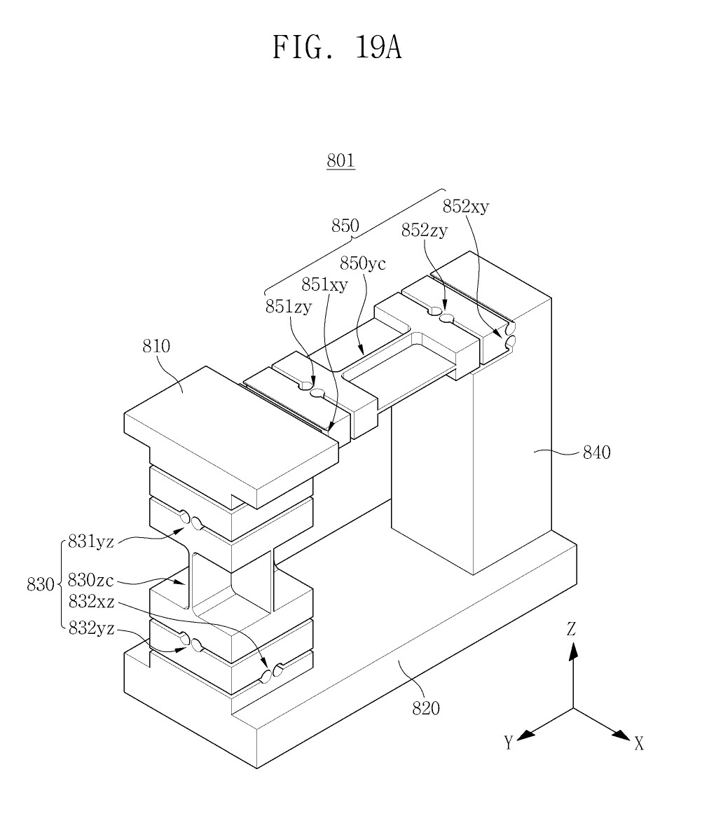

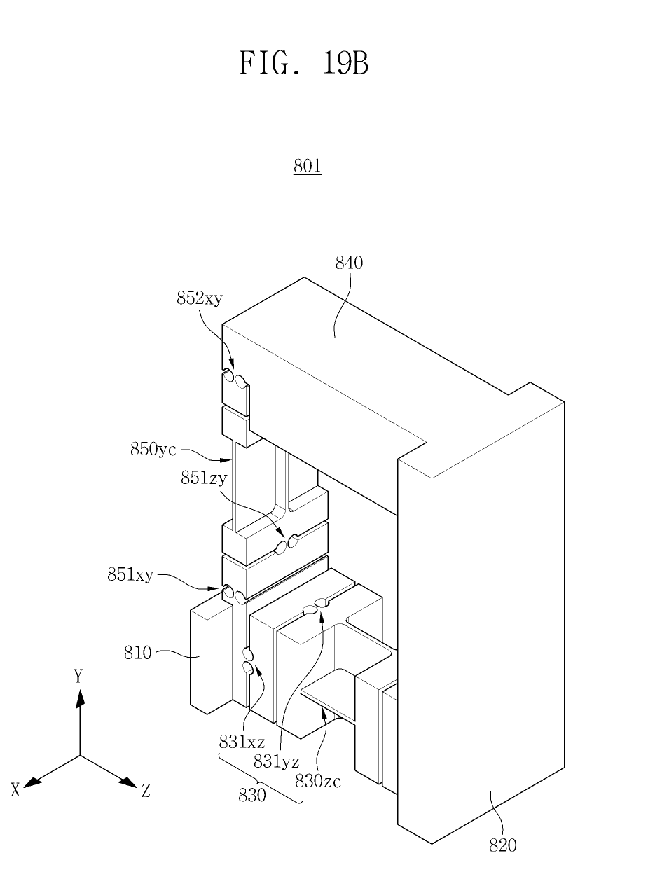

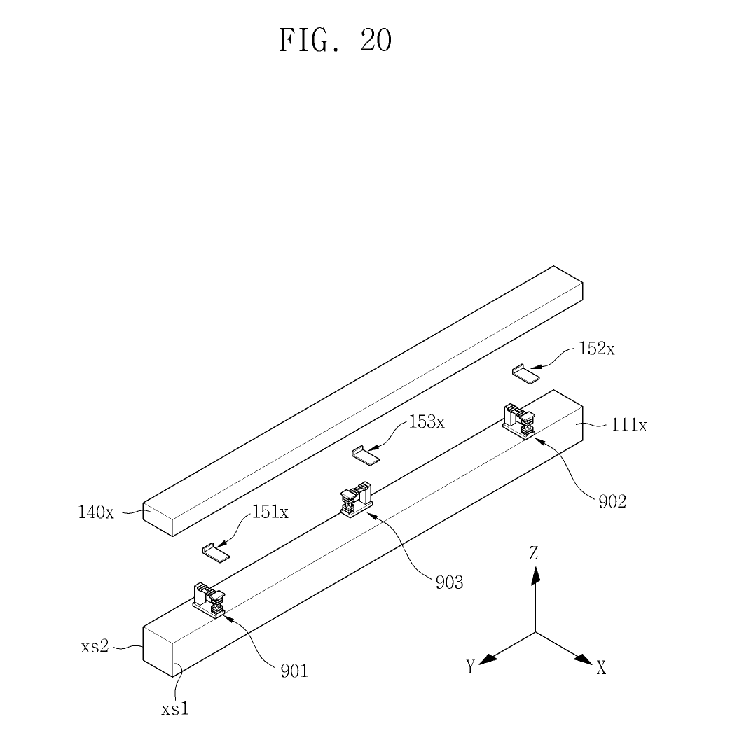

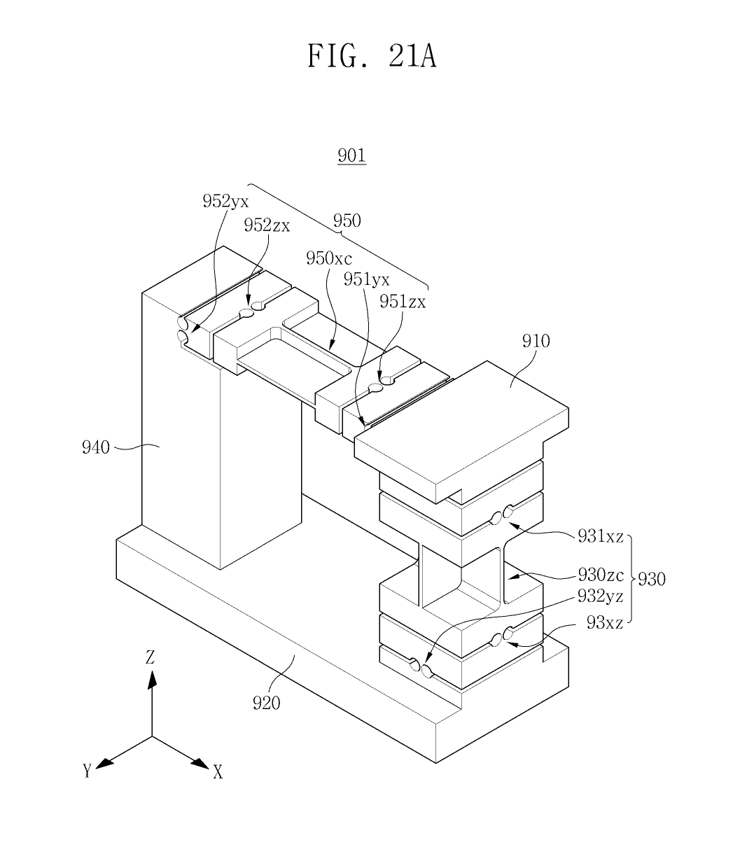

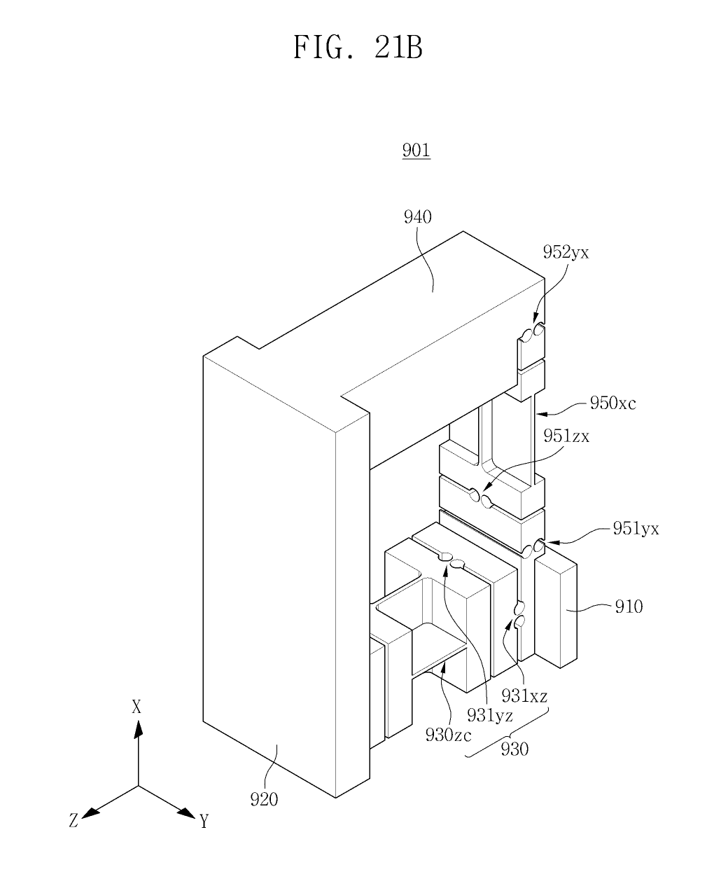

FIG. 18 is an exploded perspective view of a Y-axis mirror support and a Y-axis interference mirror of a stage device according to an exemplary embodiment of the inventive concept. FIGS. 19A and 19B are perspective views of a first Y-axis fixing flexure structure of a stage device according to an exemplary embodiment of the inventive concept. FIG. 20 is an exploded perspective view of an X-axis mirror support and an X-axis interference mirror of a stage device according to an exemplary embodiment of the inventive concept. FIGS. 21A and 21B are perspective views of a first X-axis fixing flexure structure of a stage device according to an exemplary embodiment of the inventive concept.

The first to third Y-axis fixing flexure structures 801 to 803 may be disposed on the top surface of the Y-axis mirror support 111y. The Y-axis interference mirror 140y may be disposed on the first to third Y-axis fixing flexure structures 801 to 803. The first to third Y-axis fixing flexure structures 801 to 803 may be disposed between the Y-axis mirror support 111y and the Y-axis interference mirror 140y. The Y-axis interference mirror 140y may be fixed onto the Y-axis mirror support 111y by the first to third Y-axis fixing flexure structures 801-803.

The first Y-axis fixing flexure structure 801 may fix a partial region of the Y-axis interference mirror 140y in the Y-axis direction and the Z-axis direction. The first Y-axis fixing flexure structure 801 may be combined with the bottom surface of the Y-axis interference mirror 140y by the first Y-axis adaptor 151y.

The first Y-axis fixing flexure structure 801 may be disposed close to the first side surface ys1 of the Y-axis mirror support 111y. The first Y-axis fixing flexure structure 801 may include a Y-axis fixing upper plate 810, a Y-axis fixing lower plate 820, a first Y-axis fixing hinge part 830, a Y-axis fixing body 840, and a second Y-axis fixing hinge part 850.

The Y-axis fixing upper plate 810 may be combined with the Y-axis interference mirror 140y. The Y-axis fixing upper plate 810 may be combined with the Y-axis interference mirror 140y by the first Y-axis adaptor 151y.

The Y-axis fixing lower plate 820 may be combined with the Y-axis mirror support 111y. The Y-axis fixing lower plate 820 may extend in the Y-axis direction. A Y-axial horizontal length of the Y-axis fixing lower plate 820 may be greater than a Y-axial horizontal length of the Y-axis fixing upper plate 810.

The first Y-axis fixing hinge part 830 may fix the Y-axis fixing upper plate 810 in the Z-axis direction. The first Y-axis fixing hinge part 830 may be disposed between the Y-axis fixing upper plate 810 and the Y-axis fixing lower plate 820. A Y-axial horizontal length of the first Y-axis fixing hinge part 830 may be equal to a Y-axial horizontal length of the first Y-axis fixing upper plate 810.

The first Y-axis fixing hinge part 830 may include a first xz Y-axis fixing flexure hinge 831xz, a first yz Y-axis fixing flexure hinge 831yz, a zc Y-axis fixing flexure hinge 830zc, a second yz Y-axis fixing flexure hinge 832yz, and a second xz Y-axis fixing flexure hinge 832xz. The first xz Y-axis fixing flexure hinge 831xz, the first yz Y-axis fixing flexure hinge 831yz, the zc Y-axis fixing flexure hinge 830zc, the second yz Y-axis fixing flexure hinge 832yz, and the second xz Y-axis fixing flexure hinge 832xz may be stacked in the Z-axis direction.

The first xz Y-axis fixing flexure hinge 831xz and the second xz Y-axis fixing flexure hinge 832xz may be vertical-type flexure hinges extending in the X-axis direction. The zc Y-axis fixing flexure hinge 830zc may be a cross-type flexure hinge extending in the Z-axis direction. The first yz Y-axis fixing flexure hinge 831yz and the second yz Y-axis fixing flexure hinge 832yz may be vertical-type flexure hinges extending in the Y-axis direction.

The Y-axis fixing body 840 may be spaced apart from the first Y-axis fixing hinge part 830 in the Y-axis direction. The Y-axis fixing body 840 may be fixed onto the Y-axis fixing lower plate 820. A top surface of the Y-axis fixing body 840 may be positioned at a lower level than a top surface of the Y-axis fixing upper plate 810.

The second Y-axis fixing hinge part 850 may fix the Y-axis fixing upper plate 810 in the Y-axis direction. The second Y-axis fixing hinge part 850 may be disposed between an upper end of the first Y-axis fixing hinge part 830 and an upper end of the Y-axis fixing body 840. A Y-axial horizontal length of the second Y-axis fixing hinge part 850 may be equal to a Y-axial horizontal length between the first Y-axis fixing hinge part 830 and the Y-axis fixing body 840.

The second Y-axis fixing hinge part 850 may include a first xy Y-axis fixing flexure hinge 851xy, a first zy Y-axis fixing flexure hinge 851zy, a yc Y-axis fixing flexure hinge 850yc, a second zy Y-axis fixing flexure hinge 852zy, and a second xy Y-axis fixing flexure hinge 852xy. The first xy Y-axis fixing flexure hinge 851xy, the first zy Y-axis fixing flexure hinge 851zy, the yc Y-axis fixing flexure hinge 850yc, the second zy Y-axis fixing flexure hinge 852zy, and the second xy Y-axis fixing flexure hinge 852xy may be stacked in the Y-axis direction.

The first xy Y-axis fixing flexure hinge 851xy and the second xy Y-axis fixing flexure hinge 852xy may be horizontal flexure hinges extending in the X-axis direction. The yc Y-axis fixing flexure hinge 850yc may be a cross-type flexure hinge extending in the Y-axis direction. The first zy Y-axis fixing flexure hinge 851zy and the second zy Y-axis fixing flexure hinge 852zy may be Y-axial flexure hinges extending in the Z-axis direction.

The second Y-axis fixing flexure structure 802 may fix a partial region of the Y-axis interference mirror 140y in the Y-axis direction and the Z-axis direction. The second Y-axis fixing flexure structure 802 may be combined with the bottom surface of the Y-axis interference mirror 140y by the second Y-axis adaptor 152y.

The second Y-axis fixing flexure structure 802 may be spaced apart from the first Y-axis fixing flexure structure 801 in the X-axis direction. The second Y-axis fixing flexure structure 802 may be disposed close to the first side surface ys1 of the Y-axis mirror support 111y.

The second Y-axis fixing flexure structure 802 may include fixing flexure hinges configured to fix the region combined with the Y-axis interference mirror 140y in the Y-axis direction and the Z-axis direction. For instance, the second Y-axis fixing flexure structure 802 may have substantially the same structure as the first Y-axis fixing flexure structure 801.

The third Y-axis fixing flexure structure 803 may fix a partial region of the Y-axis interference mirror 140y in the X-axis direction and the Z-axis direction. The third Y-axis fixing flexure structure 803 may be combined with the bottom surface of the Y-axis interference mirror 140y by the third Y-axis adaptor 153y.

The third Y-axis fixing flexure structure 803 may be disposed between the first Y-axis fixing flexure structure 801 and the second Y-axis fixing flexure structure 802. The third Y-axis fixing flexure structure 803 may be disposed close to the second side surface ys2 of the Y-axis mirror support 111y.

The third Y-axis fixing flexure structure 803 may include fixing flexure hinges configured to fix the region combined with the Y-axis interference mirror 140y in the X-axis direction and the Z-axis direction. For instance, the third Y-axis fixing flexure structure 803 may be substantially the same as a structure obtained by rotating the first Y-axis fixing flexure structure 801 by about 90° about the Z-axis.

The first to third X-axis fixing flexure structures 901 to 903 may be disposed on the top surface of the X-axis mirror support 111x. The X-axis interference mirror 140x may be disposed on the first to third X-axis fixing flexure structures 901 to 903. The first to third X-axis fixing flexure structures 901 to 903 may be disposed between the X-axis mirror support 111x and the X-axis interference mirror 140x. The X-axis interference mirror 140x may be fixed onto the X-axis mirror support 111x by the first to third X-axis fixing flexure structures 901 to 903.

The first X-axis fixing flexure structure 901 may fix a partial region of the X-axis interference mirror 140x in the X-axis direction and the Z-axis direction. The first X-axis fixing flexure structure 901 may be combined with the bottom surface of the X-axis interference mirror 140x by the first Y-axis adaptor 151x.

The first X-axis fixing flexure structure 901 may be disposed close to the first side surface xs1 of the X-axis mirror support 111x. The first X-axis fixing flexure structure 901 may include an X-axis fixing upper plate 910, an X-axis fixing lower plate 920, a first X-axis fixing hinge part 930, an X-axis fixing body 940, and a second X-axis fixing hinge part 950.

The X-axis fixing upper plate 910 may be combined with the X-axis interference mirror 140x. The X-axis fixing upper plate 910 may be combined with the X-axis interference mirror 140x by the first X-axis adaptor 151x.

The X-axis fixing lower plate 920 may be combined with the X-axis mirror support 111x. The X-axis fixing lower plate 920 may extend in the X-axis direction. An X-axial horizontal length of the X-axis fixing lower plate 920 may be greater than an X-axial horizontal length of the X-axis fixing upper plate 910.

The first X-axis fixing hinge part 930 may fix the X-axis fixing upper plate 910 in the X-axis direction. The first X-axis fixing hinge part 930 may be disposed between the X-axis fixing upper plate 910 and the X-axis fixing lower plate 920. An X-axial horizontal length of the first X-axis fixing hinge part 930 may be equal to an X-axial horizontal length of the first X-axis fixing upper plate 910.

The first X-axis fixing hinge part 930 may include a first yz X-axis fixing flexure hinge 931yz, a first xz X-axis fixing flexure hinge 931xz, a zc X-axis fixing flexure hinge 930zc, a second xz X-axis fixing flexure hinge 932xz, and a second yz X-axis fixing flexure hinge 932yz. The first yz X-axis fixing flexure hinge 931yz, the first xz X-axis fixing flexure hinge 931xz, the zc X-axis fixing flexure hinge 930zc, the second xz X-axis fixing flexure hinge 932xz, and the second yz X-axis fixing flexure hinge 932yz may be stacked in the Z-axis direction.

The first yz X-axis fixing flexure hinge 931yz and the second yz X-axis fixing flexure hinge 932yz may be vertical-type flexure hinges extending in the Y-axis direction. The zc X-axis fixing flexure hinge 930zc may be a cross-type flexure hinge extending in the Z-axis direction. The first xz X-axis fixing flexure hinge 931xz and the second xz X-axis fixing flexure hinge 932xz may be vertical-type flexure hinges extending in the X-axis direction.

The X-axis fixing body 940 may be spaced apart from the first X-axis fixing hinge part 930 in the X-axis direction. The X-axis fixing body 940 may be fixed onto the X-axis fixing lower plate 920. A top surface of the X-axis fixing body 940 may be positioned at a lower level than a top surface of the X-axis fixing upper plate 910.

The second X-axis fixing hinge part 950 may fix the X-axis fixing upper plate 910 in the X-axis direction. The second X-axis fixing hinge part 950 may be disposed between an upper end of the first X-axis fixing hinge part 930 and an upper end of the X-axis fixing body 940. An X-axial horizontal length of the second X-axis fixing hinge part 950 may be equal to an X-axial horizontal length between the first X-axis fixing hinge part 930 and the X-axis fixing body 940.

The second X-axis fixing hinge part 950 may include a first yx X-axis fixing flexure hinge 951yx, a first zx X-axis fixing flexure hinge 951zx, an xc X-axis fixing flexure hinge 950xc, a second zx X-axis fixing flexure hinge 952zx, and a second yx X-axis fixing flexure hinge 952yx. The first yx X-axis fixing flexure hinge 951yx, the first zx X-axis fixing flexure hinge 951zx, the xc X-axis fixing flexure hinge 950xc, the second zx X-axis fixing flexure hinge 952zx, and the second yx X-axis fixing flexure hinge 952yx may be stacked in the X-axis direction.

The first yx X-axis fixing flexure hinge 951yx and the second yx X-axis fixing flexure hinge 952yx may be horizontal-type flexure hinges extending in the Y-axis direction. The xc X-axis fixing flexure hinge 950yc may be a cross-type flexure hinge extending in the X-axis direction. The first zx X-axis fixing flexure hinge 951zx and the second zx X-axis fixing flexure hinge 952zx may be X-axial flexure hinges extending in the Z-axis direction.

The second X-axis fixing flexure structure 902 may fix a partial region of the X-axis interference mirror 140x in the X-axis direction and the Z-axis direction. The second X-axis fixing flexure structure 902 may be combined with the bottom surface of the X-axis interference mirror 140x by the second Y-axis adaptor 152x.

The second X-axis fixing flexure structure 902 may be spaced apart from the first X-axis fixing flexure structure 901 in the X-axis direction. The second X-axis fixing flexure structure 902 may be disposed close to the first side surface xs1 of the X-axis mirror support 111x.

The second X-axis fixing flexure structure 902 may include fixing flexure hinges configured to fix the region combined with the X-axis interference mirror 140x in the X-axis direction and the Z-axis direction. For instance, the second X-axis fixing flexure structure 902 may have substantially the same structure as the first X-axis fixing flexure structure 901.

The third X-axis fixing flexure structure 903 may fix a partial region of the X-axis interference mirror 140x in the Y-axis direction and the Z-axis direction. The third X-axis fixing flexure structure 903 may be combined with the bottom surface of the X-axis interference mirror 140x by the third Y-axis adaptor 153x.

The third X-axis fixing flexure structure 903 may be disposed between the first X-axis fixing flexure structure 901 and the second X-axis fixing flexure structure 902. The third X-axis fixing flexure structure 903 may be disposed close to the second side surface xs2 of the X-axis mirror support 111x.

The third X-axis fixing flexure structure 903 may include fixing flexure hinges configured to fix the region combined with the X-axis interference mirror 140x in the Y-axis direction and the Z-axis direction. For instance, the third X-axis fixing flexure structure 903 may be substantially the same as a structure obtained by rotating the first X-axis fixing flexure structure 901 by about 90° about the Z-axis.

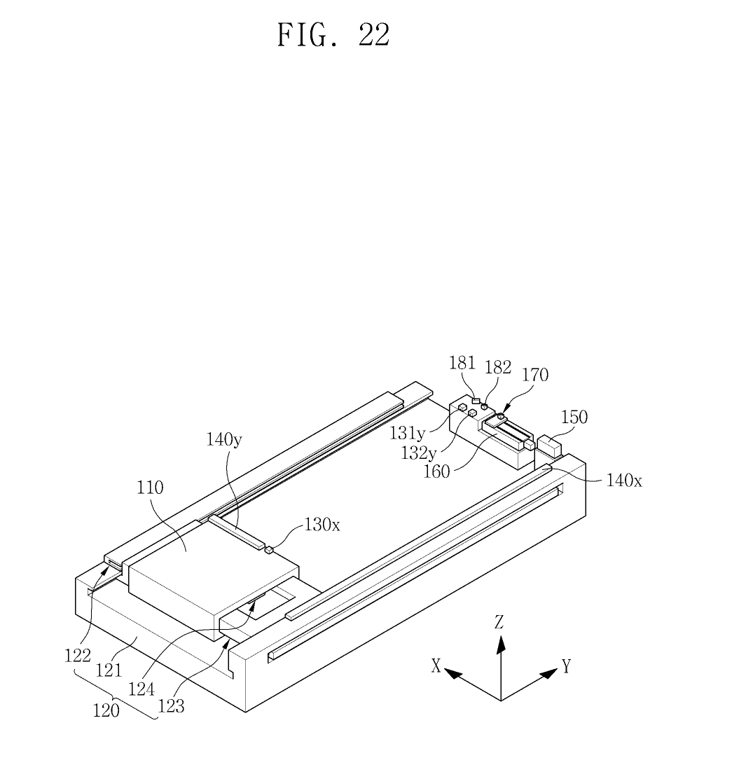

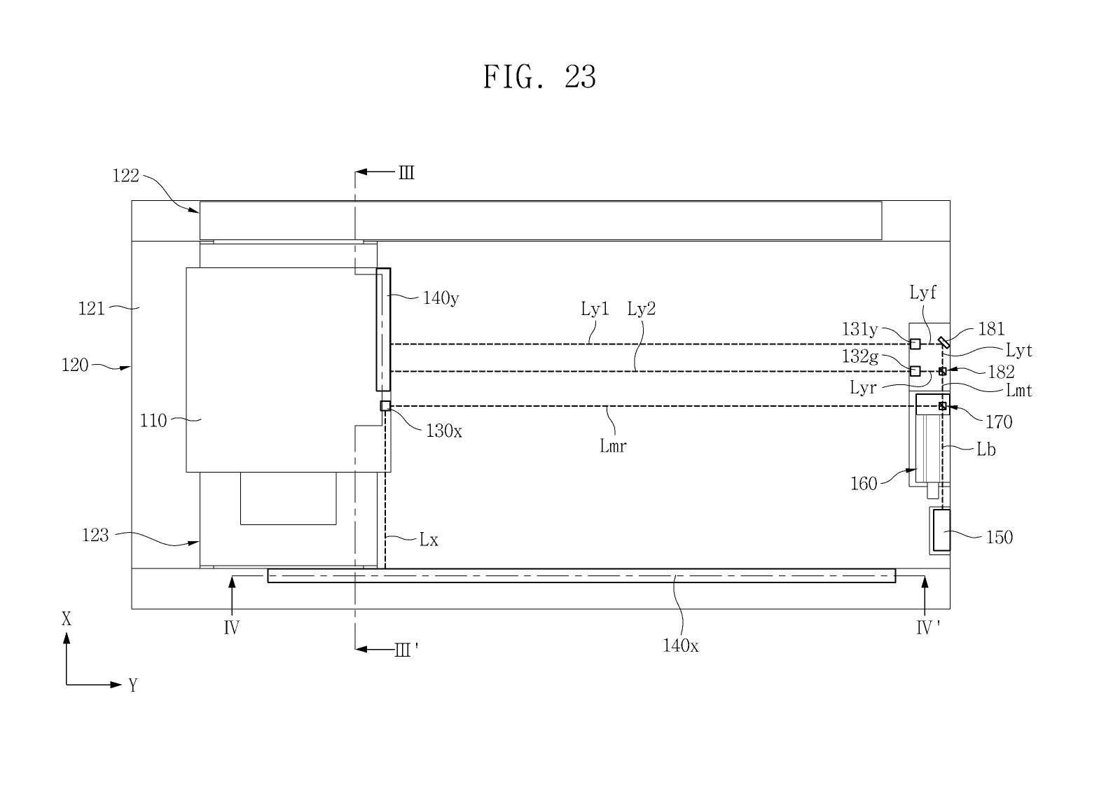

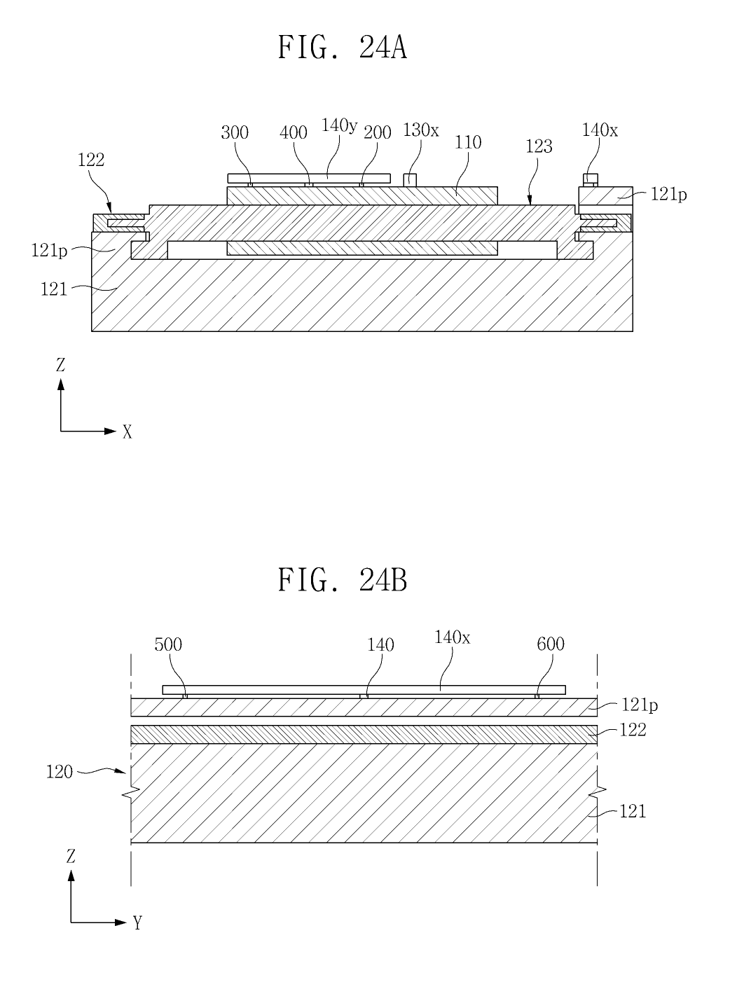

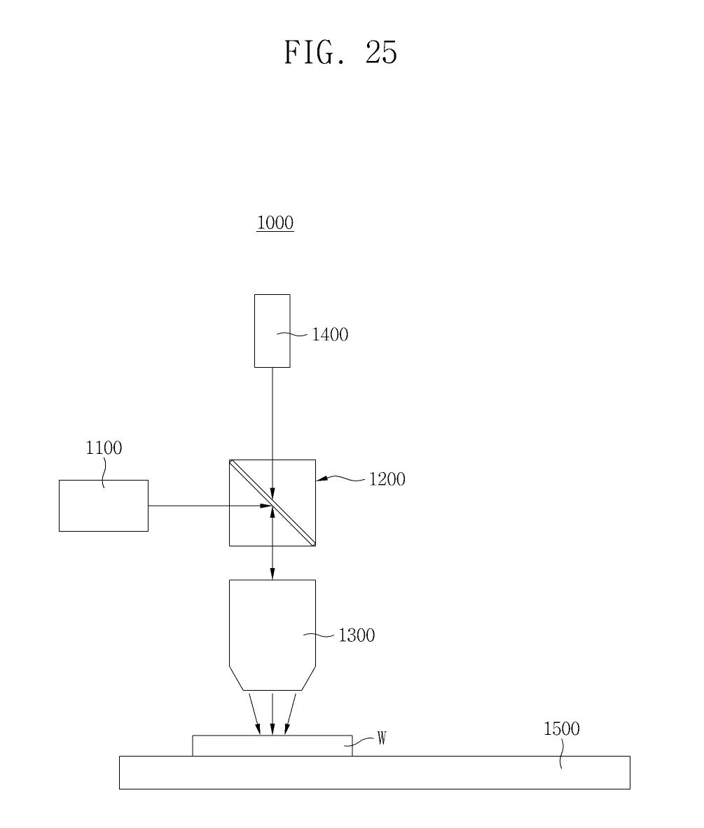

FIG. 22 is a perspective view of a stage device according to an exemplary embodiment of the inventive concept. FIG. 23 is a top view of a stage device according to an exemplary embodiment of the inventive concept. FIG. 24A is a cross-sectional view taken along line of FIG. 23, and FIG. 24B is a cross-sectional view taken along line IV-IV′ of FIG. 23.

Referring to FIGS. FIGS. 22, 23, 24A, and 24B, the stage device according to an exemplary embodiment of the inventive concept may include a stage 110, a stage base 120, a first Y-axis interferometer 131y, a second Y-axis interferometer 132y, an X-axis interferometer 130x, a Y-axis interference mirror 140y, an X-axis interference mirror 140x, a light source 150, an optical motion member 160, a motion beam splitter 170, a Y-axis fixing mirror 181, a Y-axis beam splitter 182, a Y-axis datum flexure structure 200, a Y-axis distant flexure structure 300, a Y-axis intermediate flexure structure 400, an X-axis datum flexure structure 500, an X-axis distant flexure structure 600, and an X-axis intermediate flexure structure 700.

The stage base 120 may include a base body 121, a Y-axis driving members 122, a guide block 123, and an X-axis driving member 124. The base body 121 may include a body protrusion 121p.

The first Y-axis interference mirror 131y may radiate beams Lyf reflected by the Y-axis fixing mirror 181 to the Y-axis interference mirror 140y. The first Y-axis interference mirror 131y may measure a Y-axial position of the stage 110 using beams Ly1 reflected by the Y-axis interference mirror 140y.

The first Y-axis interferometer 131y may be disposed on the base body 121. The first Y-axis interferometer 131y may be spaced apart from the stage 110 in the Y-axis direction. The first Y-axis interferometer 131y may be disposed between the stage 110 and the Y-axis fixing mirror 181.

The second Y-axis interferometer 132y may radiate beams Lyr reflected by the Y-axis beam splitter 182 to the Y-axis interference mirror 140y. The second Y-axis interferometer 132y may measure a Y-axial position of the stage 110 using beams Ly2 reflected by the Y-axis interference mirror 140y.

The stage device according to an exemplary embodiment of the inventive concept may include a first Y-axis interferometer 131y and a second Y-axis interferometer 132y configured to measure the Y-axial position of the stage device 110. Thus, in a stage device according to an exemplary embodiment of the inventive concept, the rotation of the stage 110 about Z-axis may be measured. Accordingly, in the stage device according to an exemplary embodiment of the inventive concept, the reliability for the measurement of the position of the stage 110 may be increased.

The second Y-axis interferometer 132y may be disposed on the base body 121. The first Y-axis interferometer 131y may be spaced apart from the stage 110 in the Y-axis direction. The second Y-axis interferometer 132y may be disposed between the stage 110 and the Y-axis beam splitter 182.

The second Y-axis interferometer 132y may be spaced apart from the first Y-axis interferometer 131y in the X-axis direction. The second Y-axis interferometer 132y may be disposed between the light source 150 and the first Y-axis interferometer 131y. A Y-axial horizontal distance between the second Y-axis interferometer 132y and the Y-axis interference mirror 140y may be equal to a Y-axial horizontal distance between the first Y-axis interferometer 131y and the Y-axis interference mirror 140y.

The X-axis interferometer 130x may radiate beams Lmr reflected by the motion beam splitter 170 to the X-axis interference mirror 140x. The X-axis interferometer 130x may measure an X-axial position of the stage 110 using beams Lx reflected by the X-axis interference mirror 140x.

The X-axis interferometer 130x may be disposed on the stage 110. The X-axis interferometer 130x may be spaced apart from the Y-axis interference mirror 140y in the X-axis direction. For instance, the X-axis interferometer 130x may be disposed between the Y-axis interference mirror 140y and the X-axis interference mirror 140x.

The Y-axis interference mirror 140y may be disposed on the stage 110. The Y-axis interference mirror 140y may be fixed onto the top surface of the stage 110 by the Y-axis datum flexure structure 200, the Y-axis distant flexure structure 300, and the Y-axis intermediate flexure structure 400.

The X-axis interference mirror 140x may be disposed on the Y-axis driving members 122. For instance, the X-axis interference mirror 140x may be disposed on the body protrusion 121p of the base body 121. The X-axis interference mirror 140x may be fixed onto the top surface of the body protrusion 121p by the X-axis datum flexure structure 500, the X-axis distant flexure structure 600, and the X-axis intermediate flexure structure 700.

The light source 150 may generate beams Lb radiated to the X-axis interferometer 130x, the first Y-axis interferometer 131y and the second Y-axis interferometer 132y. The light source 150 may radiate the beams Lb, for instance, in the X-axis direction.

The light source 150 may be spaced apart from the stage 100. For instance, the light source 150 may be spaced apart from the stage 100 in the Y-axis direction. The light source 150 may be disposed on the stage base 200. The light source 150 may be disposed on the top surface of the base body 210.

The optical motion member 160 may move the motion beam splitter 170. The optical motion member 160 may move the motion beam splitter 170 in the X-axis direction. The optical motion member 160 may move the motion beam splitter 170, allowing the X-axis interferometer 130x to be located on a path of the beams Lmr reflected by the motion beam splitter 170. The optical motion member 160 may move the motion beam splitter 170 according to a position of the stage 100. The path of the beams Lmr radiated from the motion beam splitter 170 toward the X-axis interferometer 130x may be moved in the X-axis direction according to an X-axial position of the stage 100 by the optical motion member 160.

The optical motion member 160 may be spaced apart from the stage 100. For instance, the optical motion member 160 may be spaced apart from the stage 100 in the Y-axis direction. The optical motion member 160 may be disposed on the top surface of the base body 210. The optical motion member 160 may support the motion beam splitter 170. The optical motion member 160 may be disposed between the base body 210 and the motion beam splitter 170.

The motion beam splitter 170 may split the beams Lb radiated by the light source 160. The beams Lb radiated by the light source 150 may be split by the motion beam splitter 170 in the direction of the X-axis interferometer 130x and the direction of the first Y-axis interferometer 131y and the second Y-axis interferometer 132y. The motion beam splitter 170 may split the beams Lb radiated by the light source 150 in the X-axis direction and the Y-axis direction. For instance, the motion beam splitter 170 may include a beam splitter configured to split the beams Lb radiated by the light source 150 in the direction of the first X-axis interferometer 130x and the direction of the first Y-axis interferometer 131y.

The motion beam splitter 170 may be spaced apart from the stage 100. For instance, the motion beam splitter 170 may be spaced apart from the stage 100 in the Y-axis direction. The motion beam splitter 170 may be disposed on the top surface of the base body 210.

The motion beam splitter 170 may be disposed on the path of the beams Lb radiated by the light source 150. For instance, the motion beam splitter 170 may be spaced apart from the light source 150 in the X-axis direction. The motion beam splitter 170 may be disposed between the light source 150 and the first Y-axis interferometer 131y. The motion beam splitter 170 may be disposed between the light source 150 and the second Y-axis interferometer 132y.

The Y-axis fixing mirror 181 may radiate beams to the first Y-axis interferometer 131y. The Y-axis fixing mirror 181 may reflect beams Lmt passing through the motion beam splitter 170 toward the first Y-axis interferometer 131y. The first Y-axis interferometer 131y may be disposed on the path of beams reflected by the Y-axis fixing mirror 181. For instance, the Y-axis fixing mirror 181 may be spaced apart from the first Y-axis interferometer 131y in the Y-axis direction. The first Y-axis interferometer 131y may be disposed between the Y-axis interference mirror 140y and the Y-axis fixing mirror 181.

The Y-axis fixing mirror 181 may be spaced apart from the stage 100. For instance, the Y-axis fixing mirror 181 may be spaced apart from the stage 100 in the Y-axis direction. The Y-axis fixing mirror 181 may be disposed on the top surface of the base body 210.

The Y-axis fixing mirror 181 may be disposed on the path of the beams Lmt radiated toward the first Y-axis interferometer 131y by the motion beam splitter 170. The Y-axis fixing mirror 181 may be disposed on the path of the beams Lmt passing through the motion beam splitter 170. For instance, the Y-axis fixing mirror 181 may be spaced apart from the motion beam splitter 170 in the X-axis direction. The motion beam splitter 170 may be disposed between the light source 150 and the Y-axis fixing mirror 181.

The Y-axis beam splitter 182 may split the beams Lmt passing through the motion beam splitter 170. The Y-axis beam splitter 182 may split the beams Lmt passing through the motion beam splitter 170 in the direction of the second Y-axis interferometer 132y and the direction of the Y-axis fixing mirror 181. For instance, the Y-axis beam splitter 182 may split the beams Lmt passing through the motion beam splitter 170 in the X-axis direction and the Y-axis direction. The second Y-axis interferometer 132y may be disposed on a path of beams Lyr reflected by the Y-axis beam splitter 182.

The Y-axis beam splitter 182 may be spaced apart from the stage 100. For instance, the Y-axis beam splitter 182 may be spaced apart from the stage 100 in the Y-axis direction. The Y-axis beam splitter 182 may be disposed on the top surface of the base body 210.

The Y-axis beam splitter 182 may be disposed between the motion beam splitter 170 and the Y-axis fixing mirror 181. The Y-axis fixing mirror 181 may be disposed on a path of beams Lyt passing through the Y-axis beam splitter 182. For instance, the Y-axis fixing mirror 181 may be spaced apart from the Y-axis beam splitter 182 in the X-axis direction. The path of the beams Lyt passing through the Y-axis beam splitter 182 may be the same as the path of the beams Lmt passing through the motion beam splitter 170. The Y-axis fixing mirror 181 may be disposed on the path of the beams Lyt passing through the Y-axis beam splitter 182

FIG. 25 is a diagram of a semiconductor fabrication apparatus 1000 including a stage device according to an exemplary embodiment of the inventive concept.

Referring to FIG. 25, the semiconductor fabrication apparatus 1000 including the stage device according to an exemplary embodiment of the inventive concept may include a light source member 1100, a beam splitter 1200, a test optical system 1300, a detector, 1400 and a stage member 1500. The semiconductor fabrication apparatus 1000 may be an optical measuring apparatus configured to measure the surface of a wafer. The semiconductor fabrication apparatus 1000 may be an optical test apparatus configured to test surface defects of a wafer.

The light source member 1100 may radiate light onto a wafer W through the beam splitter 1200 and the test optical system 1300. The beam splitter 1200 may reflect light radiated by the light source member 11000 toward the wafer W. The beam splitter 1200 may transmit light reflected by the wafer W. The test optical system 1300 may condense light reflected by the beam splitter 1200 onto the wafer W. Light reflected by the wafer W may pass through the beam splitter 1200 by the test optical system 1300. The detector 1400 may measure a surface profile of the wafer W using light reflected by the wafer W. The detector 1400 may confirm defects in a pattern formed on the wafer W using light reflected by the wafer W.

The stage member 1500 may support the wafer W. The wafer W may be fixed onto the stage member 1500. The stage member 1500 may move the wafer W during a fabrication process. The stage member 1500 may include a stage device according to an exemplary embodiment of the inventive concept. Thus, the stage member 1500 may precisely control the wafer W. Accordingly, reliability in measurement and tests of the semiconductor fabrication apparatus 1000 may be increased.

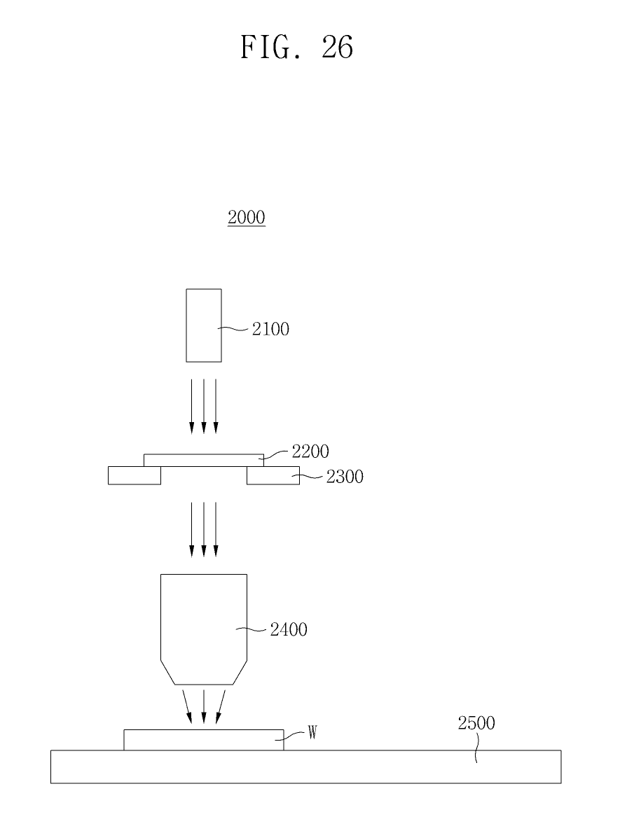

FIG. 26 is a diagram of a semiconductor fabrication apparatus 2000 including a stage device according to an exemplary embodiment of the inventive concept.

Referring to FIG. 26, the semiconductor fabrication apparatus 2000 including the stage device according to an exemplary embodiment of the inventive concept may include a light source member 2100, a reticle 2200, a reticle table 2300, an exposure optical system 2400, and a stage member 2500. The semiconductor fabrication apparatus 2000 may be an exposure apparatus.

The light source member 2100 may radiate light onto the wafer W through the reticle 2200 and the exposure optical system 2400. The reticle 2200 may be disposed between the light source member 2100 and the wafer stage 2500. The reticle 2200 may include a predetermined pattern. Light radiated by the light source member 2100 may be patterned by the pattern of the reticle 2200. The light source member 2100 may transfer the pattern of the reticle 2200 onto the wafer W. The reticle table 2300 may be disposed under the reticle 2200. The reticle table 2300 may support the reticle 2200. The reticle table 2300 may be in direct contact with the reticle 2200. The exposure optical system 2400 may condense light passing through the reticle 2200 onto the wafer W.

The stage member 2500 may fix the wafer W. The stage member 2500 may be disposed under the exposure optical system 2400. The stage member 2500 may move the wafer W during a fabrication process. The stage member 2500 may include a stage device according to an exemplary embodiment of the inventive concept. Thus, the stage member 2500 may precisely control the wafer W. Accordingly, reliability in an exposure process of the semiconductor fabrication process 2000 may be increased.

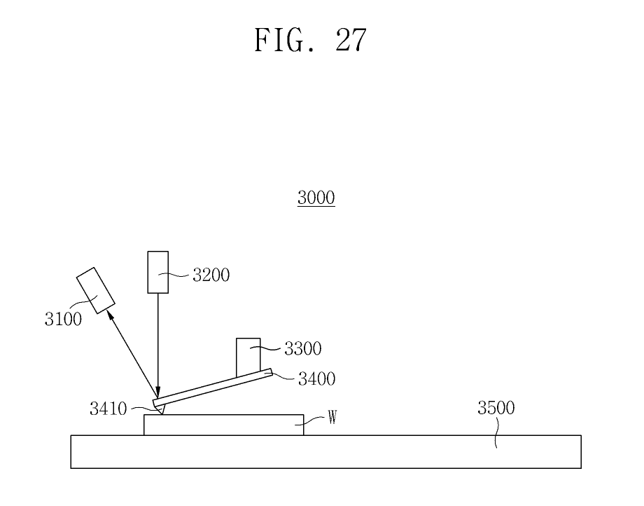

FIG. 27 is a schematic diagram of a semiconductor fabrication apparatus 3000 including a stage device according to an exemplary embodiment of the inventive concept.

Referring to FIG. 27, the semiconductor fabrication apparatus 3000 including the stage device according to an exemplary embodiment of the inventive concept may include a light source member 3100, an optical detection member 3200, a cantilever support member 3300, a cantilever, 3400 and a stage member 3500. The semiconductor fabrication apparatus 3000 may be an atomic microscope, such as a scanning tunneling microscope (STM) and an atomic force microscope (AFM).

The light source member 3100 may radiate light onto an end portion of the cantilever 3400. The optical detection member 3200 may detect beams reflected by the cantilever 3400. The optical detection member 3200 may measure a surface profile of the wafer W based on the wavelength, phase, intensity, or positional variation of light reflected by the cantilever 3400. The cantilever support member 3300 may fix a position of the cantilever 3400. The cantilever 3400 may include a tip 3410 disposed close to the wafer W. The tip 3410 may move up and down according to a surface state of the wafer W. The tip 3410 may be spaced apart from the surface of the wafer W.

The stage member 3500 may fix the wafer W. The stage member 3500 may move the wafer W during a fabrication process. The stage member 3500 may include a stage device according to an exemplary embodiment of the inventive concept. Thus, the stage member 3500 may precisely control the wafer W. Accordingly, reliability in a measured surface profile of the semiconductor fabrication apparatus 3000 may be increased.

A stage device and a semiconductor fabrication apparatus including the stage device, according to exemplary embodiments of the inventive concept, can include an interference mirror extending in an X-axis direction and three flexure structures configured to fix the interference mirror. The flexure structures can restrict the X-axial motion, X-axial rotation, Y-axial motion, Y-axial rotation, Z-axial motion, and Z-axial rotation of the interference mirror without redundancy. Thus, the interference mirror may be prevented from being deformed by stress caused by installing the interference mirror or moving a stage. Accordingly, the stage device and semiconductor fabrication apparatus including the stage device according to exemplary embodiments of the inventive concept may have increased reliability in the measurement/control of a position of the stage.

While the inventive concept has been shown and described with reference to exemplary embodiments thereof, it will be apparent to those of ordinary skill in the art that various changes in form and detail may be made thereto without departing from the spirit and scope of the inventive concept as defined by the following claims.

What is claimed is:

1. A stage device, comprising:
an interference mirror extending in an X-axis direction;
a datum flexure structure configured to restrict the interference mirror in a Y-axis direction and a Z-axis direction, the datum flexure structure including a datum upper plate combined with the interference mirror and a datum hinge part disposed under the datum upper plate;
a distant flexure structure configured to restrict the interference mirror in the Y-axis direction and the Z-axis direction, the distant flexure structure including a distant upper plate spaced apart from the datum upper plate in the X-axis direction and a first distant hinge part disposed under the distant upper plate; and
an intermediate flexure structure configured to restrict the interference mirror in the X-axis direction and the Z-axis direction, the intermediate flexure structure including an intermediate upper plate disposed between the datum upper plate and the distant upper plate and a first intermediate hinge part disposed under the intermediate upper plate,
wherein each of the datum hinge part, the first distant hinge part, and the first intermediate hinge part comprises flexure hinges stacked in the Z-axis direction, and
wherein the intermediate upper plate is spaced apart from the datum upper plate and the distant upper plate in the Y-axis direction.

2. The device of claim 1, wherein the datum hinge part comprises:
a vertical-type first yz datum flexure hinge extending in the Y-axis direction;
a vertical-type second yz datum flexure hinge extending in the Y-axis direction;
a vertical-type xz datum flexure hinge extending in the X-axis direction; and
a cross-type zc datum flexure hinge extending in the Z-axis direction.

3. The device of claim 2, wherein the second yz datum flexure hinge is spaced apart from the first yz datum flexure hinge in the Z-axis direction.

4. The device of claim 2, wherein a Y-axial horizontal length of the datum hinge part increases in a direction away from the datum upper plate.

5. The device of claim 2, wherein the first distant hinge part comprises:
a first yz distant flexure hinge disposed parallel to the first yz datum flexure hinge;
a second yz distant flexure hinge disposed parallel to the second yz datum flexure hinge;
a first xz distant flexure hinge disposed parallel to the xz datum flexure hinge; and
a zc distant flexure hinge disposed parallel to the zc datum flexure hinge.

6. The device of claim 5, wherein an order in which the first yz distant flexure hinge, the second yz distant flexure hinge, the first xz distant flexure hinge, and the zc distant flexure hinge are stacked is different from an order in which the first yz datum flexure hinge, the second yz datum flexure hinge, the xz datum flexure hinge, and the zc

7. The device of claim 5, wherein the distant flexure structure further comprises:
a first distant body spaced apart from the first distant hinge part in the Y-axis direction; and
a second distant hinge part configured to restrict the distant upper plate in the Y-axis direction, wherein the second distant hinge part comprises flexure hinges disposed between an upper end of the first distant hinge part and an upper end of the first distant body, and stacked in the Y-axis direction, and wherein the first distant hinge part further comprises a vertical-type second xz distant flexure hinge extending in the X-axis direction.

8. The device of claim 7, wherein the second distant hinge part comprises:
a horizontal-type first xy distant flexure hinge extending in the X-axis direction;
a horizontal-type second xy distant flexure hinge extending in the X-axis direction;
a Y-axial type first zy distant flexure hinge extending in the Z-axis direction;
a Y-axial type second zy distant flexure hinge extending in the Z-axis direction; and
a cross-type yc distant flexure hinge extending in the Y-axis direction.

9. The device of claim 7, wherein the distant flexure structure further comprises:
a distant lower plate disposed under the first distant hinge part, the distant lower plate extending in the Y-axis direction;
a second distant body disposed under the second distant hinge part, the second distant fixed onto the distant lower plate;
a horizontal-type xy rotation flexure hinge disposed between an upper end of the second distant body and the first distant body, the xy rotation flexure hinge extending in the X-axis direction; and
a rotation control member disposed at a lower end of the first distant body, wherein the first distant body is spaced apart from the distant lower plate, and wherein a level of a bottom surface of the first distant body is higher than a level of a bottom surface of the distant lower plate.

10. The device of claim 1, wherein the first intermediate hinge part comprises:
a vertical-type first yz intermediate flexure hinge extending in the Y-axis direction;
a vertical-type first xz intermediate flexure hinge extending in the X-axis direction;
a vertical-type second xz intermediate flexure hinge extending in the X-axis direction; and
a cross-type zc intermediate flexure hinge extending in the Z-axis direction.

11. The device of claim 10, wherein the intermediate flexure structure further comprises:
an intermediate fixing body spaced apart from the first intermediate hinge part in the X-axis direction; and
a second intermediate hinge part configured to restrict the intermediate upper plate in the X-axis direction, wherein the second intermediate hinge part comprises flexure hinges disposed between an upper end of the first intermediate hinge part and an upper end of the intermediate fixing body, the flexure hinges stacked in the X-axis direction, and wherein the first intermediate hinge part further comprises a vertical second yz intermediate flexure hinge extending in the Y-axis direction.

12. The device of claim 11, wherein the second intermediate hinge part comprises:
a horizontal-type first yx intermediate flexure hinge extending in the Y-axis direction;
a horizontal-type second yx intermediate flexure hinge extending in the Y-axis direction;
an X-axial type first zx intermediate flexure hinge extending in the Z-axis direction;
an X-axial type second zx intermediate flexure hinge extending in the Z-axis direction; and
a cross-type xc intermediate flexure hinge extending in the X-axis direction.

13. The device of claim 11, wherein the intermediate flexure structure further comprises tilting control part configured to move the intermediate upper plate and the first intermediate hinge part in the Z-axis direction, wherein the tilting control part comprises:
an intermediate lower plate disposed under the intermediate fixing body, the intermediate lower plate extending in the X-axis direction;
an tilting fixing body disposed under the second distant hinge part, the tilting fixing body fixed onto the intermediate lower plate;
a first tilting control body disposed between the intermediate fixing body and the tilting fixing body, the first tilting control body spaced apart from the intermediate lower plate;
a second tilting control body disposed between the second intermediate hinge part and the tilting fixing body;
a third tilting control body disposed between the first intermediate hinge part and the tilting fixing body, the third tilting control body spaced apart from the intermediate lower plate;
a horizontal-type first yx tilting flexure hinge disposed between an upper end of the tilting fixing body and the first tilting control body, the first yx tilting flexure hinge extending in the Y-axis direction;
a horizontal-type second yx tilting flexure hinge disposed between the first tilting control body and the second tilting control body, the second yx tilting flexure hinge extending in the Y-axis direction;
a horizontal-type third yx tilting flexure hinge disposed between the second tilting control body and the third tilting control body, the third yx tilting flexure hinge extending in the Y-axis direction;
a horizontal-type fourth yx tilting flexure hinge disposed between a lower end of the tilting fixing body and the third tilting control body, the fourth yx tilting flexure hinge extending in the Y-axis direction; and
a tilting control element disposed at a lower end of the first tilting control body.

14. The device of claim 13, wherein the third tilting control body is connected to a lower end of the first intermediate hinge part, and wherein a level of a bottom surface of the third tilting control body is higher than a level of a bottom surface of the intermediate lower plate.

15. A stage device, comprising:
a first flexure structure including a first upper plate and first flexure hinges configured to restrict the first upper plate in a Y-axis direction and a Z-axis direction;
a second flexure structure spaced apart from the first flexure structure in an X-axis direction, the second flexure structure including a second upper plate and second flexure hinges configured to restrict the second upper plate in the Y-axis direction and the Z-axis direction;
a third flexure structure disposed between the first flexure structure and the second flexure structure, the third flexure structure including a third upper plate and third flexure hinges configured to restrict the third upper plate in the X-axis direction and the Z-axis direction; and
an interference mirror disposed on the first through third upper plates, the interference mirror extending in the X-axis direction,
wherein the first and second upper plates are disposed close to a first side surface of the interference minor, the first side surface of the interference mirror extending in the X-axis direction, wherein the third upper plate is disposed close to a second side surface of the interference mirror opposite to the first side surface, and wherein a Y-axial horizontal length of each of the first through third upper plates is less than or equal to the half of a Y-axial horizontal length of the interference mirror.

16. A stage device, comprising:
a stage;
a first support disposed on the stage;
a first interference mirror disposed on the first support;
a first flexure structure disposed adjacent to a first upper edge of the first support between the first support and the first interference mirror, the first flexure structure restricting a movement of the first interference mirror in a Y-axis direction and a Z-axis direction;
a second flexure structure disposed adjacent to the first upper edge of the first support between the first support and the first interference mirror, the second flexure structure restricting a movement of the first interference mirror in the Y-axis direction and the Z-axis direction; and
a third flexure structure disposed adjacent to a second upper edge of the first support between the first support and the first interference mirror, the second upper edge opposite the first upper edge, the third flexure structure restricting a movement of the first interference mirror in an X-axis direction and the Z-axis direction, the third flexure structure positioned between the first flexure structure and the second flexure structure in the X-axis direction,
wherein each of the first flexure structure, the second flexure structure, and the third flexure structure includes a plurality of hinges that are stacked in the Z-axis direction.

17. The stage device of claim 16, further comprising adaptors respectively attaching the first flexure structure, the second flexure structure, and the third flexure structure to the first interference mirror.

18. The stage device of claim 16, further comprising:
a second support disposed on the stage, the second support expanding in the different direction as the first support;
a second interference mirror disposed on the second support; and
at least three flexure structures disposed between the second support and the second interference mirror, the three flexure structures restricting a movement of the second interference mirror in the X-axis direction, the Y-axis direction, or the Z-axis direction.

19. The stage device of claim 18, wherein the each of the three flexure structures includes an upper plate, a lower plate, and a hinge set disposed between the upper plate and the lower plate.

20. The stage device of claim 19, wherein the hinge set of each of the three flexure structures includes a plurality of hinges that are stacked in the Z-axis direction.
